(19) United States
(12) Patent Application Publication
(10) Pub. No.: US 2024/0053680 A1
(43) Pub. Date: Feb. 15, 2024

(54) PHOTOSENSITIVE DRY FILM, LAMINATED FILM, METHOD FOR PRODUCING LAMINATED FILM, AND METHOD FOR PRODUCING PATTERNED RESIST FILM

(71) Applicant: TOKYO OHKA KOGYO CO., LTD., Kawasaki-shi (JP)

(72) Inventors: Aya MOMOZAWA, Kawasaki-shi (JP); Yuta YAMAMOTO, Kawasaki-shi (JP)

(21) Appl. No.: 18/258,533

(22) PCT Filed: Nov. 30, 2021
(86) PCT No.: PCT/JP2021/043743

§ 371 Date: Jun. 20, 2023

(30) Foreign Application Priority Data
Dec. 28, 2020 (JP) 2020-218627

(51) Int. Cl. G03F 7/039; G03F 7/004

(52) U.S. Cl. CPC G03F 7/0392; G03F 7/0045; G03F 7/0048

(57) ABSTRACT

A photosensitive dry film including a chemically amplified positive type photosensitive composition, in which the photosensitive dry film can suppress white turbidity and separation caused by resin contained therein and can prevent bubbles generated while solvent is removed by heating from remaining. The photosensitive dry film including a chemically amplified positive type photosensitive composition includes an acid generating agent, resin having alkali solubility that increases under action of an acid, and organic solvent, the resin including an acrylic resin, the acrylic resin including a constituent unit derived from (meth)acrylate including an acid-non-dissociable alicyclic hydrocarbon group-comprising group, the organic solvent (S) including a high boiling point organic solvent that has a boiling point at atmospheric pressure of 150° C. or more, and a value of δh, a term of energy by hydrogen bonding relating to a Hansen solubility parameter, of 11 (MPa)^{0.5} or less.

### TECHNICAL FIELD

The present invention relates to a photosensitive dry film, a laminated film having the photosensitive dry film; a method of producing the laminated film; and a method of producing a patterned resist film using the above-described laminated film.

### BACKGROUND ART

Photofabrication is now the mainstream of a microfabrication technique. Photofabrication is a generic term describing the technology used for manufacturing a wide variety of precision components such as semiconductor packages. The manufacturing is carried out by applying a photoresist composition to the surface of a processing target to form a photoresist layer, patterning this photoresist layer using photolithographic techniques, and then conducting chemical etching, electrolytic etching, or electroforming mainly based on electroplating, using the patterned photoresist layer (photoresist pattern) as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems or three-dimensional packaging technologies. In these high density packaging techniques, connection terminals, such as protruding electrodes (mounting terminals), e.g., bumps protruding from the package, or metal posts to connect redistribution that extends from peripheral terminals on the wafer with the mounting terminals, are disposed on the surface of the substrate with high precision.

In the photofabrication as described above, a photoresist composition is used, and chemically amplified photosensitive compositions containing an acid generating agent have been known as such a photoresist composition (see Patent Documents 1, 2 and the like). According to the chemically amplified photosensitive composition, an acid is generated from the acid generating agent upon irradiation with radiation (exposure) and diffusion of the acid is promoted through heat treatment, to cause an acid catalytic reaction with a base resin and the like in the composition, resulting in a change to the alkali-solubility of the same.

Such chemically amplified photosensitive compositions are used, for example, in formation of plated articles such as bumps, metal posts, and Cu redistribution, for example, in plating steps, in addition to formation of patterned insulating films or etching masks. Specifically, a photoresist layer having a desired film thickness is formed on a support such as a metal substrate using a chemically amplified photosensitive composition, and the photoresist layer is exposed through a predetermined mask pattern and is developed. Thereby, a photoresist pattern used as a template in which portions for forming plated articles have been selectively removed (stripped) is formed. Then, bumps, metal posts, and Cu redistribution can be formed by embedding a conductor such as copper into the removed portions (nonresist portions) using plating, and then removing the surrounding photoresist pattern.
Patent Document 1: Japanese Unexamined Patent Application, Publication No. H9-176112
Patent Document 2: Japanese Unexamined Patent Application, Publication No. H11-52562

### DISCLOSURE OF THE INVENTION

### Problems to be Solved by the Invention

Here, in a case in which a photoresist layer to be formed is thick or in other cases, the photoresist layer is provided as a photosensitive dry film formed on a base film by using an applicator, a bar coater, or the like, in some cases. A resist pattern can be formed on a support by laminating such a laminated film including a photosensitive dry film formed on a base film on the support (substrate) such that the photosensitive dry film is in contact with the surface of the support, peeling off the base film, and exposing the photosensitive dry film in a position-selective manner, followed by developing.

In such a laminated film, a solvent is contained in the photosensitive dry film in order to ensure flexibility. Then, after the photosensitive dry film is laminated on a support (substrate), the solvent is removed from the photosensitive dry film in order to form a resist pattern having a good shape, and then the photosensitive dry film is exposed and developed. However, there is an issue that when a conventional photosensitive dry film is heated (PAB) to remove the solvent, bubbles generated while the solvent evaporates may remain in the photosensitive dry film after the heating (PAB). If bubbles are present in the photosensitive dry film after heating, a resist pattern (patterned resist film) including unintended pores (bubbles) is formed.

Incidentally, when a photosensitive dry film is used for forming the above-described plated articles, an alicyclic hydrocarbon group-containing group is sometimes introduced into a resin serving as a base in order to improve chemical resistance and heat resistance of a pattern serving as a template. In this case, white turbidity or separation may occur in the photosensitive dry film. The photosensitive dry film in which white turbidity or separation has occurred has poor transparency or uniformity, thus the acid generating agent and the resin contained therein cannot exert functions thereof, and it is, therefore, difficult to obtain a patterned resist film having a desired shape.

The present invention has been made in view of the above-mentioned problems, and it is an object of the present invention to provide a photosensitive dry film composed of a chemically amplified positive type photosensitive composition, in which the photosensitive dry film can suppress white turbidity and separation caused by a resin contained therein and can prevent bubbles generated while the solvent is removed by heating from remaining; a laminated film having the photosensitive dry film; a method of producing the laminated film; and a method of producing a patterned resist film using the above-described laminated film.

### Means for Solving the Problems

As a result of extensive research to achieve the above objects, the present inventors have found that the above problems can be solved by a photosensitive dry film including an acid generating agent (A) to generate an acid by irradiation with an actinic ray or radiation, a resin (B) having an alkali solubility that increases under action of an acid, and an organic solvent (S), in which the resin (B) includes an acrylic resin (B3), the acrylic resin (B3) includes a constituent unit (B3a) derived from a (meth)acrylate including an acid-non-dissociable alicyclic hydrocarbon group-containing group, the organic solvent (S) includes a high boiling temperature organic solvent (S1) that satisfies the following conditions I) and II), thereby arriving at completion of the present invention. Specifically, the present invention provides the following.

A first aspect of the present invention relates to a photosensitive dry film composed of a chemically amplified positive type photosensitive composition, comprising: an acid generating agent (A) to generate an acid by irradiation with an actinic ray or radiation, a resin (B) having an alkali solubility that increases under action of an acid, and an organic solvent (S), the resin (B) comprising an acrylic resin (B3), the acrylic resin (B3) comprising a constituent unit (B3a) derived from a (meth)acrylate comprising an acid-non-dissociable alicyclic hydrocarbon group-comprising group, the organic solvent (S) comprising a high boiling point organic solvent (S1) that satisfies the following conditions I) and II):
I) a boiling point at atmospheric pressure is 150° C. or more, and
II) a value of δh, a term of energy by hydrogen bonding relating to a Hansen solubility parameter, is 11 (MPa)0.5 or less.

A second aspect of the present invention relates to a laminated film comprising a base film and the photosensitive dry film as described in the first aspect, the photosensitive dry film being laminated on the base film.

A third aspect of the present invention relates to a method of producing the laminated film as described in the second aspect, the method including the steps of:
coating a base film with the chemically amplified positive type photosensitive composition to form a coating film; and drying the coating film by heating to remove some of the organic solvent (S) to form the photosensitive dry film.

A fourth aspect of the present invention relates to a method of producing a patterned resist film, including the steps of:
laminating the laminated film as described in the second aspect on a substrate so that the photosensitive dry film is in contact with a surface of the substrate;
removing the base film from the laminated film;
removing the organic solvent (S) by heating the photosensitive dry film at 100° C. or more and 180° C. or less; exposing the photosensitive dry film by irradiating the photosensitive dry film with an actinic ray or radiation in a position-selective manner after the solvent removing step; and developing the photosensitive dry film after the exposing step.

### Effects of the Invention

According to the present invention, it is possible to provide a photosensitive dry film composed of a chemically amplified positive type photosensitive composition, in which white turbidity or separation caused by a resin contained therein is suppressed and the remaining of bubbles generated while a solvent is removed by heating is suppressed; a laminated film having the photosensitive dry film; a method of producing the laminated film; and a method of producing a patterned resist film using the laminated film.

### PREFERRED MODE FOR CARRYING OUT THE INVENTION

### <<Photosensitive Dry Film>>

The photosensitive dry film is composed of a chemically amplified positive type photosensitive composition (hereinafter, also referred to as a photosensitive composition). The photosensitive dry film contains an acid generating agent (A) to generate an acid by irradiation with an actinic ray or radiation (hereinafter also referred to as an acid generating agent (A)), a resin (B) having an alkali solubility that increases under action of an acid (hereinafter also referred to as a resin (B)), and an organic solvent (S). The resin (B) contains an acrylic resin (B3), and the acrylic resin (B3) includes a constituent unit (B3a) derived from a (meth)acrylate including an acid-non-dissociable alicyclic hydrocarbon group-containing group. The organic solvent (S) includes a high boiling point organic solvent (S1) that satisfies the following conditions I) and II). I) The boiling point at atmospheric pressure is 150° C. or more; and II) a value of δh, a term of energy by hydrogen bonding relating to a Hansen solubility parameter is 11 (MPa)^{0.5} or less.

Such a photosensitive dry film can be produced by a method including: applying a photosensitive composition to form a coating film, and drying the coating film by heating the coating film to remove some of the organic solvent (S) contained in the photosensitive composition to form a photosensitive dry film.

Therefore, likewise to the photosensitive dry film, the photosensitive composition contains the acid generating agent (A), the resin (B), and the organic solvent (S), the resin (B) contains the acrylic resin (B3), the acrylic resin (B3) includes the constituent unit (B3a) derived from a (meth)acrylate including an acid-non-dissociable alicyclic hydrocarbon group-containing group, and the organic solvent (S) includes the high boiling point organic solvent (S1) that satisfies the conditions I) and II). That is, the components contained in the photosensitive composition is typically the same as the components contained in the photosensitive dry film. However, since the photosensitive dry film is formed by heating (drying) the photosensitive composition to remove some of the organic solvent (S), the content ratio of the organic solvent (S) in the photosensitive dry film is typically lower than the content ratio of the organic solvent (S) in the photosensitive composition. The blending ratio of each component that is not related to the organic solvent (S) and the blending ratio of the constituent unit in the resin are typically substantially the same between the photosensitive composition and the photosensitive dry film.

First, essential or optional components of the photosensitive composition and a producing method thereof will be described. The essential or optional components described below are common to the essential or optional components included in the photosensitive dry film.

### <Acid Generating Agent (A)>

The acid generating agent (A) is a compound to produce an acid when irradiated with an active ray or radiation, and is not particularly limited as long as it is a compound which directly or indirectly produces an acid under the action of light. The acid generating agent (A) is preferably any one of the acid generating agents of the first to fifth aspects that will be described below. Hereinafter, among suitably used acid generating agents (A) in the photosensitive composition, particularly suitable acid generating agents (A) will be described as the first to fifth aspects.

An example of the first aspect of the acid generating agent (A) may include a compound represented by the following formula (a1).

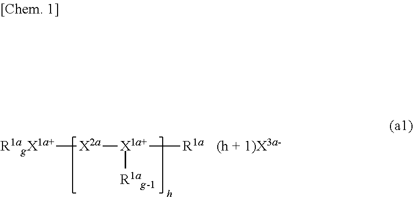

In the formula (a1), X^{1a} represents a sulfur atom or iodine atom respectively having a valence of g; g represents 1 or 2. h represents the number of repeating units in the structure within parentheses. R^{1a} represents an organic group that is bonded to X^{1a}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms, or an alkynyl group having 2 or more and 30 or less carbon atoms, and R^{1a} may be substituted with at least one selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group, and halogen atoms. The number of R^{1a}s is g+h (g−1)+1, and the R^{1a}s may be respectively identical to or different from each other. Furthermore, two or more R^{1a}s may be bonded to each other directly or via —O—, —S—, —SO—, —SO₂—, —NH—, —NR^{2a}—, —CO—, —COO—, —CONH—, an alkylene group having 1 or more and 3 or less carbon atoms, or a phenylene group, and may form a ring structure including X^{1a}. R^{2a} represents an alkyl group having 1 or more and 5 or less carbon atoms, or an aryl group having 6 or more and 10 or less carbon atoms.

X^{2a} represents a structure represented by the following formula (a2).

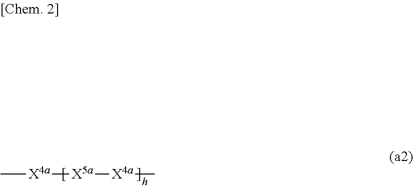

In the above formula (a2), X^{4a} represents an alkylene group having 1 or more and 8 or less carbon atoms, an arylene group having 6 or more and 20 or less carbon atoms, or a divalent group of a heterocyclic compound having 8 or more and 20 or less carbon atoms, and X^{4a} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group, and halogen atoms. X^{3a} represents —O—, —S—, —SO—, —SO₂—, —NH—, —NR^{2a}—, —CO—, —COO—, —CONH—, an alkylene group having 1 or more and 3 or less carbon atoms, or a phenylene group. h represents the number of repeating units of the structure in parentheses. X^{4a}s in the number of h+1 and X^{5a}s in the number of h may be identical to or different from each other. R^{2a} has the same definition as described above.

X^{3a-} represents a counterion of an onium, and examples thereof include a fluorinated alkylfluorophosphoric acid anion represented by the following formula (a17) or a borate anion represented by the following formula (a18).

[Chem. 3]

[(R^{3a})ⱼPF₆₋ⱼ]⁻ (a17)

In the formula (a17), R^{3a} represents an alkyl group having 80% or more of the hydrogen atoms substituted with fluorine atoms. j represents the number of R^{3a}s and is an integer of 1 or more and 5 or less. R^{3a}s in the number of j may be respectively identical to or different from each other.

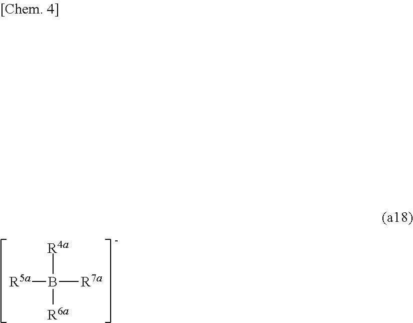

In the formula (a18), R^{4a} to R^{7a} each independently represents a fluorine atom or a phenyl group, and a part or all of the hydrogen atoms of the phenyl group may be substituted with at least one selected from the group consisting of a fluorine atom and a trifluoromethyl group.

Examples of the onium ion in the compound represented by the above formula (a1) include triphenylsulfonium, tri-p-tolylsulfonium, 4-(phenylthio)phenyldiphenylsulfonium, bis[4-(diphenylsulfonio)phenyl] sulfide, bis[4-{bis[4-(2-hydroxyethoxy)phenyl]sulfonio}phenyl] sulfide, bis{4-[bis(4-fluorophenyl)sulfonio]phenyl} sulfide, 4-(4-benzoyl-2-chlorophenylthio)phenylbis(4-fluorophenyl)sulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfo-nium, 2-naphthylmethyl(1-ethoxycarbonyl)ethylsulfonium, 4-hydroxyphenylmethylphenacylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, or the like.

Among the onium ions in the compound represented by the above formula (a1), a preferred onium ion may be a sulfonium ion represented by the following formula (a19).

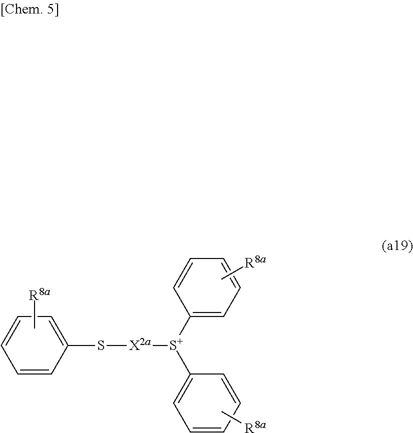

In the above formula (a19), R^{8a}s each independently represents a hydrogen atom or a group selected from the group consisting of alkyl, hydroxyl, alkoxy, alkylcarbonyl, alkylcarbonyloxy, alkyloxycarbonyl, a halogen atom, an aryl, which may be substituted, and arylcarbonyl. X^{2a} has the same definition as X^{2a} in the above formula (a1).

Specific examples of the sulfonium ion represented by the above formula (a19) include 4-(phenylthio)phenyldiphenylsulfonium, 4-(4-benzoyl-2-chlorophenylthio)phenylbis(4-fluorophenyl)sulfonium, 4-(4-benzoylphenylthio)phenyldiphenylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, and diphenyl[4-(p-terphenylthio)phenyl]diphenylsulfonium.

In regard to the fluorinated alkylfluorophosphoric acid anion represented by the above formula (a17), R^{3a} represents an alkyl group substituted with a fluorine atom, and a preferred number of carbon atoms is 1 or more and 8 or less, while a more preferred number of carbon atoms is 1 or more and 4 or less. Specific examples of the alkyl group include linear alkyl groups such as methyl, ethyl, propyl, butyl, pentyl and octyl; branched alkyl groups such as isopropyl, isobutyl, sec-butyl and tert-butyl; and cycloalkyl groups such as cyclopropyl, cyclobutyl, cyclopentyl, and cyclohexyl. The proportion of hydrogen atoms substituted with fluorine atoms in the alkyl groups is usually 80% or more, preferably 90% or more, and even more preferably 100%. If the substitution ratio of fluorine atoms is less than 80%, the acid strength of the onium fluorinated alkylfluorophosphate represented by the above formula (a1) decreases.

A particularly preferred example of R^{3a} is a linear or branched perfluoroalkyl group having 1 or more and 4 or less carbon atoms and a substitution ratio of fluorine atoms of 100%. Specific examples thereof include CF₃, CF₃CF₂, (CF₃)₂CF, CF₃CF₂CF₂, CF₃CF₂CF₂CF₂, (CF₃)₂CFCF₂, CF₃CF₂(CF₃)CF, and (CF₃)₃C. j which is the number of R^{3a}s represents an integer of 1 or more and 5 or less, and is preferably 2 or more and 4 or less, and particularly preferably 2 or 3.

Preferred specific examples of the fluorinated alkylfluorophosphoric acid anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻, or [(CF₃CF₂CF₂)₃PF₃]⁻. Among these, [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻, or [((CF₃)₂CFCF₂)₂PF₄]⁻ are particularly preferred.

Preferred specific examples of the borate anion represented by the above formula (a18) include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl)borate ([(C₆F₅)₂BF₂]⁻), trifluoro (pentafluorophenyl)borate ([(C₆F₅) BF₃]⁻), and tetrakis(difluorophenyl)borate ([B(C₆H₃F₂)₄]⁻). Among these, tetrakis(pentafluorophenyl)borate ([B(C₆F₅)₄]⁻) is particularly preferred.

Examples of the second aspect of the acid generating agent (A) include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the following formula (a3) such as tris(2,3-dibromopropyl)isocyanurate.

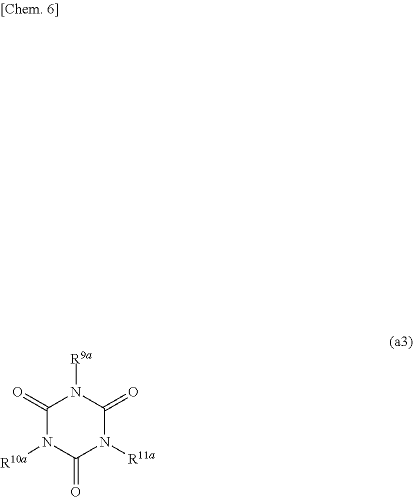

In the above formula (a3), R^{9a}, R^{10a}, and R^{11a} each independently represent a halogenated alkyl group.

Further, examples of the third aspect of the acid generating agent (A) include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile and α-(ethylsulfonyloxyimino)-1-cyclopentenylacetonitrile, and compounds represented by the following formula (a4) having an oximesulfonate group.

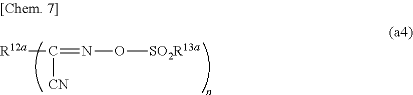

In the above formula (a4), R^{12a} represents a monovalent, divalent or trivalent organic group, R^{13a} represents a substituted or unsubstituted saturated hydrocarbon group, an unsaturated hydrocarbon group, or an aromatic group, and n represents the number of repeating units of the structure in the parentheses.

In the formula (a4), examples of the aromatic group include aryl groups such as a phenyl group and a naphthyl group, and heteroaryl groups such as a furyl group and a thienyl group. These may have one or more appropriate substituents such as halogen atoms, alkyl groups, alkoxy groups and nitro groups on the rings. It is particularly preferable that R^{13a} is an alkyl group having 1 or more and 6 or less carbon atoms such as a methyl group, an ethyl group, a propyl group, and a butyl group. In particular, compounds in which R^{12a} represents an aromatic group, and R^{13a} represents an alkyl group having 1 or more and 4 or less carbon atoms are preferred.

Examples of the acid generating agent represented by the above formula (a4) include compounds in which R^{12a} is any one of a phenyl group, a methylphenyl group and a methoxyphenyl group, and R^{13a} is a methyl group, provided that n is 1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene] (o-tolyl)acetonitrile and the like. Provided that n is 2, the acid generating agent represented by the above formula (a4) is specifically an acid generating agent represented by the following formulae.

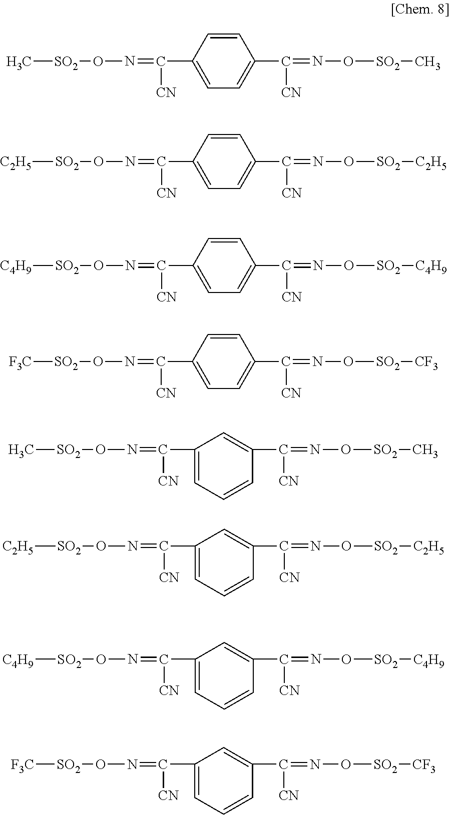

In addition, examples of the fourth aspect of the acid generating agent (A) may include onium salts having a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 or more and 6 or less carbon atoms, a hydroxyl group, a linear or branched alkoxy group having 1 or more and 6 or less carbon atoms or the like. The structure derived from the naphthalene ring, which may be of a monovalent group (one free valance) or of a divalent group (two free valences), is desirably of a monovalent group (in this regard, the number of free valance is counted except for the portions connecting with the substituents described above). The number of naphthalene rings is preferably 1 or more and 3 or less.

Preferably, the cation moiety of the onium salt having a naphthalene ring at the cation moiety is of the structure represented by the following formula (a5).

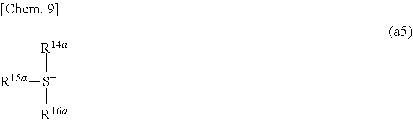

In the above formula (a5), at least one of R^{14a}, R^{15a} and R^{16a} represents a group represented by the following formula (a6), and the remaining represents a linear or branched alkyl group having 1 or more and 6 or less carbon atoms, a phenyl group optionally having a substituent, a hydroxyl group, or a linear or branched alkoxy group having 1 or more and 6 or less carbon atoms. Alternatively, one of R^{14a}, R^{15a} and R^{16a} is a group represented by the following formula (a6), and the remaining two are each independently a linear or branched alkylene group having 1 or more and 6 or less carbon atoms, and these terminals may bond to form a ring structure.

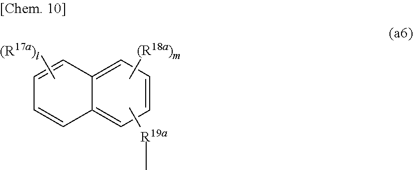

In the formula (a6), R^{17a} and R^{18a} each independently represent a hydroxyl group, a linear or branched alkoxy group having 1 or more and 6 or less carbon atoms, or a linear or branched alkyl group having 1 or more and 6 or less carbon atoms, and R^{19a} represents a single bond or a linear or branched alkylene group having 1 or more and 6 or less carbon atoms that may have a substituent. 1 and m each independently represent an integer of 0 or more and 2 or less, and 1+m is 3 or less. Herein, when there exists a plurality of R^{17a}, they may be identical to or different from each other. Furthermore, when there exists a plurality of R^{18a}, they may be identical to or different from each other.

Preferably, among R^{14a}, R^{15a} and R^{16a} as above, the number of groups represented by the above formula (a6) is one in view of the stability of the compound, and the remaining are linear or branched alkylene groups having 1 or more and 6 or less carbon atoms of which the terminals may bond to form a ring. In this case, the two alkylene groups described above form a 3 to 9 membered ring including sulfur atom(s). Preferably, the number of atoms to form the ring (including sulfur atom(s)) is 5 or more and 6 or less.

Examples of the substituent, which the alkylene group may have, include an oxygen atom (in this case, a carbonyl group is formed together with a carbon atom that constitutes the alkylene group), a hydroxyl group or the like.

Furthermore, examples of the substituent, which the phenyl group may have, include a hydroxyl group, a linear or branched alkoxy group having 1 or more and 6 or less carbon atoms, a linear or branched alkyl group having 1 or more and 6 or less carbon atoms, or the like.

Examples of suitable cations for the suitable cation moiety include cations represented by the following formulae (a7) and (a8), and the structure represented by the following formula (a8) is particularly preferable.

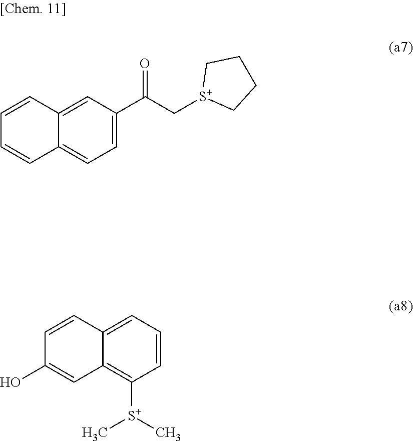 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in view of acid-producing efficiency.

It is, therefore, desirable that the suitable anions for the anion moiety of the onium salt having a naphthalene ring at the cation moiety is an anion capable of forming a sulfonium salt.

The anion moiety of the acid generating agent is exemplified by fluoroalkylsulfonic acid ions or aryl sulfonic acid ions, of which hydrogen atom(s) being partially or entirely fluorinated.

The alkyl group of the fluoroalkylsulfonic acid ions may be linear, branched or cyclic and have 1 or more and 20 or less carbon atoms. Preferably, the carbon number is 1 or more and 10 or less in view of bulkiness and diffusion distance of the produced acid. In particular, branched or cyclic alkyl groups are preferable due to shorter diffusion length. Also, methyl, ethyl, propyl, butyl, octyl groups and the like are preferable due to being inexpensively synthesizable.

The aryl group of the aryl sulfonic acid ions may be an aryl group having 6 or more and 20 or less carbon atoms, and is exemplified by a phenol group or a naphthyl group that may be unsubstituted or substituted with an alkyl group or a halogen atom. In particular, aryl groups having 6 or more and 10 or less carbon atoms are preferable due to being inexpensively synthesizable. Specific examples of preferable aryl group include phenyl, toluenesulfonyl, ethylphenyl, naphthyl, methylnaphthyl groups and the like.

When hydrogen atoms in the above fluoroalkylsulfonic acid ion or the aryl sulfonic acid ion are partially or entirely substituted with a fluorine atom, the fluorination rate is preferably 10% or more and 100% or less, and more preferably 50% or more and 100% or less; it is particularly preferable that all hydrogen atoms are each substituted with a fluorine atom in view of higher acid strength. Specific examples thereof include trifluoromethane sulfonate, perfluorobutane sulfonate, perfluorooctane sulfonate, perfluorobenzene sulfonate, and the like.

Among these, the preferable anion moiety is exemplified by those represented by the following formula (a9).

[Chem. 12]

R^{20a}SO₃⁻ (a9)

In the above formula (a9), R^{20a} represents groups represented by the following formulae (a10), (a11), and (a12).

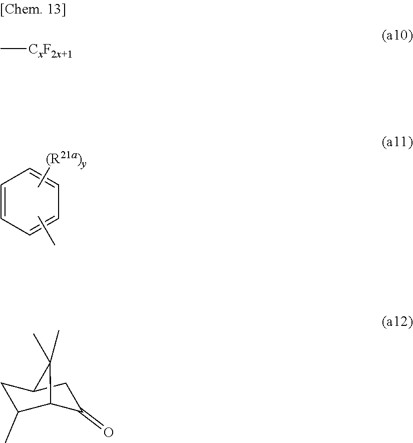

In the above formula (a10), x represents an integer of 1 or more and 4 or less. Also, in the above formula (a11), R^{21a} represents a hydrogen atom, a hydroxyl group, a linear or branched alkyl group having 1 or more and 6 or less carbon atoms, or a linear or branched alkoxy group having 1 or more and 6 or less carbon atoms, and y represents an integer of 1 or more and 3 or less. Of these, trifluoromethane sulfonate, and perfluorobutane sulfonate are preferable in view of safety.

In addition, a nitrogen-containing moiety represented by the following formulae (a13) and (a14) may also be used for the anion moiety.

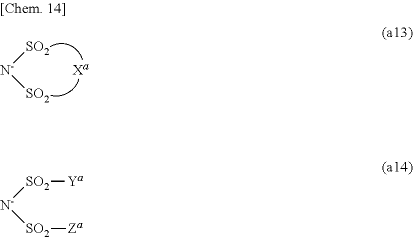

In the formulae (a13) and (a14), X^{a} represents a linear or branched alkylene group in which at least one hydrogen atom is substituted with a fluorine atom, the carbon number of the alkylene group is 2 or more and 6 or less, preferably 3 or more and 5 or less, and most preferably the carbon number is 3. In addition, Y^{a} and Z^{a} each independently represent a linear or branched alkyl group of which at least one hydrogen atom is substituted with a fluorine atom, the number of carbon atoms of the alkyl group is 1 or more and 10 or less, preferably 1 or more and 7 or less, and more preferably 1 or more and 3 or less.

The smaller number of carbon atoms in the alkylene group of X^{a}, or in the alkyl group of Y^{a} or Z^{a} is preferred since the solubility into organic solvent is favorable.

In addition, a larger number of hydrogen atoms each substituted with a fluorine atom in the alkylene group of X^{a}, or in the alkyl group of Y^{a} or Z^{a} is preferred since the acid strength becomes greater. The percentage of fluorine atoms in the alkylene group or alkyl group, i.e., the fluorination rate is preferably 70% or more and 100% or less and more preferably 90% or more and 100% or less, and most preferable are perfluoroalkylene or perfluoroalkyl groups in which all of the hydrogen atoms are each substituted with a fluorine atom.

Examples of preferable compounds for onium salts having a naphthalene ring at their cation moieties include compounds represented by the following formulae (a15) and (a16).

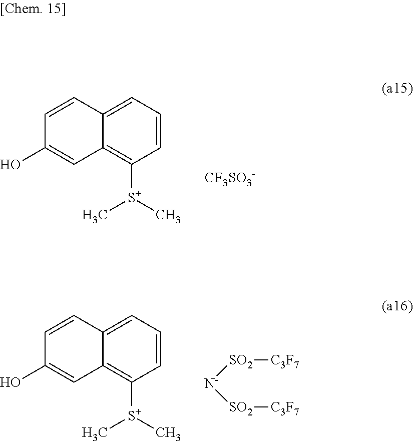

Also, examples of the fifth aspect of the acid generating agent (A) may include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxysuccinimide, N-trichloromethylsulfonyloxysuccinimide, N-phenylsulfonyloxymaleimide and N-methylsulfonyloxyphthalimide; trifluoromethane sulfonates such as N-(trifluoromethylsulfonyloxy)phthalimide, N-(trifluoromethylsulfonyloxy)-1,8-naphthalimide and N-(trifluoromethylsulfonyloxy)-4-butyl-1,8-naphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates and the like.

This acid generating agent (A) may be used alone, or two or more types may be used in combination. Furthermore, the content of the acid generating agent (A) is adjusted to preferably 0.1% by mass or more and 10% by mass or less, more preferably 0.2% by mass or more and 6% by mass or less, and particularly preferably 0.5% by mass or more and 3% by mass or less, relative to the total mass of the solid component of the photosensitive composition. When the amount of the acid generating agent (A) used is adjusted to the range mentioned above, it is easy to prepare a photosensitive composition which is a uniform solution having satisfactory sensitivity and excellent storage stability.

### <Resin (B)>

The photosensitive composition includes, as essential components, the acrylic resin (B3) as the resin (B) having an alkali solubility that increases under action of an acid. The acrylic resin (B3) includes a constituent unit (B3a) derived from a (meth)acrylate including an acid-non-dissociable alicyclic hydrocarbon group-containing group. The photosensitive composition may contain, together with the acrylic resin (B3), any resin having an alkali solubility that increases under action of an acid other than the acrylic resin (B3). However, the ratio of the mass of the acrylic resin (B3) with respect to the mass of the resin (B) is preferably 50% by mass or more, more preferably 70% by mass or more, more preferably 90% by mass or more, and particularly preferably 100% by mass or more. Examples of the any resin having an alkali solubility that increases under action of an acid other than the acrylic resin (B3) include a novolac resin (B1), a polyhydroxystyrene resin (B2), and an acrylic resin other than the acrylic resin (B3). Each resin will be specifically described below.

### [Novolac Resin (B1)]

As the novolak resin (B1), a resin including the constituent unit represented by the following formula (b1) may be used.

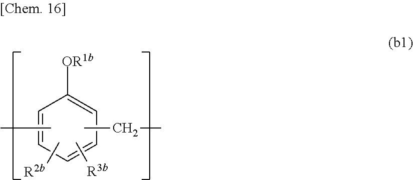

In the formula (b1), R^{1b} represents an acid-dissociable dissolution-inhibiting group, and R^{2b} and R^{3b} each independently represent a hydrogen atom or an alkyl group having 1 or more and 6 or less carbon atoms.

The acid-dissociable dissolution-inhibiting group represented by the above R^{1b} is preferably a group represented by the following formula (b2) or (b3), a linear, branched or cyclic alkyl group having 1 or more and 6 or less carbon atoms, a vinyloxyethyl group, a tetrahydropyranyl group, a tetrahydrofuranyl group, or a trialkylsilyl group.

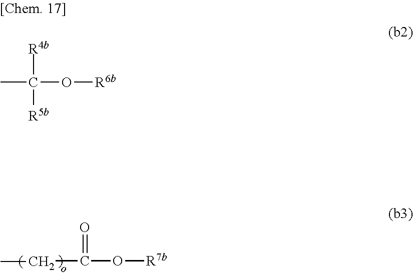

In the above formulae (b2) and (b3), R^{4b} and R^{5b} each independently represent a hydrogen atom, or a linear or branched alkyl group having 1 or more and 6 or less carbon atoms, R^{6b} represents a linear, branched or cyclic alkyl group having 1 or more and 10 or less carbon atoms, R^{7b} represents a linear, branched or cyclic alkyl group having 1 or more and 6 or less carbon atoms, and o represents 0 or 1.

Examples of the above linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Also, examples of the above cyclic alkyl group include a cyclopentyl group, a cyclohexyl group, and the like.

Specific examples of the acid-dissociable dissolution-inhibiting group represented by the above formula (b2) include a methoxyethyl group, an ethoxyethyl group, an n-propoxyethyl group, an isopropoxyethyl group, an n-butoxyethyl group, an isobutoxyethyl group, a tert-butoxyethyl group, a cyclohexyloxyethyl group, a methoxypropyl group, an ethoxypropyl group, a 1-methoxy-1-methyl-ethyl group, a 1-ethoxy-1-methylethyl group, and the like. Furthermore, specific examples of the acid-dissociable dissolution-inhibiting group represented by the above formula (b3) include a tert-butoxycarbonyl group, a tert-butoxycarbonylmethyl group, and the like. Examples of the above trialkylsilyl group include a trimethylsilyl group and a tri-tert-butyldimethylsilyl group in which each alkyl group has 1 or more and 6 or less carbon atoms.

### [Polyhydroxystyrene Resin (B2)]

As the polyhydroxystyrene resin (B2), a resin including a constituent unit represented by the following formula (b4) may be used.

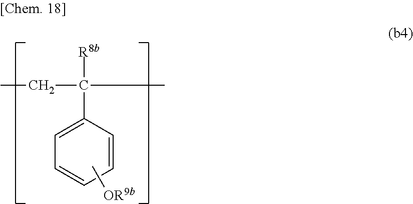

In the above formula (b4), R^{8b} represents a hydrogen atom or an alkyl group having 1 or more and 6 or less carbon atoms, and R^{9b} represents an acid-dissociable dissolution-inhibiting group.

The above alkyl group having 1 or more and 6 or less carbon atoms may include, for example, linear, branched or cyclic alkyl groups having 1 or more and 6 or less carbon atoms. Examples of the linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Examples of the cyclic alkyl group include a cyclopentyl group and a cyclohexyl group.

The acid-dissociable dissolution-inhibiting group represented by the above R^{9b} may be similar to those exemplified in terms of the above formulae (b2) and (b3).

Furthermore, the polyhydroxystyrene resin (B2) may include another polymerizable compound as a constituent unit in order to moderately control physical or chemical properties. The polymerizable compound is exemplified by conventional radical polymerizable compounds and anion polymerizable compounds. Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl(meth)acrylate, ethyl (meth)acrylate and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

### [Acrylic Resin (B3)]

The acrylic resin (B3) as the resin (B) having an alkali solubility that increases under action of an acid includes a constituent unit (B3a) derived from a (meth)acrylate including an acid-non-dissociable alicyclic hydrocarbon group-containing group (hereinafter also referred to as constituent unit (B3a)).

In the present specification, the “acrylic resin” is a resin in which a ratio of an acrylic constituent unit, which is a constituent unit derived from a monomer having a (meth)acryloyloxy group, with respect to all of the constituent units constituting the resin is 50 mol % or more, preferably 70 mol % or more, and more preferably 90 mol % or more. In this specification, “(meth)acrylic” means both “acrylic” and “methacrylic”. “(Meth)acrylate” means both “acrylate” and “methacrylate”. “(Meth)acryloyloxy” means both “acryloyloxy” and “methacryloyloxy”.

As the acid-non-dissociable alicyclic hydrocarbon group-containing group which is included in the constituent unit (B3a), a polycyclic acid-non-dissociable alicyclic hydrocarbon group-containing group may be exemplified. As the polycyclic acid-non-dissociable alicyclic hydrocarbon group-containing group, a tricyclodecanyl group, an adamantyl group, a tetracyclododecanyl group, an isobornyl group, a norbornyl group, or the like is preferable from the viewpoint of industrial availability. These acid-non-dissociable alicyclic hydrocarbon group-containing groups may have a linear or branched alkyl group having 1 to 5 carbon atoms as a substituent. The constituent unit (B3a) can be introduced into the acrylic resin (B3), for example, by using a (meth)acrylic acid ester having an acid-non-dissociable alicyclic hydrocarbon group-containing group, as a copolymerization component.

Examples of the constituent unit (B3a) include the following formulae (B3a-1) to (B3a-5). In formulae (B3a-1) to (B3a-5), R^{25b} represents a hydrogen atom or a methyl group.

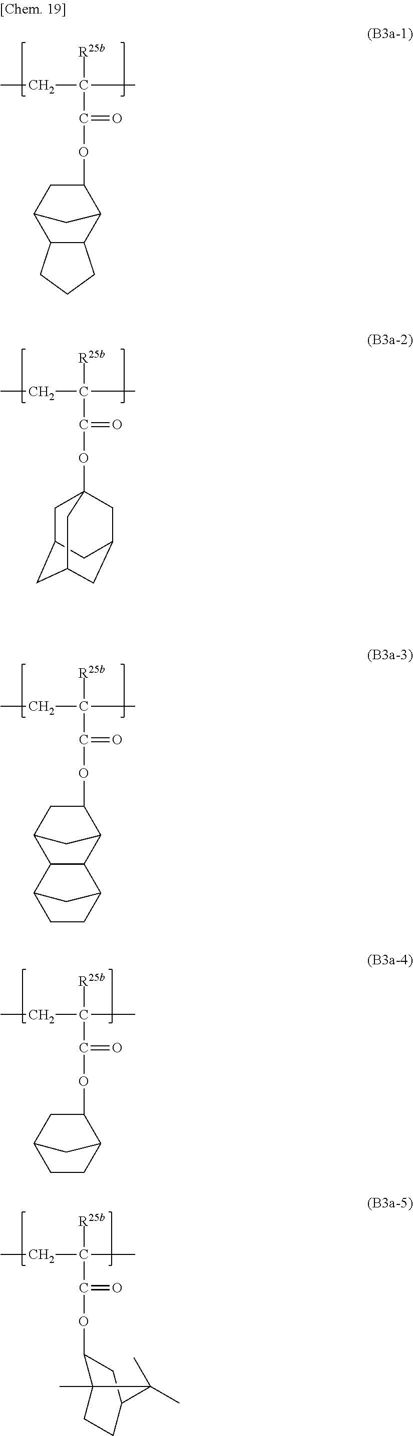

The ratio of the mass of the constituent unit (B3a) with respect to the mass of the acrylic resin (B3) is preferably 15% by mass or more and 50% by mass or less, and more preferably 20% by mass or more and 30% by mass or less.

Preferably, the acrylic resin (B3) contains a constituent unit (b-3) derived from, for example, an acrylic ester including an —SO₂— containing cyclic group or a lactone-containing cyclic group. In such a case, when a resist pattern is formed, a resist pattern having a preferable cross-sectional shape can be easily formed.

### (—SO₂—Containing Cyclic Group)

Herein, the “—SO₂-containing cyclic group” refers to a cyclic group having a cyclic group containing a ring including —SO₂— in the ring skeleton thereof, specifically a cyclic group in which the sulfur atom (S) in —SO₂— forms a part of the ring skeleton of the cyclic group. Considering a ring including —SO₂— in the ring skeleton thereof as the first ring, a group having that ring alone is called a monocyclic group, and a group further having another ring structure is called a polycyclic group regardless of its structure. The —SO₂— containing cyclic group may be monocyclic or polycyclic.

In particular, the —SO₂-containing cyclic group is preferably a cyclic group containing —O—SO₂— in the ring skeleton thereof, i.e., a cyclic group containing a sultone ring in which —O—S— in —O—SO₂— forms a part of the ring skeleton.

The number of carbon atoms in an —SO₂-containing cyclic group is preferably 3 or more and 30 or less, more preferably 4 or more and 20 or less, even more preferably 4 or more and 15 or less, and in particular preferably 4 or more and 12 or less. The above number of carbon atoms is the number of carbon atoms constituting a ring skeleton, and shall not include the number of carbon atoms in a substituent.

The —SO₂-containing cyclic group may be an —SO₂— containing aliphatic cyclic group or an —SO₂-containing aromatic cyclic group. It is preferably an —SO₂-containing aliphatic cyclic group.

—SO₂— containing aliphatic cyclic groups include a group in which at least one hydrogen atom is removed from an aliphatic hydrocarbon ring where a part of the carbon atoms constituting the ring skeleton thereof is(are) substituted with —SO₂— or —O—SO₂—. More specifically, they include a group in which at least one hydrogen atom is removed from an aliphatic hydrocarbon ring where —CH₂— constituting the ring skeleton thereof is substituted with —SO₂— and a group in which at least one hydrogen atom is removed from an aliphatic hydrocarbon ring where —CH₂—CH₂— constituting the ring thereof is substituted with —O—SO₂—.

The number of carbon atoms in the above alicyclic hydrocarbon ring is preferably 3 or more and 20 or less, more preferably 3 or more and 12 or less. The above alicyclic hydrocarbon ring may be polycyclic, or may be monocyclic. As the monocyclic alicyclic hydrocarbon group, preferred is a group in which two hydrogen atoms are removed from monocycloalkane having 3 or more and 6 or less carbon atoms. Examples of the above monocycloalkane can include cyclopentane, cyclohexane and the like. As the polycyclic alicyclic hydrocarbon ring, preferred is a group in which two hydrogen atoms are removed from polycycloalkane having 7 or more and 12 or less carbon atoms, and specific examples of the above polycycloalkane include adamantane, norbornane, isobornane, tricyclodecane, tetracyclododecane and the like.

The —SO₂-containing cyclic group may have a substituent. Examples of the above substituent include, for example, an alkyl group, an alkoxy group, a halogen atom, a halogenated alkyl group, a hydroxyl group, an oxygen atom (═O), —COOR″, —OC(═O)R″, a hydroxyalkyl group, a cyano group and the like.

For an alkyl group as the above substituent, preferred is an alkyl group having 1 or more and 6 or less carbon atoms. The above alkyl group is preferably linear or branched. Specific examples include a methyl group, an ethyl group, an n-propyl group, an isopropyl group, an n-butyl group, an isobutyl group, a tert-butyl group, an n-pentyl group, an isopentyl group, a neopentyl group, an n-hexyl group and the like. Among these, a methyl group or an ethyl group is preferred, and a methyl group is particularly preferred.

For an alkoxy group as the above substituent, preferred is an alkoxy group having 1 or more and 6 or less carbon atoms. The above alkoxy group is preferably linear or branched. Specific examples include a group in which an alkyl groups recited as an alkyl group for the above substituent is attached to the oxygen atom (—O—).

Halogen atoms as the above substituent include a fluorine atom, a chlorine atom, a bromine atom, an iodine atom and the like, and a fluorine atom is preferred.

Halogenated alkyl groups for the above substituent include a group in which a part or all of the hydrogen atoms in the above alkyl group is(are) substituted with the above halogen atom(s).

Halogenated alkyl groups as the above substituent include a group in which a part or all of the hydrogen atoms in the alkyl groups recited as an alkyl group for the above substituent is(are) substituted with the above halogen atom(s). As the above halogenated alkyl group, a fluorinated alkyl group is preferred, and a perfluoroalkyl group is particularly preferred.

R″s in the aforementioned —COOR″ and —OC(═O)R″ are either a hydrogen atom or a linear, branched or cyclic alkyl group having 1 or more and 15 or less carbon atoms.

In a case where R″ is a linear or branched alkyl group, the number of carbon atoms in the above chain alkyl group is preferably 1 or more and 10 or less, more preferably 1 or more and 5 or less, and in particular preferably 1 or 2.

In a case where R″ is a cyclic alkyl group, the number of carbon atoms in the above cyclic alkyl group is preferably 3 or more and 15 or less, more preferably 4 or more and 12 or less, and in particular preferably 5 or more and 10 or less. Specific examples can include a group in which one or more hydrogen atoms are removed from monocycloalkane; and polycycloalkane such as bicycloalkane, tricycloalkane, tetracycloalkane and the like optionally substituted with a fluorine atom or a fluorinated alkyl group. More specific examples include a group in which one or more hydrogen atoms are removed from monocycloalkane such as cyclopentane and cyclohexane; and polycycloalkane such as adamantane, norbornane, isobornane, tricyclodecane and tetracyclododecane.

For a hydroxyalkyl group as the above substituent, preferred is a hydroxyalkyl group having 1 or more and 6 or less carbon atoms. Specific examples include a group in which at least one of the hydrogen atoms in the alkyl groups recited as an alkyl group for the above substituent is substituted with a hydroxyl group.

More specific examples of the —SO₂-containing cyclic group include the groups represented by the following formulae (3-1) to (3-4).

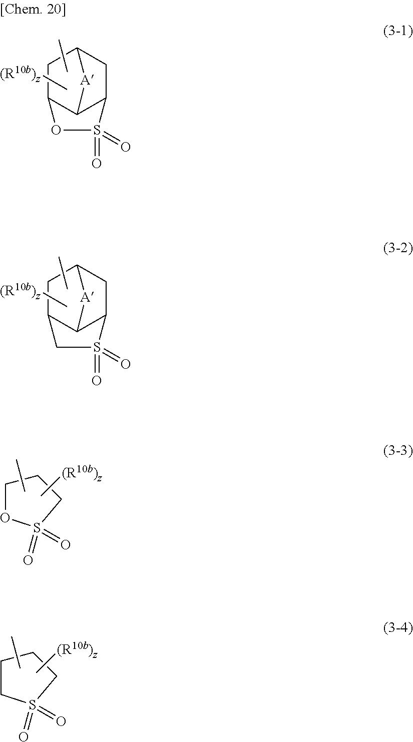

(In the formulae, A′ represents an alkylene group having 1 or more and 5 or less carbon atoms optionally including an oxygen atom or a sulfur atom, an oxygen atom or a sulfur atom; z represents an integer of 0 or more and 2 or less; R^{10b} represents an alkyl group, an alkoxy group, a halogenated alkyl group, a hydroxyl group, —COOR″, —OC(═O)R″, a hydroxyalkyl group, or a cyano group; and R″ represents a hydrogen atom or an alkyl group.)

In the above formulae (3-1) to (3-4), A′ represents an alkylene group having 1 or more and 5 or less carbon atoms optionally including an oxygen atom (—O—) or a sulfur atom (—S—), an oxygen atom or a sulfur atom. As an alkylene group having 1 or more and 5 or less carbon atoms in A′, a linear or branched alkylene group is preferred, and examples thereof include a methylene group, an ethylene group, an n-propylene group, an isopropylene group and the like.

In a case where the above alkylene group includes an oxygen atom or a sulfur atom, specific examples thereof include a group in which —O— or —S— is present at a terminal or between carbon atoms of the above alkylene group, for example, —O—CH₂—, —CH₂—O—CH₂—, —S—CH₂—, —CH₂—S—CH₂—, and the like. As A′, an alkylene group having 1 or more and 5 or less carbon atoms or —O— is preferred, and an alkylene group having 1 or more and 5 or less carbon atoms is more preferred, and a methylene group is most preferred.

z may be any of 0, 1, and 2, and is most preferably 0. In a case where z is 2, a plurality of R^{10b} may be the same, or may differ from each other.

An alkyl group, the alkoxy group, the halogenated alkyl group, —COOR″, —OC(═O)R″ and a hydroxyalkyl group in R^{10b} include those similar to the groups described above for the alkyl group, the alkoxy group, the halogenated alkyl group, —COOR″, —OC(═O)R″ and the hydroxyalkyl group, respectively, which are recited as those optionally contained in the —SO₂— containing cyclic group.

Below, specific cyclic groups represented by the above formulae (3-1) to (3-4) will be illustrated. Note here that “Ac” in the formulae represents an acetyl group.

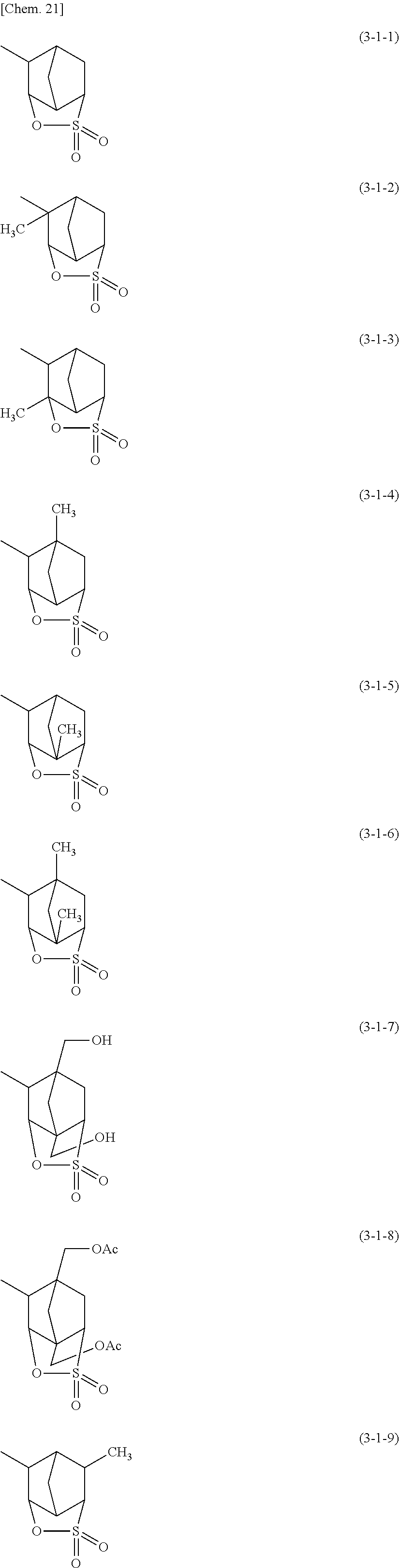

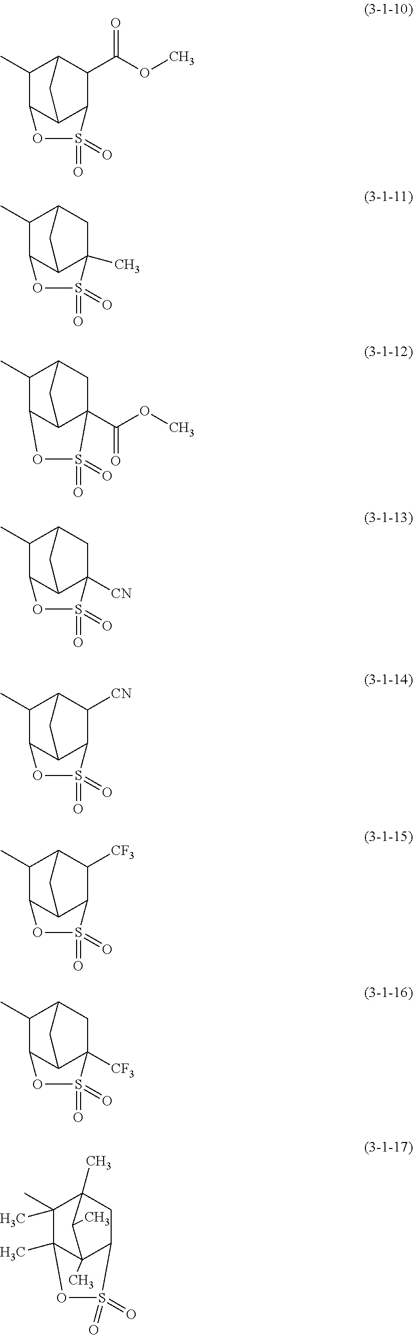

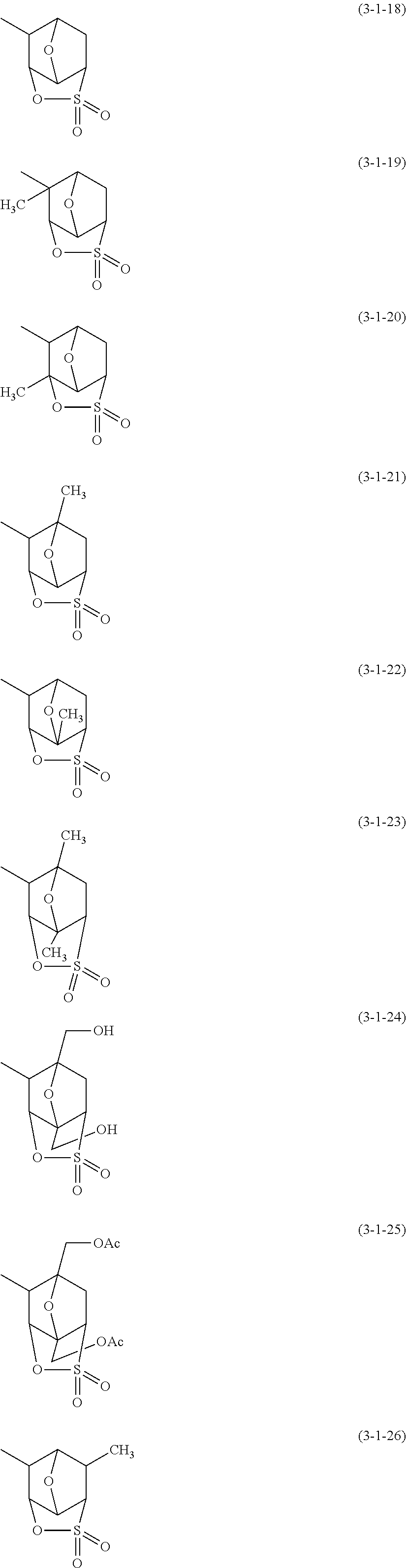

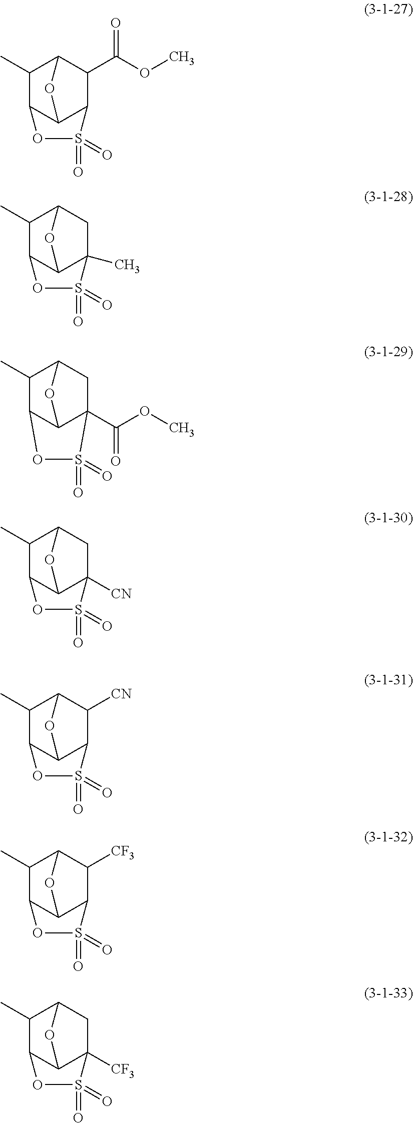

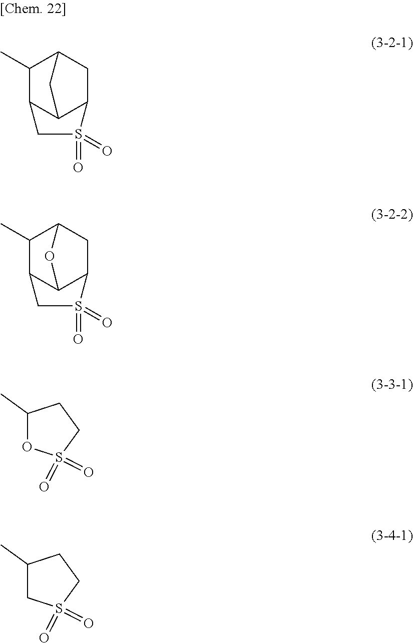

As the —SO₂-containing cyclic group, among those shown above, a group represented by the above formula (3-1) is preferred, and at least one selected from the group consisting of the groups represented by any of the aforementioned formulae (3-1-1), (3-1-18), (3-3-1) and (3-4-1) is more preferred, and a group represented by the aforementioned formula (3-1-1) is most preferred.

### (Lactone-Containing Cyclic Group)

The “lactone-containing cyclic group” refers to a cyclic group containing a ring (lactone ring) including —O—C(═O)— in the ring skeleton thereof. Considering the lactone ring as the first ring, a group having that lactone ring alone is called a monocyclic group, and a group further having another ring structure is called a polycyclic group regardless of its structure. The lactone-containing cyclic group may be a monocyclic group, or may be a polycyclic group.

There is no particular limitation on the lactone cyclic group in the constituent unit (b-3), and any cyclic group can be used. Specifically, examples of the lactone-containing monocyclic groups include a group in which one hydrogen atom is removed from 4 to 6 membered ring lactone, for example, a group in which one hydrogen atom is removed from β-propiono lactone, a group in which one hydrogen atom is removed from γ-butyrolactone, a group in which one hydrogen atom is removed from δ-valerolactone and the like. Further, lactone-containing polycyclic groups include a group in which one hydrogen atom is removed from bicycloalkane, tricycloalkane and tetracycloalkane having a lactone ring.

As to the constituent unit (b-3), as long as the constituent unit (b-3) has an —SO₂-containing cyclic group or a lactone-containing cyclic group, the structures of other parts are not particularly limited. A preferred constituent unit (b-3) is at least one constituent unit selected from the group consisting of a constituent unit (b-3-S) derived from an acrylic acid ester including an —SO₂-containing cyclic group in which a hydrogen atom attached to the carbon atom in the α position may be substituted with a substituent; and a constituent unit (b-3-L) derived from an acrylic acid ester including a lactone-containing cyclic group in which the hydrogen atom attached to the carbon atom in the α position may be substituted with a substituent.

[Constituent Unit (b-3-S)]

More specifically, examples of the constituent unit (b-3-S) include one represented by the following formula (b-S1).

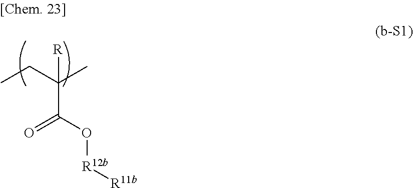

(In the formula, R represents a hydrogen atom, an alkyl group having 1 or more 5 or less carbon atoms or a halogenated alkyl group having 1 or more 5 or less carbon atoms; and R^{11b} represents an —SO₂-containing cyclic group; and R^{12b} represents a single-bond or divalent linking group.)

In the formula (b-S1), R is similarly defined as above. R^{11b} is similarly defined as in the —SO₂-containing cyclic group described above. R^{12b} may be either a single-bond linking group or a divalent linking group.

There is no particular limitation on the divalent linking group in R^{12b}, and suitable groups include an optionally substituted divalent hydrocarbon group, a divalent linking group including a heteroatom, and the like.

### Optionally Substituted Divalent Hydrocarbon Group

The hydrocarbon group as a divalent linking group may be an aliphatic hydrocarbon group, or may be an aromatic hydrocarbon group. The aliphatic hydrocarbon group means a hydrocarbon group without aromaticity. The above aliphatic hydrocarbon group may be saturated or may be unsaturated. Usually, a saturated hydrocarbon group is preferred. More specifically, examples of the above aliphatic hydrocarbon group include a linear or branched aliphatic hydrocarbon group, an aliphatic hydrocarbon group including a ring in the structure thereof and the like.

The number of carbon atoms in the linear or branched aliphatic hydrocarbon group is preferably 1 or more and 10 or less, more preferably 1 or more and 8 or less, and even more preferably 1 or more and 5 or less.

As the linear aliphatic hydrocarbon group, a linear alkylene group is preferred. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like.

As the branched aliphatic hydrocarbon group, a branched alkylene group is preferred. Specific examples include alkyl alkylene groups such as alkyl methylene groups such as —CH(CH₃)—, —CH(CH₂CH₃)—, —C(CH₃)₂—, —C(CH₃) (CH₂CH₃)—, —C(CH₃) (CH₂CH₂CH₃)— and —C(CH₂CH₃)₂—; alkyl ethylene groups such as —CH(CH₃) CH₂—, —CH(CH₃) CH(CH₃)—, —C(CH₃)₂CH₂—, —CH(CH₂CH₃) CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃)CH₂CH₂—; and the like. As an alkyl group in the alkyl alkylene group, a linear alkyl group having 1 or more and 5 or less carbon atoms is preferred.

The above linear or branched aliphatic hydrocarbon group may or may not have a substituent (a group or atom other than a hydrogen atom) which substitutes a hydrogen atom. Examples of the substituent include a fluorine atom, a fluorinated alkyl group having 1 or more and 5 or less carbon atoms substituted with a fluorine atom, an oxo group (═O) and the like.

Examples of the above aliphatic hydrocarbon group including a ring in the structure thereof include a cyclic aliphatic hydrocarbon group optionally including a hetero atom in the ring structure (a group in which two hydrogen atoms are removed from an aliphatic hydrocarbon ring); a group in which the above cyclic aliphatic hydrocarbon group is attached to an end of a linear or branched aliphatic hydrocarbon group; a group in which the above cyclic aliphatic hydrocarbon group is present in a linear or branched aliphatic hydrocarbon group along the chain; and the like. Examples of the above linear or branched aliphatic hydrocarbon group include those similar to the above.

The number of carbon atoms in the cyclic aliphatic hydrocarbon group is preferably 3 or more and 20 or less, and more preferably 3 or more and 12 or less.

The cyclic aliphatic hydrocarbon group may be polycyclic, or may be monocyclic. As the monocyclic aliphatic hydrocarbon group, a group in which two hydrogen atoms are removed from monocycloalkane is preferred. The number of carbon atoms in the above monocycloalkane is preferably 3 or more and 6 or less. Specific examples include cyclopentane, cyclohexane and the like. As the polycyclic aliphatic hydrocarbon group, a group in which two hydrogen atoms are removed from polycycloalkane is preferred. The number of carbon atoms in the above polycycloalkane is preferably 7 or more and 12 or less. Specific examples include adamantane, norbornane, isobornane, tricyclodecane, tetracyclododecane and the like.

The cyclic aliphatic hydrocarbon group may or may not have a substituent which substitutes a hydrogen atom (a group or atom other than a hydrogen atom). Examples of the above substituent include an alkyl group, an alkoxy group, a halogen atom, a halogenated alkyl group, a hydroxyl group, an oxo group (═O) and the like.

For an alkyl group as the above substituent, an alkyl group having 1 or more and 5 or less carbon atoms is preferred, and a methyl group, an ethyl group, a propyl group, an n-butyl group and a tert-butyl group are more preferred.

For an alkoxy group as the above substituent, an alkoxy group having 1 or more and 5 or less carbon atoms is preferred, and a methoxy group, an ethoxy group, an n-propoxy group, an iso-propoxy group, an n-butoxy group and a tert-butoxy group are more preferred, and a methoxy group and an ethoxy group are particularly preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is (are) substituted with the above halogen atom(s).

In the cyclic aliphatic hydrocarbon group, a part of carbon atoms constituting the ring structure thereof may be substituted with —O—, or —S—. As the substituent including the above hetero atom, preferred are —O—, —C(═O)—O—, —S—, —S(═O)₂—and —S(═O)₂—O—.

The aromatic hydrocarbon group as the divalent hydrocarbon group is a divalent hydrocarbon group having at least one aromatic ring, and may have a substituent. There is no particular limitation on the aromatic ring as long as it is a cyclic conjugated system having a 4n+2 π electrons, and it may be monocyclic or may be polycyclic. The number of carbon atoms in the aromatic ring is preferably 5 or more and 30 or less, more preferably 5 or more and 20 or less, further more preferably 6 or more and 15 or less, and particularly preferably 6 or more and 12 or less. However, the number of carbon atoms in a substituent shall not be included in the above number of carbon atoms.

Specifically, aromatic rings include aromatic hydrocarbon rings such as benzene, naphthalene, anthracene and phenanthrene; aromatic heterocycles in which a part of the carbon atoms constituting the above aromatic hydrocarbon ring is(are) substituted with hetero atom(s). Hetero atoms in the aromatic heterocycle include an oxygen atom, a sulfur atom, a nitrogen atom and the like. Specifically, aromatic heterocycles include a pyridine ring, a thiophene ring, and the like.

Specific examples of the aromatic hydrocarbon group as a divalent hydrocarbon group include a group in which two hydrogen atoms are removed from the above aromatic hydrocarbon ring or the above aromatic heterocycle (an arylene group or a heteroarylene group); a group in which two hydrogen atoms are removed from an aromatic compound including two or more aromatic rings (for example, biphenyl, fluorene and the like); a group in which one hydrogen atom from a group where one hydrogen atom is removed from the above aromatic hydrocarbon ring or the above aromatic heterocycle (an aryl group or a heteroaryl group) is substituted with an alkylene group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group and a 2-naphthylethyl group); and the like.

The number of carbon atoms in the above alkylene group bonded to an aryl group or a heteroaryl group is preferably 1 or more and 4 or less, more preferably 1 or more and 2 or less, and particularly preferably 1.

In the above aromatic hydrocarbon group, a hydrogen atom of the above aromatic hydrocarbon group may be substituted with a substituent. For example, a hydrogen atom attached to an aromatic ring in the above aromatic hydrocarbon group may be substituted with a substituent. Examples of the substituent include an alkyl group, an alkoxy group, a halogen atom, a halogenated alkyl group, a hydroxyl group, an oxo group (═O) and the like.

For an alkyl group as the above substituent, an alkyl group having 1 or more and 5 or less carbon atoms is preferred, and a methyl group, an ethyl group, an n-propyl group, an n-butyl group and a tert-butyl group are more preferred.

For an alkoxy group as the above substituent, an alkoxy group having 1 or more and 5 or less carbon atoms is preferred, and a methoxy group, an ethoxy group, an n-propoxy group, an iso-propoxy group, an n-butoxy group and a tert-butoxy group are preferred, and a methoxy group and an ethoxy group are more preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is (are) substituted with the above halogen atom(s).

### Divalent Linking Group Including Hetero Atom

A hetero atom in the divalent linking group including a hetero atom is an atom other than a carbon atom and a hydrogen atom, and examples thereof include an oxygen atom, a nitrogen atom, a sulfur atom, a halogen atom and the like.

Specific examples of the divalent linking group including a hetero atom include non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)—, ═N—, and combinations of at least one of these non-hydrocarbon based linking groups and a divalent hydrocarbon group and the like. Examples of the above divalent hydrocarbon group include those similar to the aforementioned divalent hydrocarbon groups optionally having a substituent, and linear or branched aliphatic hydrocarbon groups are preferred.

Among those described above, —NH— in —C(═O)—NH—, and H in —NH— and —NH—C(═NH)— may be substituted with a substituent such as an alkyl group or an acyl group, respectively. The number of carbon atoms in the above substituent is preferably 1 or more and 10 or less, more preferably 1 or more and 8 or less, and in particular preferably 1 or more and 5 or less.

As a divalent linking group in R^{12b}, a linear or branched alkylene group, a cyclic aliphatic hydrocarbon group, or a divalent linking group including a hetero atom is preferred.

In a case where the divalent linking group in R^{12b} is a linear or branched alkylene group, the number of carbon atoms in the above alkylene group is preferably 1 or more and 10 or less, more preferably 1 or more and 6 or less, in particular preferably 1 or more and 4 or less, and most preferably 1 or more and 3 or less. Specific examples include groups similar to the linear alkylene groups or branched alkylene groups recited as a linear and branched aliphatic hydrocarbon group in the description of the “divalent hydrocarbon group optionally having a substituent” as the aforementioned divalent linking group.

In a case where the divalent linking group in R^{12b} is a cyclic aliphatic hydrocarbon group, examples of the above cyclic aliphatic hydrocarbon group include groups similar to those recited as the “aliphatic hydrocarbon group including a ring in the structure” in the description of the “divalent hydrocarbon group optionally having a substituent” as the aforementioned divalent linking group.

As the above cyclic aliphatic hydrocarbon group, particularly preferred is a group in which two or more hydrogen atoms are removed from cyclopentane, cyclohexane, norbornane, isobornane, adamantane, tricyclodecane or tetracyclododecane.

In a case where the divalent linking group in R^{12b} is a divalent linking group including a hetero atom, groups preferred as the above linking groups include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O— and a group represented by the general formula —Y¹—O—Y²—, —[Y¹—C(═O)—O]_{m′}—Y²— or —Y¹—O—C(═O)—Y₂-[wherein Y¹ and Y² are divalent hydrocarbon groups each independently, optionally having a substituent, and O represents an oxygen atom, and m′ is an integer of 0 or more and 3 or less].

In a case where the divalent linking group in R^{12b} is —NH—, the hydrogen atom in —NH— may be substituted with a substituent such as an alkyl group or an acyl group. The number of carbon atoms in the above substituent (an alkyl group, an acyl group and the like) is preferably 1 or more and 10 or less, more preferably 1 or more and 8 or less, and in particular preferably 1 or more and 5 or less.

Y¹ and Y² in the formula Y¹—O—Y²—, —[Y¹—C(═O)—O]_{m′}—Y²— or —Y¹—O—C(═O)—Y²— are divalent hydrocarbon groups each independently, optionally having a substituent. Examples of the above divalent hydrocarbon group include groups similar to the “divalent hydrocarbon group optionally having a substituent” recited in the description of the above divalent linking group.

As Y¹, a linear aliphatic hydrocarbon group is preferred, and a linear alkylene group is more preferred, and a linear alkylene group having 1 or more and 5 or less carbon atoms is more preferred, and a methylene group and an ethylene group are particularly preferred.

As Y², a linear or branched aliphatic hydrocarbon group is preferred, and a methylene group, an ethylene group and an alkylmethylene group are more preferred. The alkyl group in the above alkylmethylene group is preferably a linear alkyl group having 1 or more and 5 or less carbon atoms, more preferably a linear alkyl group having 1 or more and 3 or less carbon atoms, and particularly preferably a methyl group.

In a group represented by the formula —[Y¹—C(═O)—O]_{m′}—Y²—, m′ is an integer of 0 or more and 3 or less, preferably an integer of 0 or more and 2 or less, more preferably 0 or 1, and particularly preferably 1. In other words, as a group represented by the formula —[Y¹—C(═O)—O]_{m′}—Y²— a group represented by the formula —Y¹—C(═O)—O—Y²— is particularly preferred. Among these, a group represented by the formula —(CH₂)_{a′}—C(═O)—O—(CH₂)_{b′}— is preferred. In the above formula, a′ is an integer of 1 or more and 10 or less, preferably an integer of 1 or more and 8 or less, more preferably an integer of 1 or more and 5 or less, even more preferably 1 or 2, and most preferably 1. b′ is an integer of 1 or more and 10 or less, preferably an integer of 1 or more and 8 or less, more preferably an integer of 1 or more and 5 or less, even more preferably 1 or 2, and most preferably 1.

With regard to the divalent linking group in R^{12b}, an organic group including a combination of at least one non-hydrocarbon group and a divalent hydrocarbon group is preferred as the divalent linking group including a hetero atom. Among these, a linear chain group having an oxygen atom as a hetero atom, for example, a group including an ether bond or an ester bond is preferred, and a group represented by the aforementioned formula —Y¹—O—Y²—, —[Y¹—C(═O)—O]_{m′}—Y²— or —Y¹—O—C(═O)—Y²— is more preferred, and a group represented by the aforementioned formula —[Y¹—C(═O)—O]_{m′}—Y²— or —Y¹—O—C(═O)—Y²— is particularly preferred.

As the divalent linking group in R^{12b}, a group including an alkylene group or an ester bond (—C(═O)—O—) is preferred.

The above alkylene group is preferably a linear or branched alkylene group. Suitable examples of the above linear aliphatic hydrocarbon group include a methylene group [—CH₂—], an ethylene group [—(CH₂)₂—], a trimethylene group [—(CH₂)₃—], a tetramethylene group [—(CH₂)₄—], a pentamethylene group [—(CH₂)₅-] and the like. Suitable examples of the above branched alkylene group include alkyl alkylene groups such as alkyl methylene groups such as —CH(CH₃)—, —CH(CH₂CH₃)—, —C(CH₃)₂—, —C(CH₃) (CH₂CH₃)—, —C(CH₃) (CH₂CH₂CH₃)— and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃) CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃) CH₂CH₂—.

As the divalent linking group including an ester bond, particularly preferred is a group represented by the formula: —R^{13b}—C(═O)—O—[wherein R^{13b} represents a divalent linking group]. In other words, the constituent unit (b-3-S) is preferably a constituent unit represented by the following formula (b-S1-1).

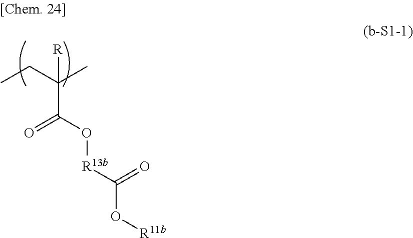

(In the formula, R and R^{11b} are each similar to the above, and R^{13b} represents a divalent linking group.)

There is no particular limitation for R^{13b}, examples thereof include groups similar to the aforementioned divalent linking group in R^{12b}. As the divalent linking group in R^{13b}, a linear or branched alkylene group, an aliphatic hydrocarbon group including a ring in the structure, or a divalent linking group including a hetero atom is preferred, and a linear or branched alkylene group or a divalent linking group including an oxygen atom as a hetero atom is preferred.

As the linear alkylene group, a methylene group or an ethylene group is preferred, and a methylene group is particularly preferred. As the branched alkylene group, an alkylmethylene group or an alkylethylene group is preferred, and —CH(CH₃)—, —C(CH₃)₂— or —C(CH₃)₂CH₂— is particularly preferred.

As the divalent linking group including an oxygen atom, a divalent linking group including an ether bond or an ester bond is preferred, and the aforementioned —Y¹—O—Y²—, —[Y¹—C(═O)—O]_{m′}—Y²— or —Y¹—O—C(═O)—Y²— is more preferred. Y¹ and Y² are each independently divalent hydrocarbon groups optionally having a substituent, and m′ is an integer of 0 or more and 3 or less. Among these, —Y¹—O—C(═O)—Y²— is preferred, and a group represented by —(CH₂)_{c}—O—C(═O)—(CH₂)_{d}— is particularly preferred. c is an integer of 1 or more and 5 or less, and 1 or 2 is preferred. d is an integer of 1 or more and 5 or less, and 1 or 2 is preferred.

As the constituent unit (b-3-S), in particular, one represented by the following formula (b-S1-11) or (b-S1-12) is preferred, and one represented by the formula (b-S1-12) is more preferred.

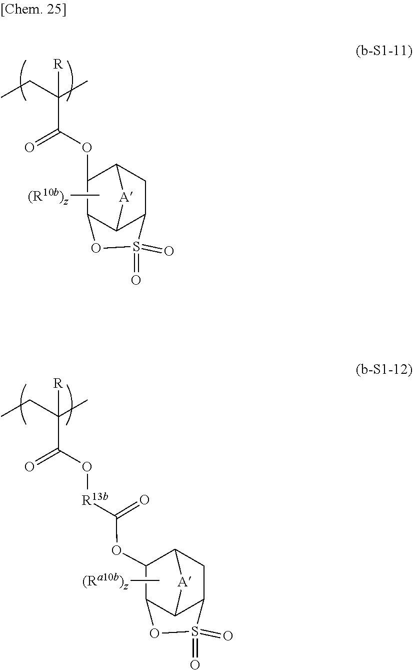

(In the formulae, R, A′, R^{10b}, z and R^{13b} are each the same as the above.)

In the formula (b-S1-11), A′ is preferably a methylene group, an oxygen atom (—O—) or a sulfur atom (—S—).

As R^{13b}, preferred is a linear or branched alkylene group or a divalent linking group including an oxygen atom. Examples of the linear or branched alkylene group and the divalent linking group including an oxygen atom in R^{13b} include those similar to the aforementioned linear or branched alkylene group and the aforementioned divalent linking group including an oxygen atom, respectively.

As the constituent unit represented by the formula (b-S1-12), particularly preferred is one represented by the following formula (b-S1-12a) or (b-S1-12b).

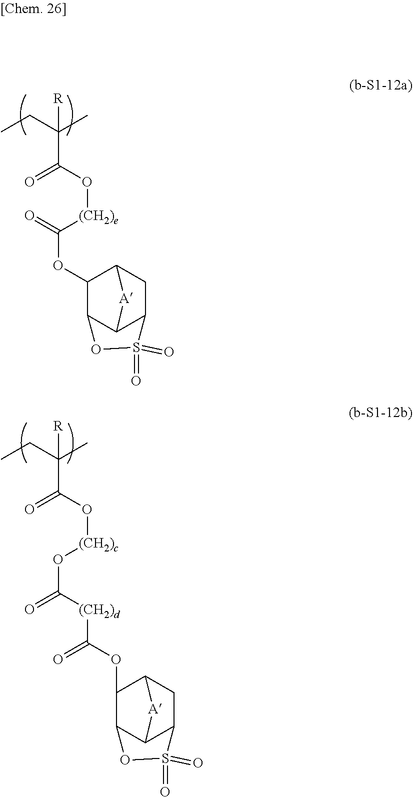

(In the formulae, R and A′ are each the same as the above, and c to e are each independently an integer of 1 or more and 3 or less.)
[Constituent Unit (b-3-L)]

Examples of the constituent unit (b-3-L) include, for example, a constituent unit in which R^{11b} in the aforementioned formula (b-S1) is substituted with a lactone-containing cyclic group. More specifically they include those represented by the following formulae (b-L1) to (b-L5).

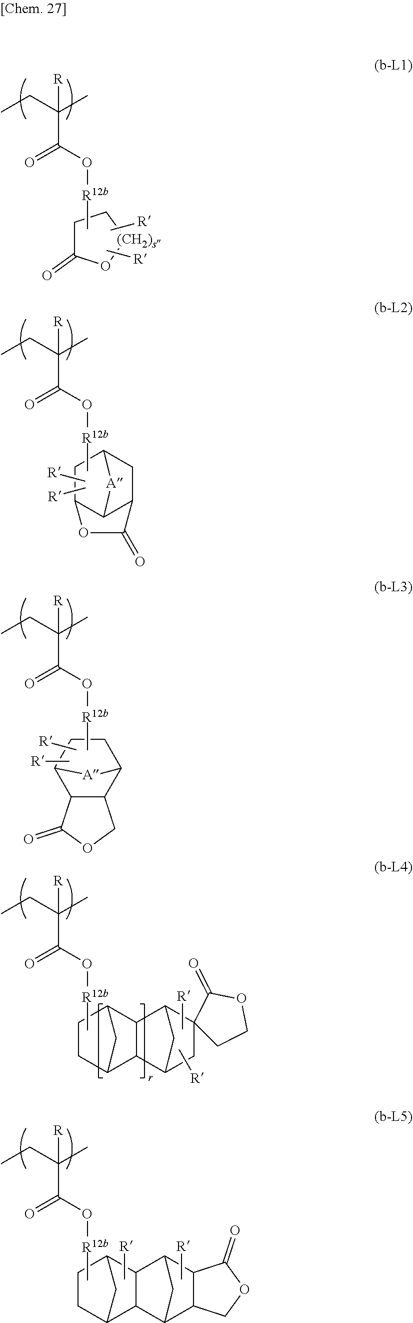

(In the formulae, R represents a hydrogen atom, an alkyl group having 1 or more and 5 or less carbon atoms or a halogenated alkyl group having 1 or more and 5 or less carbon atoms; R′ represents each independently a hydrogen atom, an alkyl group, an alkoxy group, a halogenated alkyl group, a hydroxyl group, —COOR″, —OC(═O)RR″, a hydroxyalkyl group or a cyano group, and R″ represents a hydrogen atom or an alkyl group; R^{12b} represents a single bond or divalent linking group, and s″ is an integer of 0 or more and 2 or less; A″ represents an alkylene group having 1 or more and 5 or less carbon atoms optionally including an oxygen atom or a sulfur atom, an oxygen atom or a sulfur atom; and r is 0 or 1.)

R in the formulae (b-L1) to (b-L5) is the same as the above. Examples of the alkyl group, the alkoxy group, the halogenated alkyl group, —COOR″, —OC(═O)RR″ and the hydroxyalkyl group in R′ include groups similar to those described for the alkyl group, the alkoxy group, the halogenated alkyl group, —COOR″, —OC(═O)RR″ and the hydroxyalkyl group recited as a substituent which the —SO₂— containing cyclic group may have, respectively.

R′ is preferably a hydrogen atom in view of easy industrial availability and the like. The alkyl group in R″ may be any of a linear, branched or cyclic chain. In a case where R″ is a linear or branched alkyl group, the number of carbon atoms is preferably 1 or more and 10 or less, and more preferably 1 or more and 5 or less. In a case where R″ is a cyclic alkyl group, the number of carbon atoms is preferably 3 or more and 15 or less, more preferably 4 or more and 12 or less, and most preferably 5 or more and 10 or less. Specific examples include a group in which one or more hydrogen atoms are removed from monocycloalkane and polycycloalkane such as bicycloalkane, tricycloalkane, tetracycloalkane and the like optionally substituted with a fluorine atom or a fluorinated alkyl group. Specific examples include a group in which one or more hydrogen atoms are removed from monocycloalkane such as cyclopentane and cyclohexane; and polycycloalkane such as adamantane, norbornane, isobornane, tricyclodecane and tetracyclododecane; and the like. Examples of A″ include groups similar to A′ in the aforementioned formula (3-1). A″ is preferably an alkylene group having 1 to 5 carbon atoms, an oxygen atom (—O—) or a sulfur atom (—S—), more preferably an alkylene group having 1 or more and 5 or less carbon atoms or —O—. As the alkylene group having 1 or more and 5 or less carbon atoms, a methylene group or a dimethylmethylene group is more preferred, and a methylene group is most preferred.

R^{12b} is similar to R^{12b} in the aforementioned formula (b-S1). In the formula (b-L1), s″ is preferably 1 or 2. Below, specific examples of the constituent units represented by the aforementioned formulae (b-L1) to (b-L3) will be illustrated. In each of the following formulae, R^{α} represents a hydrogen atom, a methyl group or a trifluoromethyl group.

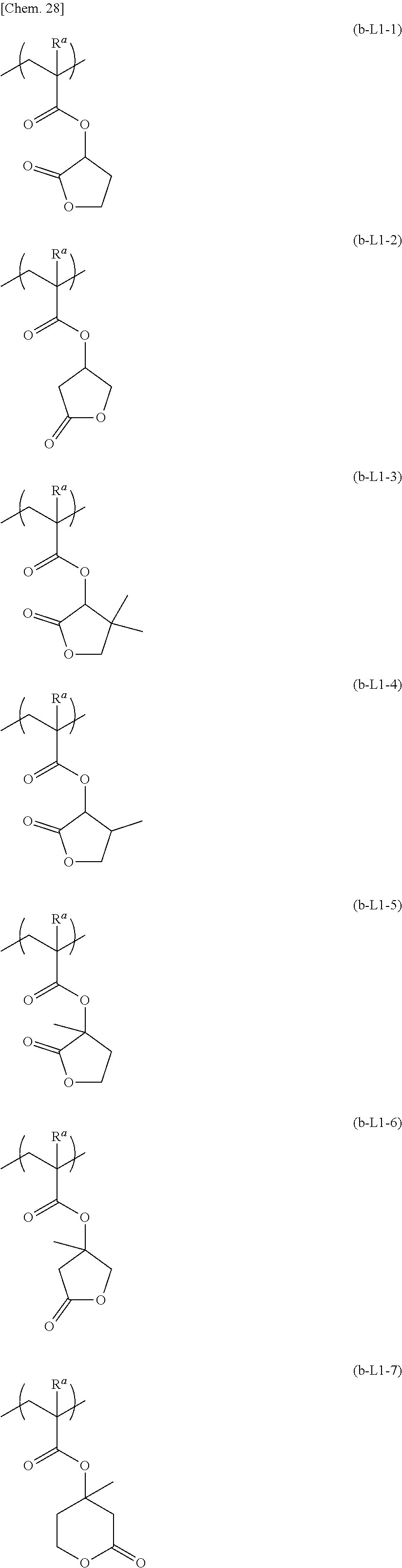

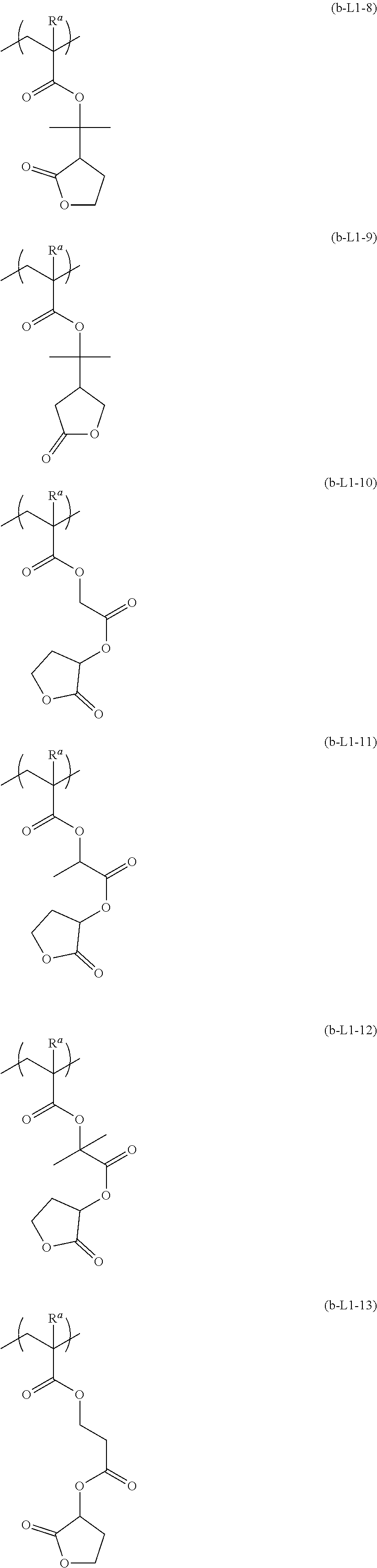

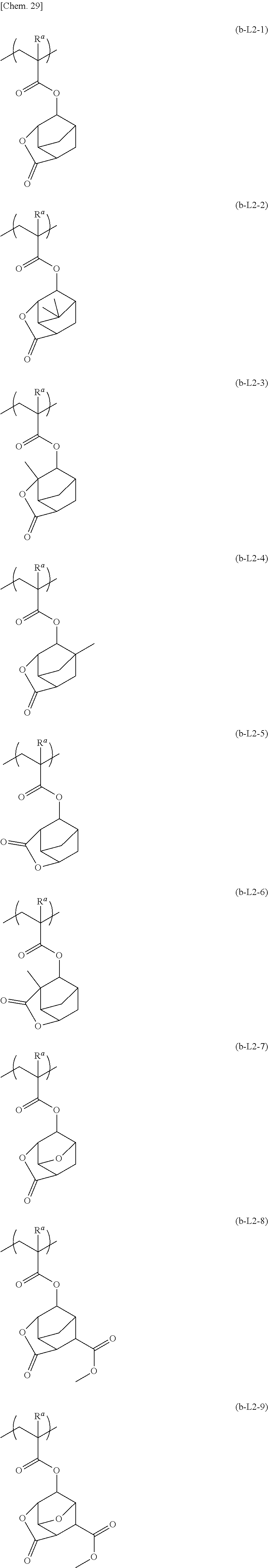

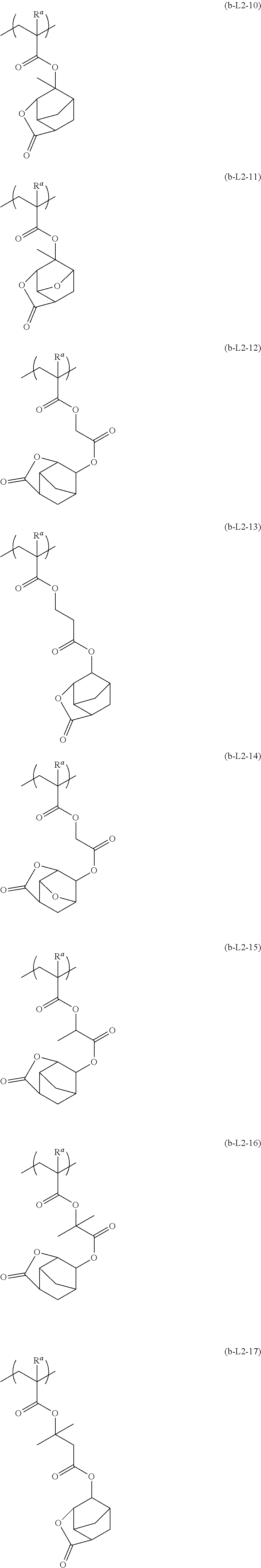

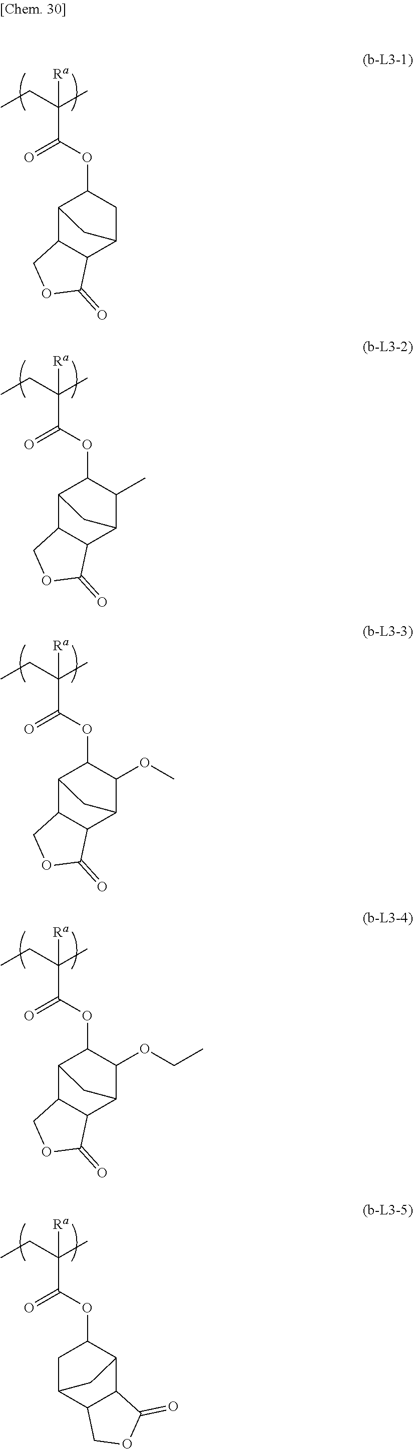

As the constituent unit (b-3a-L), at least one selected from the group consisting of the constituent units represented by the aforementioned formulae (b-L1) to (b-L5) is preferred, and at least one selected from the group consisting of the constituent units represented by the formulae (b-L1) to (b-L3) is more preferred, and at least one selected from the group consisting of the constituent units represented by the aforementioned formula (b-L1) or (b-L3) is particularly preferred. Among these, at least one selected from the group consisting of the constituent units represented by the aforementioned formulae (b-L1-1), (b-L1-2), (b-L2-1), (b-L2-7), (b-L2-12), (b-L2-14), (b-L3-1) and (b-L3-5) is preferred.

Further, as the constituent unit (b-3-L), the constituent units represented by following formulae (b-L6) to (b-L7) are also preferred.

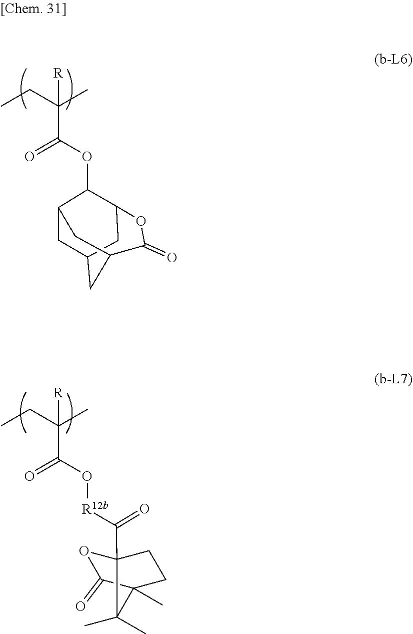

R and R^{12b} in the formulae (b-L6) and (b-L7) are the same as the above.

Further, the acrylic resin (B3) includes constituent units represented by the following formulae (b5) to (b7), having an acid dissociable group, as constituent units that enhance the solubility of the acrylic resin (B3) in alkali under the action of acid.

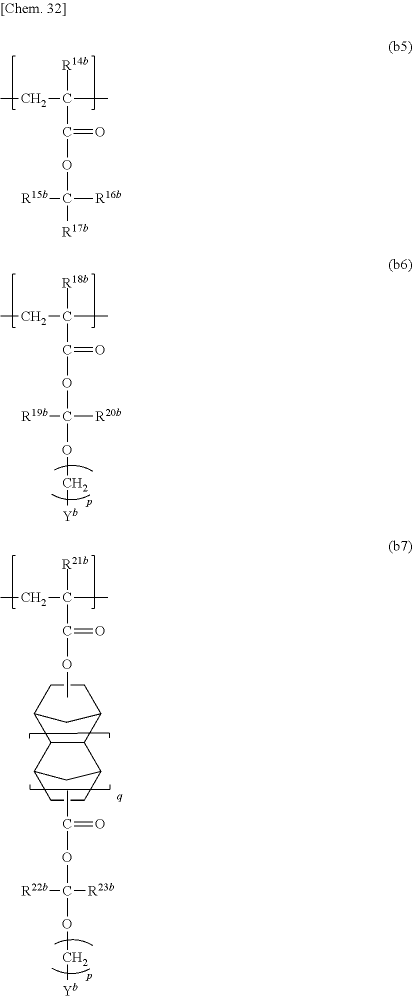

In the above formulae (b5) to (b7), R^{14b} and R^{18b} to R^{23b} each independently represent a hydrogen atom, a linear or branched alkyl group having 1 or more and 6 or less carbon atoms, a fluorine atom, or a linear or branched fluorinated alkyl group having 1 or more and 6 or less carbon atoms; R^{13b} to R^{17b} each independently represent a linear or branched alkyl group having 1 or more and 6 or less carbon atoms, a linear or branched fluorinated alkyl group having 1 or more and 6 or less carbon atoms, or an aliphatic cyclic group having 5 or more and 20 or less carbon atoms; and R^{16b} and R^{17b} may be bonded to each other to form a hydrocarbon ring having 5 or more and 20 or less carbon atoms together with the carbon atom to which both the groups are bonded; Y^{b} represents an optionally substituted aliphatic cyclic group or alkyl group; p is an integer of 0 or more and 4 or less; and q is 0 or 1.

Note here that examples of the linear or branched alkyl group include a methyl group, ethyl group, propyl group, isopropyl group, n-butyl group, isobutyl group, tert-butyl group, pentyl group, isopentyl group, neopentyl group, and the like. Furthermore, the fluorinated alkyl group refers to the abovementioned alkyl groups of which the hydrogen atoms are partially or entirely substituted with fluorine atoms. Specific examples of aliphatic cyclic groups include groups obtained by removing one or more hydrogen atoms from monocycloalkanes or polycycloalkanes such as bicycloalkanes, tricycloalkanes, and tetracycloalkanes. Specifically, groups obtained by removing one hydrogen atom from a monocycloalkane such as cyclopentane, cyclohexane, cycloheptane, or cyclooctane, or a polycycloalkane such as adamantane, norbornane, isobornane, tricyclodecane, or tetracyclododecane may be mentioned. In particular, groups obtained by removing one hydrogen atom from cyclohexane or adamantane (which may further be substituted) are preferred.

When R^{16b} and R^{17b} do not combine with each other to form a hydrocarbon ring, the above R^{15b}, R^{16b}, and R^{17b} represent preferably a linear or branched alkyl group having 1 or more and 4 or less carbon atoms, and more preferably a linear or branched alkyl group having 2 or more and 4 or less carbon atoms, for example, from the viewpoints of a high contrast and favorable resolution and depth of focus. The above R^{19b}, R^{20b}, R^{22b}, and R^{23b} preferably represent a hydrogen atom or a methyl group.

The above R^{16b} and R^{17b} may form an aliphatic cyclic group having 5 or more and 20 or less carbon atoms together with a carbon atom to which the both are attached. Specific examples of such an alicyclic group are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane and polycycloalkanes such as adamantane, norbornane, isobornane, tricyclodecane and tetracyclododecane from which one or more hydrogen atoms are removed. Particularly preferable are the groups of cyclohexane and adamantane from which one or more hydrogen atoms are removed (that may further have a substituent).

Further, in a case where an aliphatic cyclic group to be formed with the above R^{16b} and R^{17b} has a substituent on the ring skeleton thereof, examples of the substituent include a polar group such as a hydroxyl group, a carboxyl group, a cyano group and an oxygen atom (═O), and a linear or branched alkyl group having 1 or more and 4 or less carbon atoms. As the polar group, an oxygen atom (═O) is particularly preferred.

The above Y^{b} is an alicyclic group or an alkyl group; and examples thereof are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane, and polycycloalkanes such as adamantane, norbornane, isobornane, tricyclodecane and tetracyclododecane from which one or more hydrogen atoms are removed. Particularly preferable is the group of adamantane from which one or more hydrogen atoms are removed (that may further have a substituent).

When the alicyclic group of the above Y^{b} has a substituent on the ring skeleton, the substituent is exemplified by polar groups such as a hydroxyl group, carboxyl group, cyano group and oxygen atom (═O), and linear or branched alkyl groups having 1 or more and 4 or less carbon atoms. The polar group is preferably an oxygen atom (═O) in particular.

When Y^{b} is an alkyl group, it is preferably a linear or branched alkyl group having 1 or more and 20 or less carbon atoms, and more preferably 6 or more and 15 or less carbon atoms. The alkyl group is an alkoxyalkyl group particularly preferable. Examples of such an alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferable specific examples of the constituent unit represented by the above formula (b5) include those represented by the following formulae (b5-1) to (b5-33).

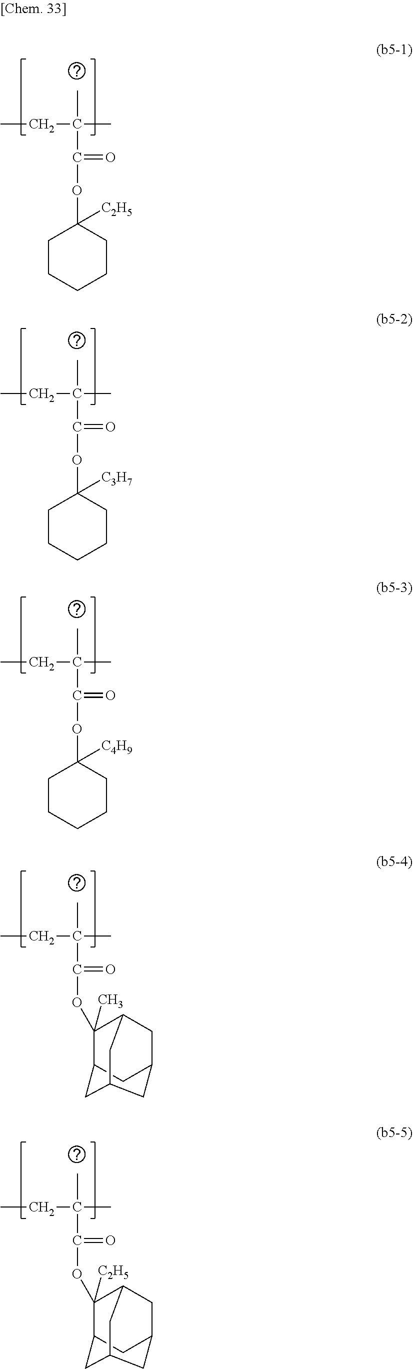

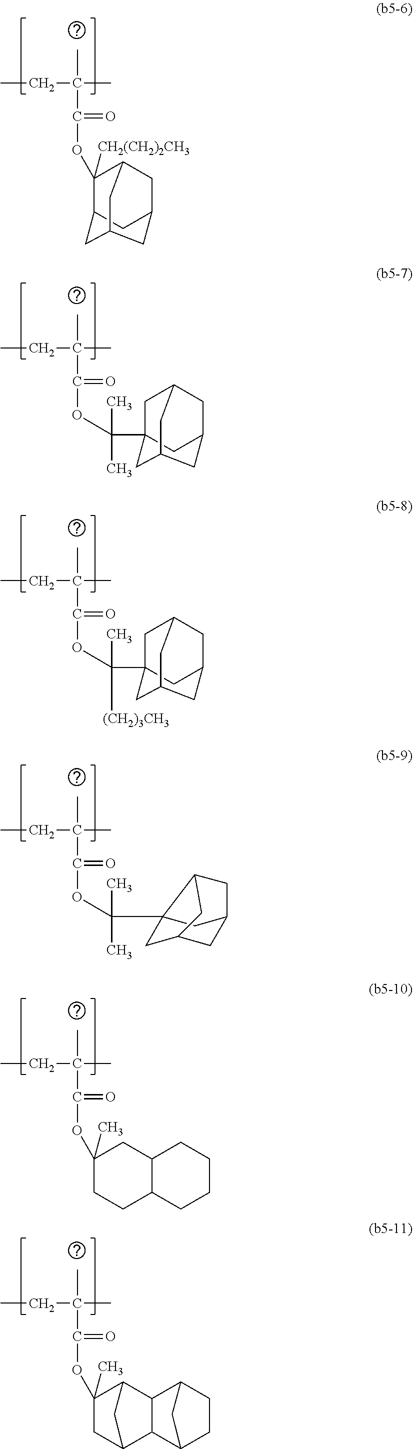

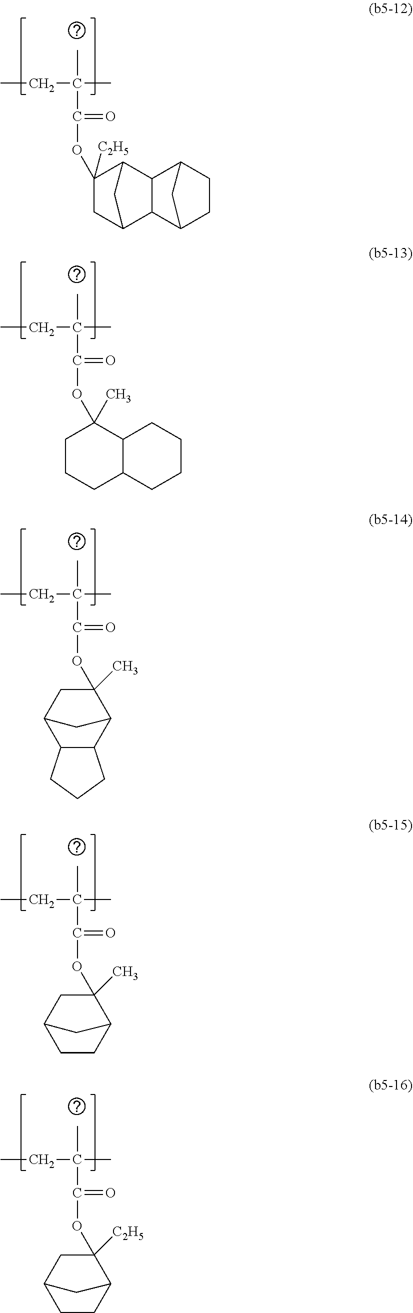

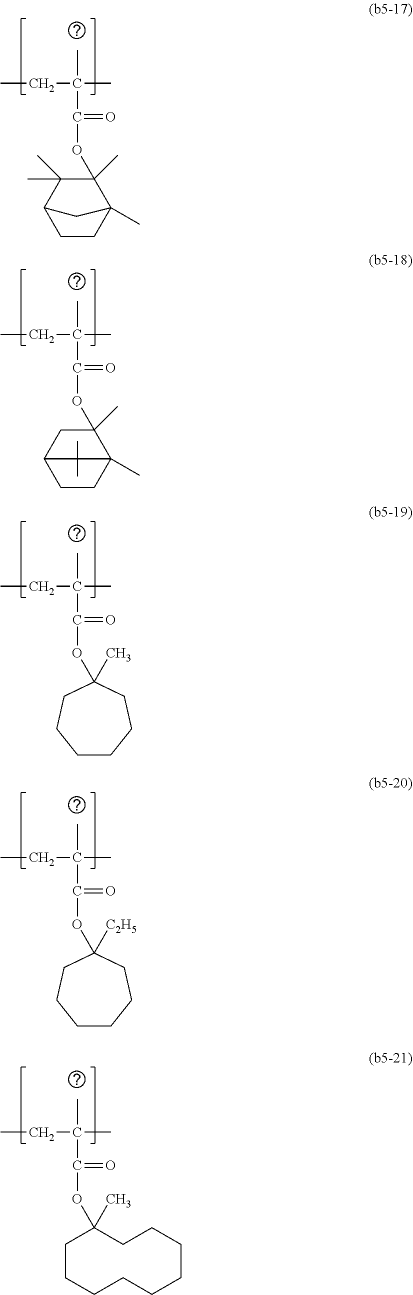

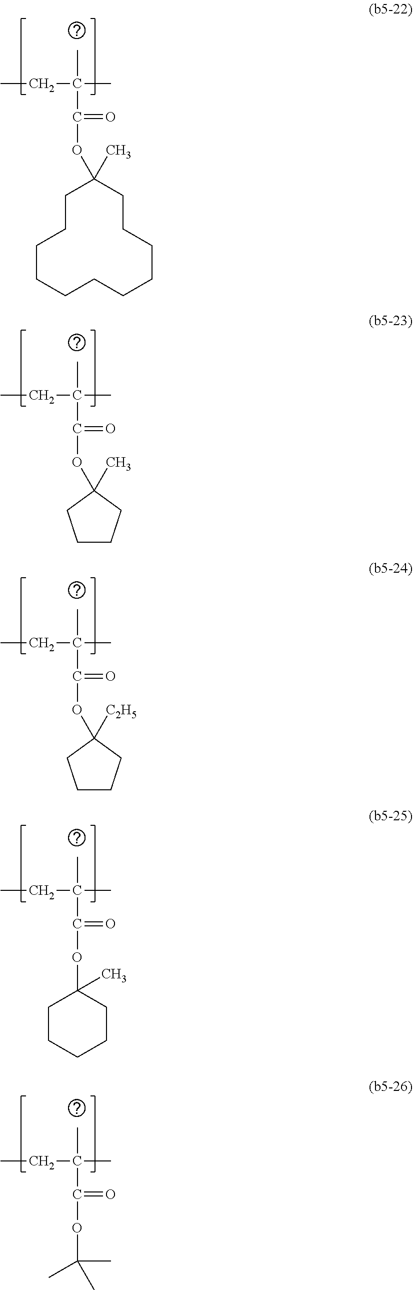

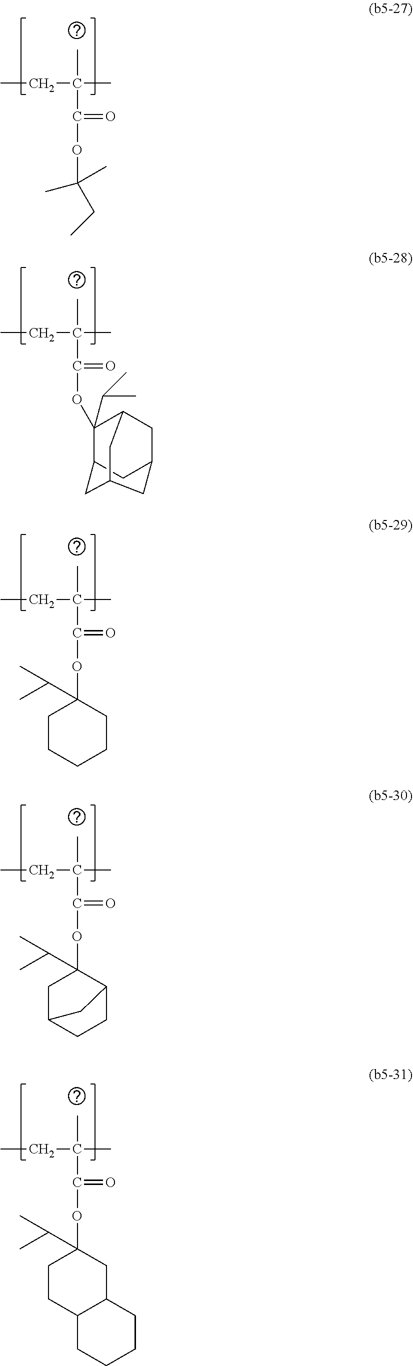

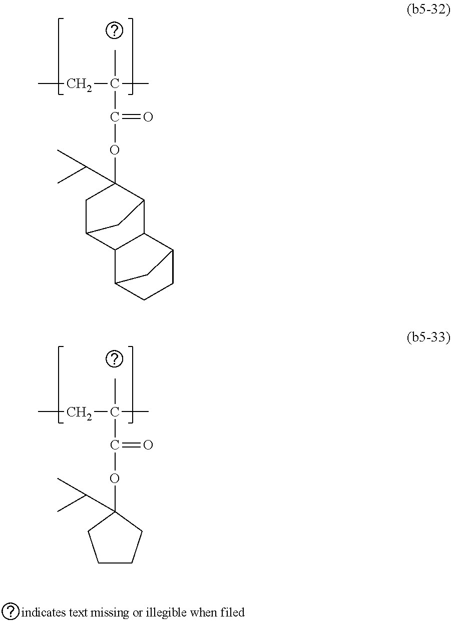

In the above formulae (b5-1) to (b5-33), R^{24b} represents a hydrogen atom or a methyl group.

Preferable specific examples of the constituent unit represented by the above formula (b6) include those represented by the following formulae (b6-1) to (b6-26).

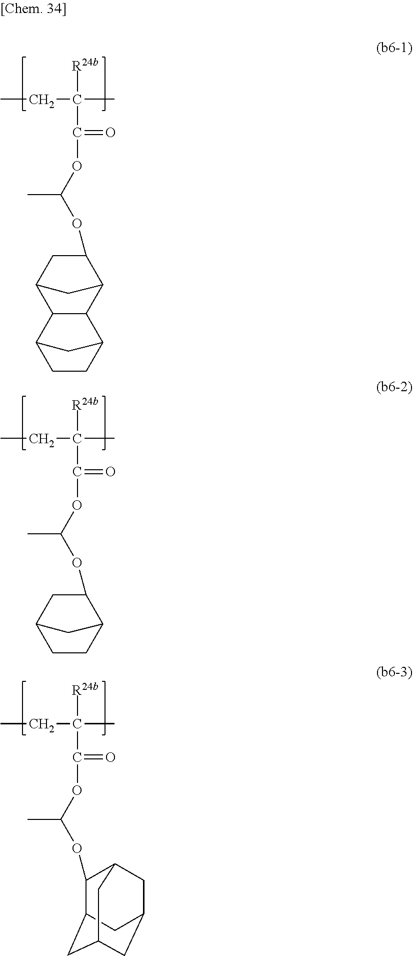

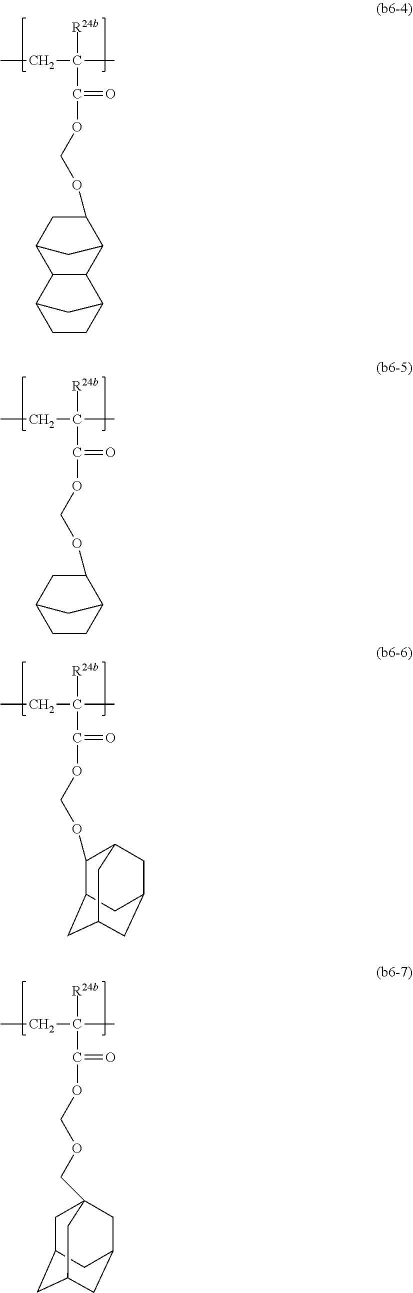

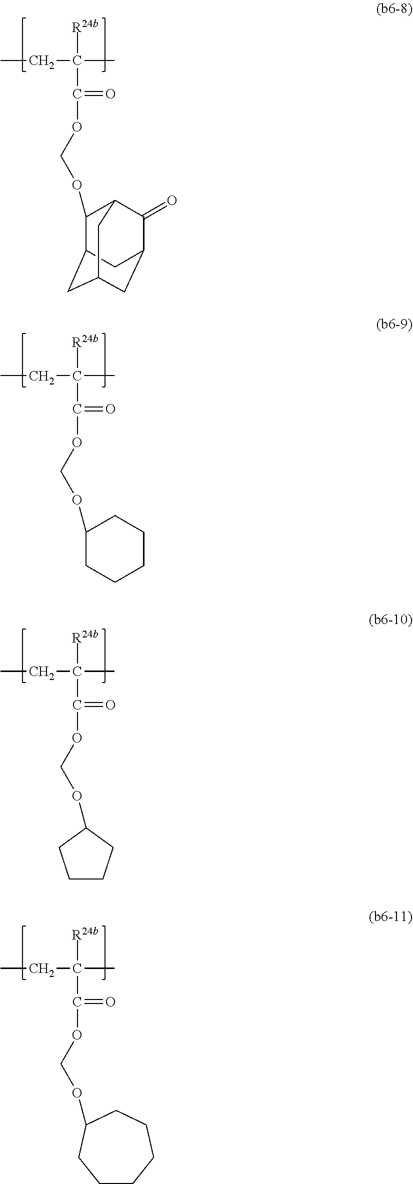

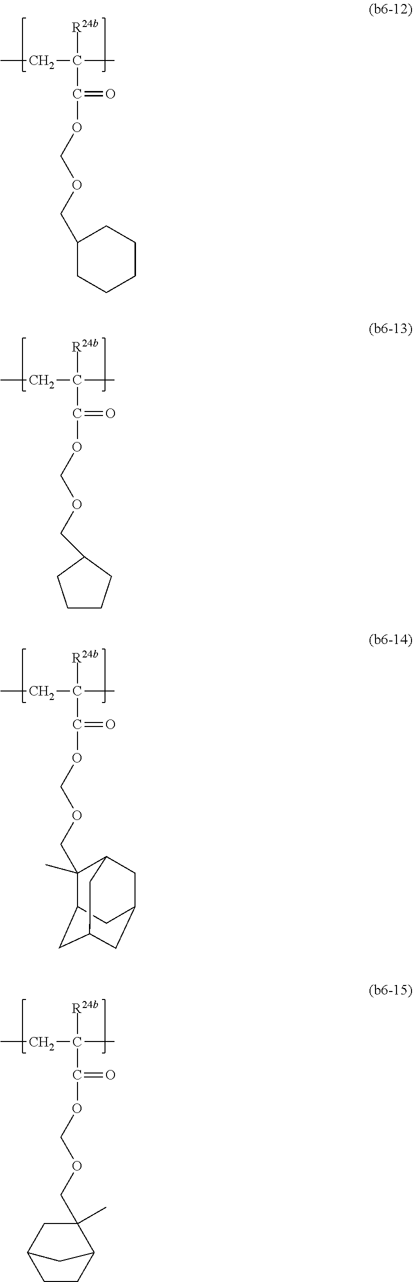

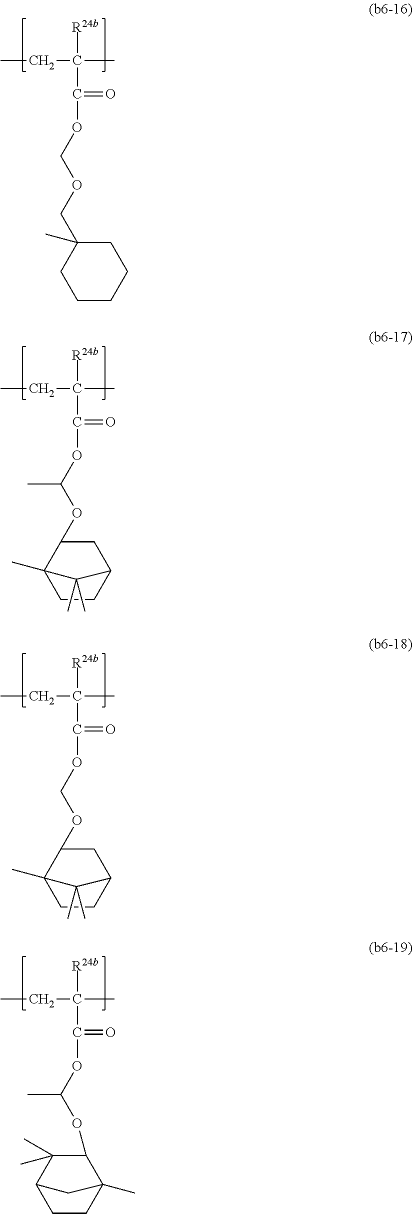

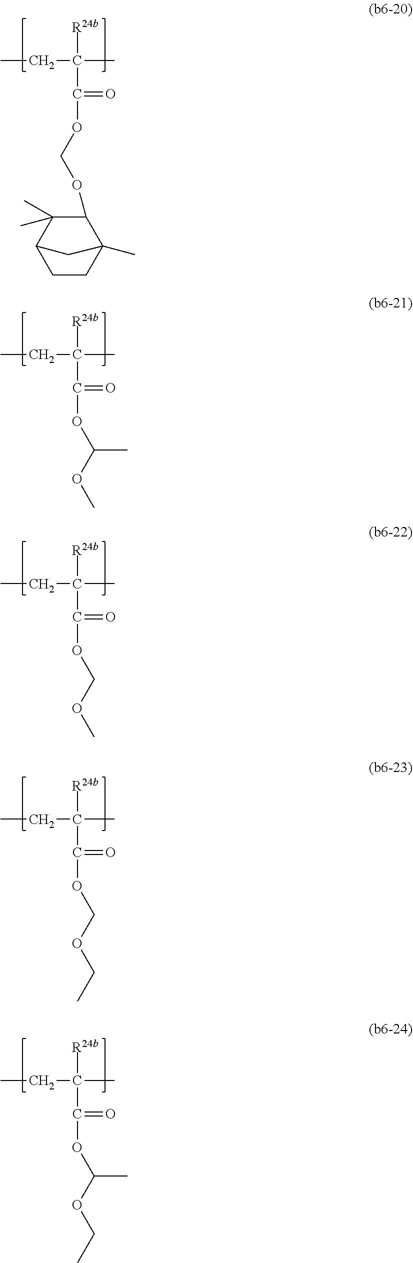

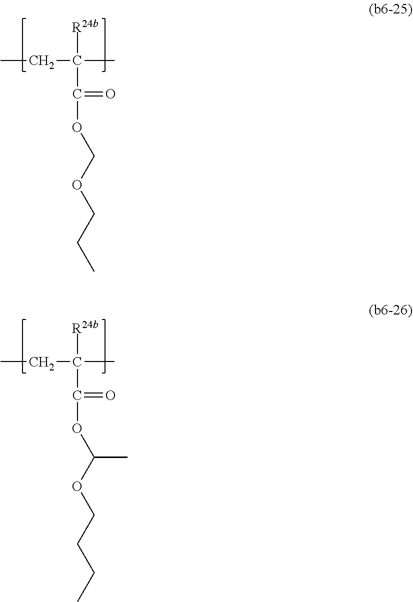

In the above formulae (b6-1) to (b6-26), R^{24b} represents a hydrogen atom or a methyl group.

Preferable specific examples of the constituent unit represented by the above formula (b7) include those represented by the following formulae (b7-1) to (b7-15).

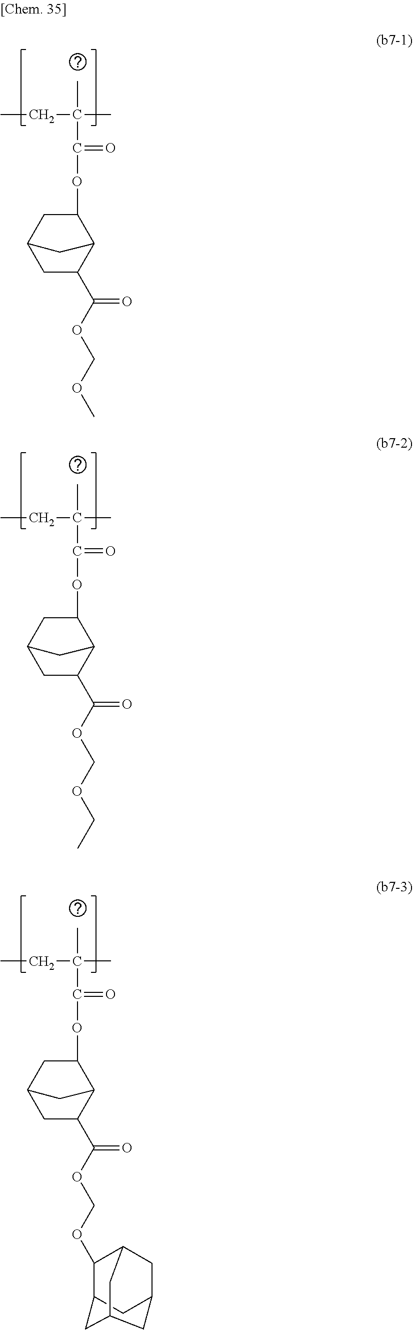

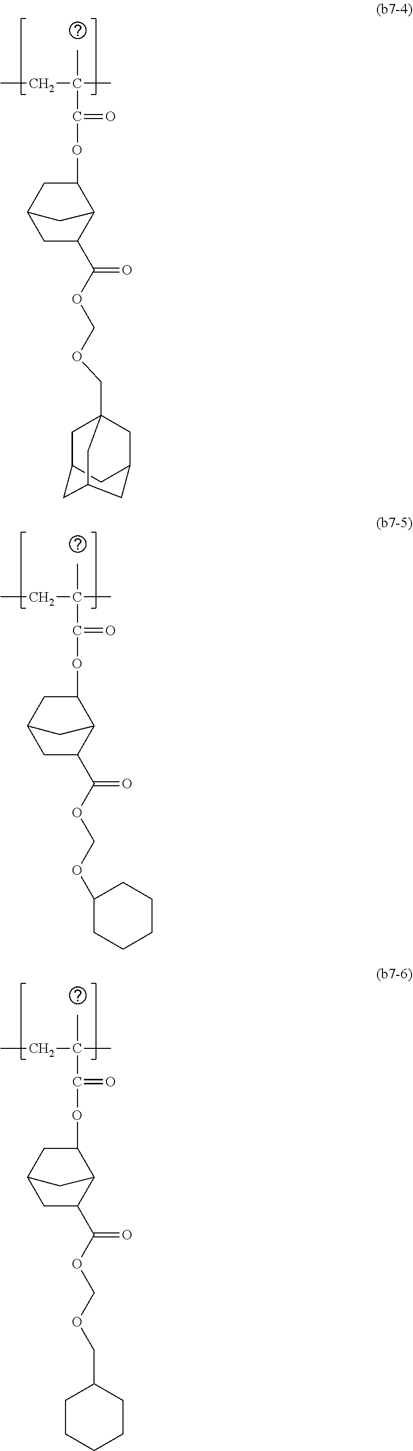

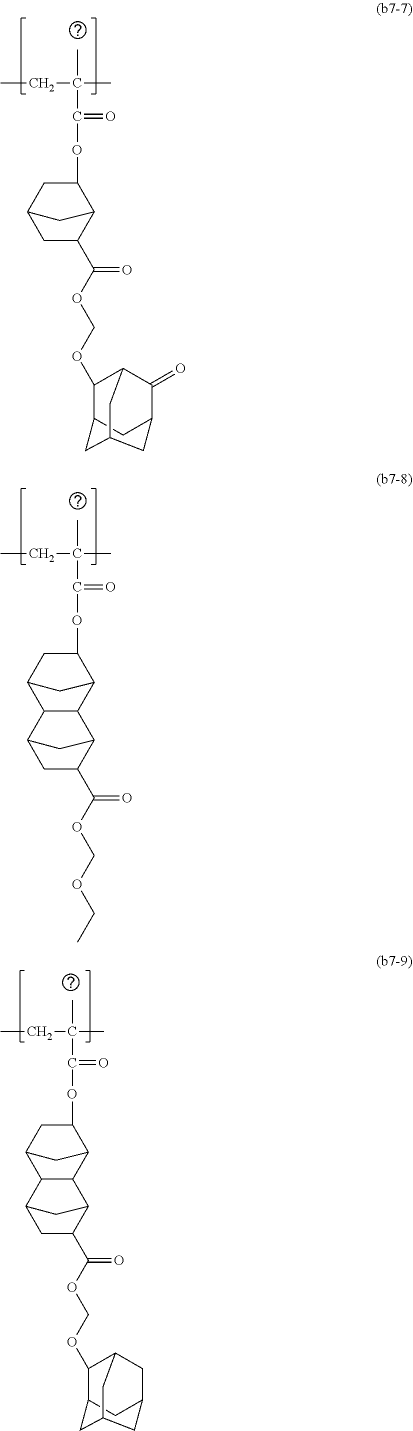

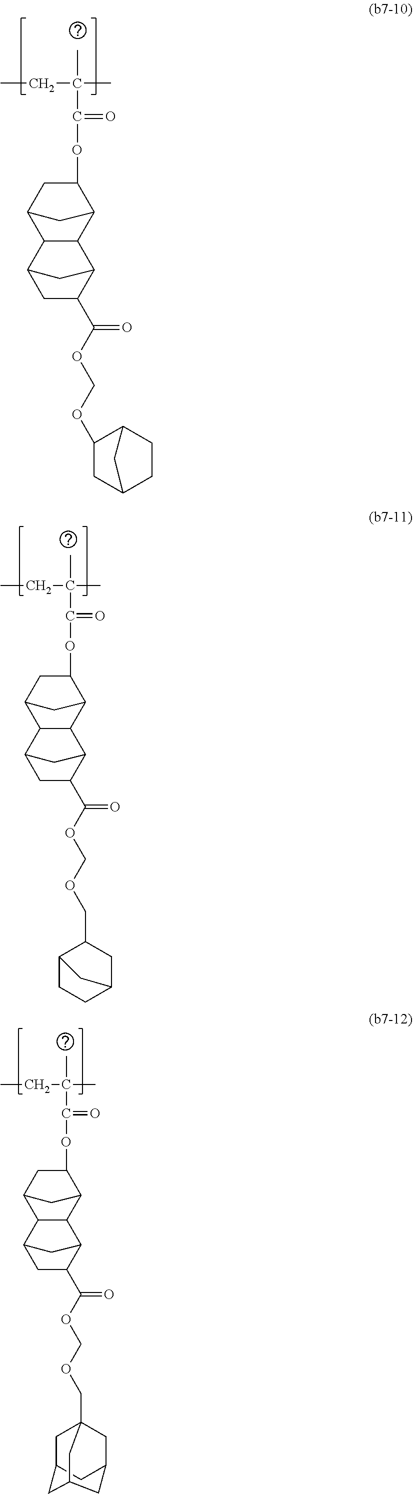

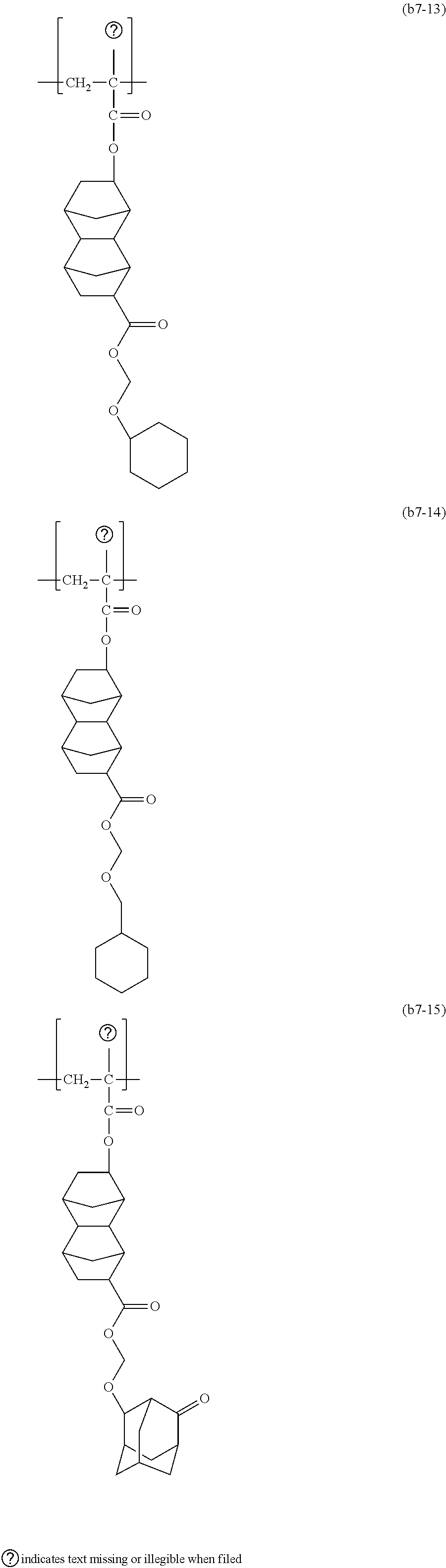

In the above formulae (b7-1) to (b7-15), R^{24b} represents a hydrogen atom or a methyl group.

Among the constituent units represented by the formulae (b5) to (b7) described above, those represented by the formula (b6) are preferred in that they can be easily synthesized and relatively easily sensitized. Further, among the constituent units represented by the formula (b6), those in which Y^{b} is an alkyl group are preferred, and those in which one or both of R^{19b} and R^{20b} are alkyl groups are preferred.

Further, the acrylic resin (B3) is preferably a resin including a copolymer including a constituent unit derived from a polymerizable compound having an ether bond together with a constituent unit represented by the above formulae (b5) to (b7).

Illustrative examples of the polymerizable compound having an ether bond include radical polymerizable compounds such as (meth)acrylic acid derivatives having an ether bond and an ester bond, and specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolyethylene glycol (meth)acrylate, methoxypolypropylene glycol (meth)acrylate, tetrahydrofurfuryl (meth)acrylate, and the like. Also, the above polymerizable compound having an ether bond is preferably, 2-methoxyethyl (meth)acrylate, 2-ethoxyethyl (meth)acrylate, or methoxytriethylene glycol (meth)acrylate. These polymerizable compounds may be used alone, or in combinations of two or more thereof.

Furthermore, the acrylic resin (B3) may include another polymerizable compound as a constituent unit in order to moderately control physical or chemical properties. The polymerizable compound is exemplified by conventional radical polymerizable compounds and anion polymerizable compounds.

Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl(meth)acrylate, butyl(meth)acrylate and cyclohexyl(meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

As described above, the acrylic resin (B3) may include a constituent unit derived from a polymerizable compound having a carboxyl group such as the above-mentioned monocarboxylic acids or dicarboxylic acids. However, the ratio of the constituent unit derived from the polymerizable compound having a carboxyl group in the acrylic resin (B3) is preferably less than 20% by mass, more preferably 0.1% by mass or more and 15% by mass or less, and particularly preferably 1% by mass or more and 10% by mass or less from the viewpoint of easy formation of a resist pattern including a non-resist portion having a rectangular shape having a better cross-sectional shape.

Examples of the polymerizable compound include a vinyl group-containing aromatic compound.

When the acrylic resin (B3) contains a constituent unit (b-3) that contains a —SO₂-containing cyclic group or a lactone-containing cyclic group, the content of the constituent unit (b-3) in the acrylic resin (B3) is preferably 5% by mass or more, more preferably 10% by mass or more, particularly preferably 10% by mass or more and 50% by mass or less, and most preferably 10% by mass or more and 30% by mass or less. When the photosensitive composition contains the constituent unit (b-3) in an amount within the above range, it is easy to achieve both good developability and good pattern shape. The acrylic resin (B3) may not contain a constituent unit (b-3) that contains a —SO₂-containing cyclic group or a lactone-containing cyclic group.

The acrylic resin (B3) preferably contains 5% by mass or more, more preferably 10% by mass or more, and particularly preferably 10% by mass or more and 50% by mass or less of the constituent unit represented by any one of the above formulae (b5) to (b7). The acrylic resin (B3) contains the constituent unit represented by the above formula (b6) in an amount of preferably 0.1% by mass or more and 30% by mass or less, more preferably 1% by mass or more and 20% by mass or less, and particularly preferably 5% by mass or more and 10% by mass or less.

The acrylic resin (B3) preferably includes the above constituent unit derived from a polymerizable compound having an ether bond. The content of the constituent unit derived from a polymerizable compound having an ether bond in the acrylic resin (B3) is preferably 0% by mass or more and 50% by mass or less, more preferably 5% by mass or more and 40% by mass or less, and further more preferably 5% by mass or more and 30% by mass or less.

As long as the photosensitive composition contains a predetermined amount of the acrylic resin (B3), an acrylic resin other than the acrylic resin (B3) described above can also be used as the resin (B). There is no particular limitation for such an acrylic resin other than the acrylic resin (B3) as long as it includes a constituent unit represented by the aforementioned formulae (b5) to (b7).

The mass-average molecular weight of the resin (B) described above in terms of polystyrene is preferably 10,000 or more and 600,000 or less, more preferably 20,000 or more and 400,000 or less, and even more preferably 30,000 or more and 300,000 or less. A mass-average molecular weight within these ranges allows a photosensitive dry film to maintain sufficient strength without reducing detachability from a substrate, and can further prevent a swelled profile and crack generation when plating.

It is also preferred that the resin (B) has a dispersivity of 1.05 or more. Dispersivity herein indicates a value of a mass average molecular weight divided by a number average molecular weight. A dispersivity in the range described above can avoid problems with respect to stress resistance on intended plating or possible swelling of metal layers resulting from the plating process.

The content of the resin (B) is preferably 5% by mass or more and 60% by mass or less with respect to the total mass of the photosensitive composition. Furthermore, the content of the resin (B) is preferably 5% by mass or more and 99% by mass or less, and more preferably 50% by mass or more and 99% by mass or less with respect to the total solid mass of the photosensitive composition.

### <Acid Diffusion Inhibiting Agent (C)>

It is preferable that the photosensitive composition further includes an acid diffusion inhibiting agent (C) for improving a shape of a resist pattern, preservation stability of the photosensitive resin film, and the like. As the acid diffusion inhibiting agent (C), a nitrogen-containing compound (C1) is preferred, and further, if necessary, an organic carboxylic acid or an oxo acid of phosphorus or a derivative thereof (C2) can be contained.

### [Nitrogen-Containing Compound (C1)]

Examples of the nitrogen-containing compound (C1) include trimethylamine, diethylamine, triethylamine, di-n-propylamine, tri-n-propylamine, tri-n-pentylamine, tribenzylamine, diethanolamine, triethanolamine, n-hexylamine, n-heptyl amine, n-octyl amine, n-nonyl amine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3,-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-S-triazine, morpholine, 4-methylmorpholine, piperazine, 1,4-dimethylpiperazine, 1,4-diazabicyclo[2.2.2]octane and pyridine, and pyridines. These may be used alone, or in combinations of two or more thereof.

Furthermore, commercially available hindered amine compounds such as ADK Stab LA-52, ADK Stab LA-57, ADK Stab LA-63P, ADK Stab LA-68, ADK Stab LA-72, ADK Stab LA-77Y, ADK Stab LA-77G, Adeka Stab LA-81, ADK Stab LA-82, and ADK Stab LA-87 (all manufactured by ADEKA), and a 4-hydroxy-1,2,2,6,6-pentamethylpiperidine derivative, and the like, and pyridine having 2 and 6 positions substituted with a substituent such as a hydrocarbon group, e.g., 2,6-diphenyl pyridine and 2,6-di-tert-butyl pyridine, can be used as the nitrogen-containing compound (C1).

The nitrogen-containing compound (C1) may be used in an amount typically in the range of 0 parts by mass or more and 5 parts by mass or less, and particularly preferably in the range of 0 parts by mass or more and 3 parts by mass or less, with respect to 100 parts by mass of total mass of the above resin (B) and the following alkali-soluble resin (D).

### [Organic Carboxylic Acid or Oxo Acid of Phosphorus or Derivative Thereof (C2)]

Among the organic carboxylic acid, or the oxo acid of phosphorus or the derivative thereof (C2), preferred examples of the organic carboxylic acid include malonic acid, citric acid, malic acid, succinic acid, benzoic acid, salicylic acid and the like, and salicylic acid is particularly preferred.

Examples of the oxo acid of phosphorus or derivatives thereof include: phosphoric acid and derivatives thereof, such as di-n-butyl phosphate, diphenyl phosphate, etc.; phosphonic acid and derivatives thereof such as phosphonic acid, dimethyl phosphonate, di-n-butyl phosphonate, phenylphosphonic acid, diphenyl phosphonate, dibenzyl phosphonate, etc.; and phosphinic acid and derivatives thereof such as phosphinic acid, phenylphosphinic acid, etc.; and the like. Among these, phosphonic acid is particularly preferred. These may be used alone, or in combinations of two or more thereof.

The organic carboxylic acid or oxo acid of phosphorus or derivative thereof (C2) may be used in an amount usually in the range of 0 parts by mass or more and 5 parts by mass or less, and particularly preferably in the range of 0 parts by mass and 3 parts by mass or less, with respect to 100 parts by mass of total mass of the above resin (B) and the following alkali-soluble resin (D).

Moreover, in order to form a salt to allow for stabilization, the organic carboxylic acid, or the oxo acid of phosphorous or the derivative thereof (C2) is preferably used in an amount equivalent to that of the above nitrogen-containing compound (C1).

### <Alkali-Soluble Resin (D)>

The photosensitive composition does not contain an alkali-soluble resin (D). However, it is preferable that the photosensitive composition further contains an alkali-soluble resin (D) in order to improve crack resistance. Here, the alkali-soluble resin refers to a resin such that when a resin film having a film thickness of 1 μm formed on a substrate by using a resin solution (solvent: propylene glycol monomethyl ether acetate) having a resin concentration of 20% by mass is immersed in an aqueous TMAH solution of 2.38% by mass for 1 minute, the resin film dissolves by 0.01 μm or more. The alkali-soluble resin (D) does not have an acid dissociable group. The alkali-soluble resin (D) is preferably at least one type of resins selected from the group consisting of a novolac resin (D1), a polyhydroxystyrene resin (D2), and an acrylic resin (D3).

### [Novolac Resin (D1)]

The novolac resin can be obtained, for example, by subjecting an aromatic compound (hereinafter, simply referred to as “phenols”) having a phenolic hydroxy group and an aldehyde to addition condensation under an acid catalyst.

Examples of the above-mentioned phenols include: phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, fluoroglycinol, hydroxydiphenyl, bisphenol A, gallic acid, gallate esters, α-naphthol, β-naphthol, etc. Examples of the aldehyde include formaldehyde, furfural, benzaldehyde, nitrobenzaldehyde, and acetaldehyde. The catalyst in the addition condensation reaction is not particularly limited, and for example, as an acid catalyst, hydrochloric acid, nitric acid, sulfuric acid, formic acid, oxalic acid, acetic acid, and the like are used.

Note that it is possible to further improve the flexibility of the novolac resin by using o-cresol, replacing a hydrogen atom of a hydroxy group in the resin with another substituent, or using a bulky aldehyde.

The mass average molecular weight of a novolac resin (D1) is not particularly limited within a range not inhibiting the objects of the present invention, but is preferably 1,000 or more and 50,000 or less.

### [Polyhydroxystyrene Resin (D2)]

Examples of hydroxystyrene-based compounds constituting the polyhydroxystyrene resin (D2) include p-hydroxystyrene, α-methylhydroxystyrene, α-ethylhydroxystyrene, etc. Furthermore, a copolymer of the polyhydroxystyrene resin (D2) with a styrene resin is preferable. Examples of the styrene-based compound constituting such a styrene resin include styrene, chlorostyrene, chloromethylstyrene, vinyltoluene, α-methylstyrene, etc.

The mass average molecular weight of the polyhydroxystyrene resin (D2) is not particularly limited within a range not inhibiting the objects of the present invention, but is preferably 1,000 or more and 50,000 or less.

### [Acrylic Resin (D3)]

The acrylic resin (D3) preferably includes a constitutional unit derived from a polymerizable compound having an ether bond and a constitutional unit derived from a polymerizable compound having a carboxy group.

As the polymerizable compound having an ether bond, the following (meth) acrylic acid derivatives having an ether bond and an ester bond can be exemplified: 2-methoxyethyl (meth)acrylate, methoxytriethylene glycol (meth)acrylate, 3-methoxybutyl (meth)acrylate, ethyl carbitol (meth)acrylate, phenoxypolyethylene glycol (meth)acrylate, methoxypolypropylene glycol (meth)acrylate, tetrahydrofurfuryl (meth) acrylate, etc. The polymerizable compound having an ether bond is preferably 2-methoxyethyl acrylate or methoxytriethylene glycol acrylate. These polymerizable compounds may be used alone, or two or more of them may be used in combination.

As the polymerizable compound having a carboxy group, monocarboxylic acids, such as acrylic acid, methacrylic acid, crotonic acid, etc.; dicarboxylic acids, such as maleic acid, fumaric acid, itaconic acid, etc.; and compounds each having both a carboxy group and an ester bond, such as 2-methacryloyloxyethyl succinate, 2-methacryloyloxyethyl maleate, 2-methacryloyloxyethyl phthalate, 2-methacryloyloxyethyl hexahydrophthalate, etc. can be exemplified. The polymerizable compound having a carboxy group is preferably acrylic acid or methacrylic acid. These polymerizable compounds may be used alone, or two or more of them may be used in combination.

The mass average molecular weight of the acrylic resin (D3) is not particularly limited within a range not inhibiting the objects of the present invention, but is preferably 50,000 or more and 800,000 or less.

The content of the alkali-soluble resin (D) is preferably 0 parts by mass or more and 80 parts by mass or less, and more preferably 0 parts by mass or more and 60 parts by mass or less, when the total of the resin (B) and the alkali-soluble resin (D) is set to 100 parts by mass. By setting the content of the alkali-soluble resin (D) within the above range, crack resistance tends to be improved, and film reduction during development tends to be prevented.

### <Sulfur-Containing Compound (E)>

When the photosensitive dry film composed of the photosensitive composition is used for pattern formation on a metal substrate, the photosensitive composition preferably includes a sulfur-containing compound (E). The sulfur-containing compound (E) is a compound containing a sulfur atom capable of coordinating to a metal. With respect to a compound capable of producing two or more tautomers, when at least one of the tautomers contains a sulfur atom capable of coordinating to a metal that constitutes a surface of the metal substrate, the compound falls under the sulfur-containing compound. When a resist pattern to be used as a template for plating is formed on a surface made of a metal such as Cu, a defect of a cross-sectional shape such as footing tends to occur. However, in the case where the photosensitive composition includes the sulfur-containing compound (E), even when a resist pattern is formed on a surface made of a metal on a substrate, it is easy to suppress the occurrence of defects in the cross-sectional shape, such as footing. It should be noted here that the “footing” is a phenomenon in which the width of the bottom is narrower than that of the top in a non-resist section, because a resist portion extends toward the non-resist portion in the vicinity of the contacting surface between the substrate surface and the resist pattern. When the photosensitive dry film composed of the photosensitive composition is used for pattern formation on a substrate other than a metal substrate, the photosensitive composition does not necessarily contain a sulfur-containing compound. When the photosensitive dry film composed of the photosensitive composition is used for pattern formation on a substrate other than a metal substrate, the photosensitive composition preferably does not contain the sulfur-containing compound (E), because the photosensitive composition can be easily produced by reducing the number of components of the photosensitive composition, and the production costs of the photosensitive composition can be reduced. It should be noted that there is no particular problem, even when the photosensitive dry film composed of the photosensitive composition used for pattern formation on the substrate other than a metal substrate contains the sulfur-containing compound (E).

The sulfur atom that can coordinate with metal is included in a sulfur-containing compound as, for example, a mercapto group (—SH), a thiocarboxy group (—CO—SH), a dithiocarboxy group (—CS—SH), a thiocarbonyl group (—CS—), and the like. From the viewpoint of easiness in coordinating with metal and being excellent in suppressing footing, the sulfur-containing compound preferably includes a mercapto group.

Preferable examples of the sulfur-containing compound having a mercapto group include compounds represented by the following formula (e1).

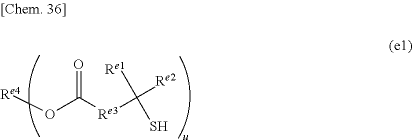

(In the formula, R^{e1} and R^{e2} each independently represents a hydrogen atom or an alkyl group, R^{e3} represents a single bond or an alkylene group, R^{e4} represents a u-valence aliphatic group which may include an atom other than carbon, and u is an integer of 2 or more and 4 or less.)

R^{e1} and R^{e2} are an alkyl group, the alkyl group may be linear or branched, and is preferably linear. When R^{e1} and R^{e2} are an alkyl group, the number of carbon atoms of the alkyl group is not particularly limited within a range in which the objects of the present invention are not impaired. The number of carbon atoms of the alkyl group is preferably 1 or more and 4 or less, particularly preferably 1 or 2, and the most preferably 1. As the combination of R^{e1} and R^{e2}, preferably, one is a hydrogen atom and the other is an alkyl group, and particularly preferably one is a hydrogen atom and the other is a methyl group.

When R^{e3} is an alkylene group, the alkylene group may be linear or branched, and is preferably linear. When R^{e3} is an alkylene group, the number of carbon atoms of the alkylene group is not particularly limited within a range in which the objects of the present invention are not impaired. The number of carbon atoms of the alkylene group is preferably 1 or more and 10 or less, more preferably 1 or more and 5 or less, particularly preferably 1 or 2, and the most preferably 1.

R^{e4} is an aliphatic group having two or more and four or less valences and which may include an atom other than carbon atom. Examples of the atoms which may be included in R^{e4} include a nitrogen atom, an oxygen atom, a sulfur atom, a fluorine atom, a chlorine atom, a bromine atom, an iodine atom, and the like. A structure of the aliphatic group as R^{e4} may be linear or branched, or may be cyclic, and a structure combining these structures.

Among the compounds represented by the formula (e1), a compound represented by the following formula (e2) is more preferable.

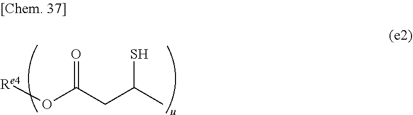

(In the formula (e2), R^{e4} and u are the same as those in the formula (e1).)

Among the compounds represented by the above formula (e2), the following compounds are preferable.

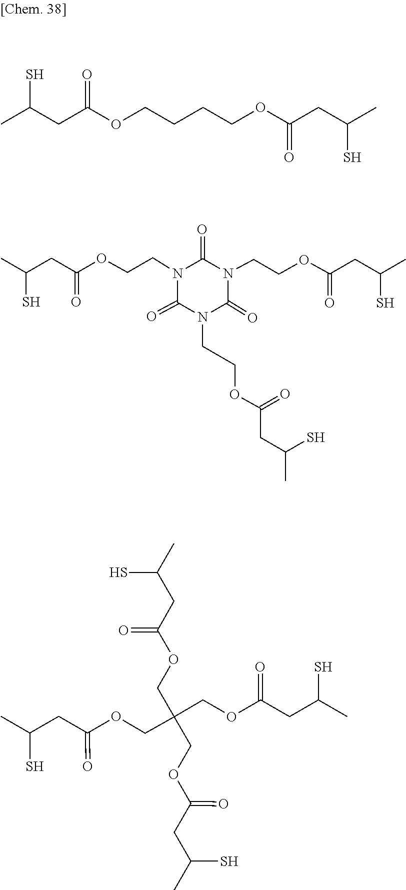

Compounds represented by the following formulae (e3-L1) to (e3-L7) are also preferable examples of the sulfur-containing compound having a mercapto group.

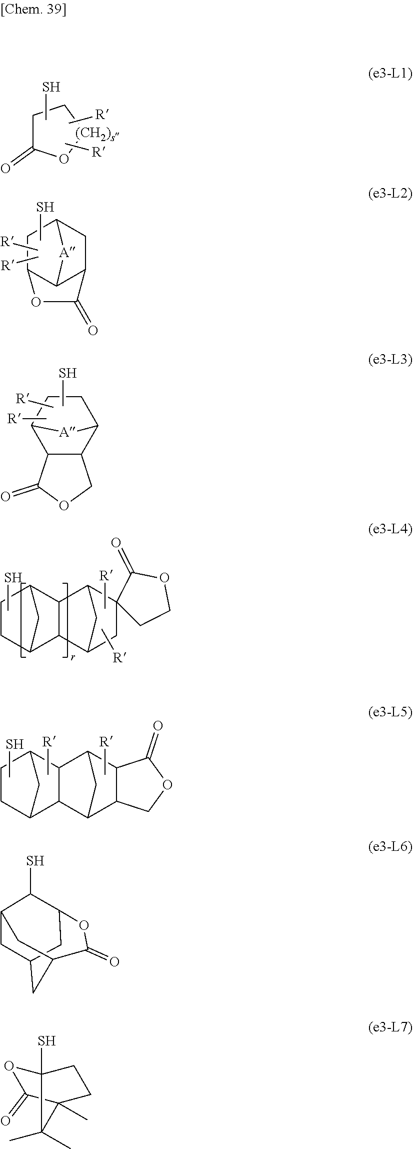

(In the formulae (e3-L1) to (e3-L7), R′, s″, A″, and r are the same as in the formulae (b-L1) to (b-L7) described for the acrylic resin (B3).)

Suitable specific examples of the mercapto compound represented by the above formulae (e3-L1) to (e3-L7) include the following compounds.

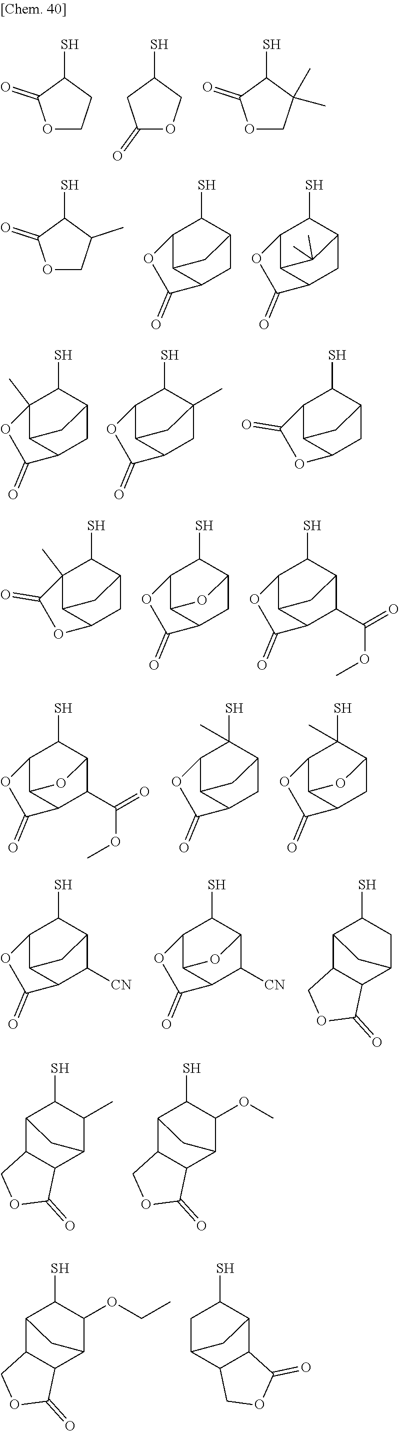

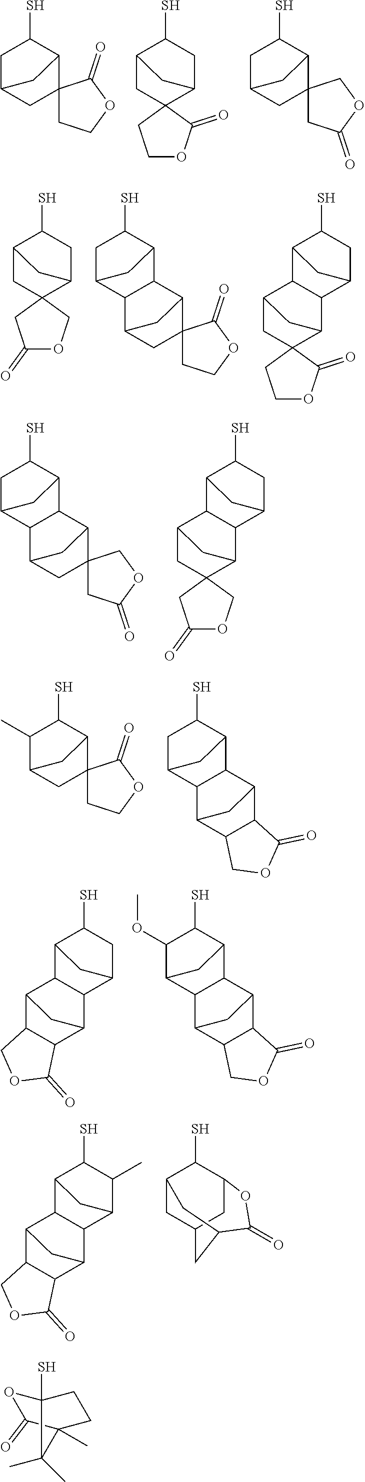

Compounds represented by the following formulae (e3-1) to (e3-4) are also preferable examples of the sulfur-containing compound having a mercapto group.

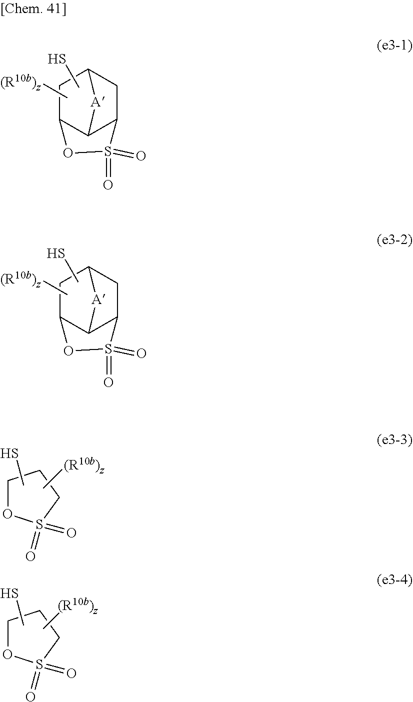

(In the formulae (e3-1) to (e3-4), definitions of abbreviations are the same as mentioned for the formulae (3-1) to (3-4) described for acrylic resin (B3).)

Suitable specific examples of the mercapto compound represented by the above formulae (e3-1) to (e3-4) include the following compounds.

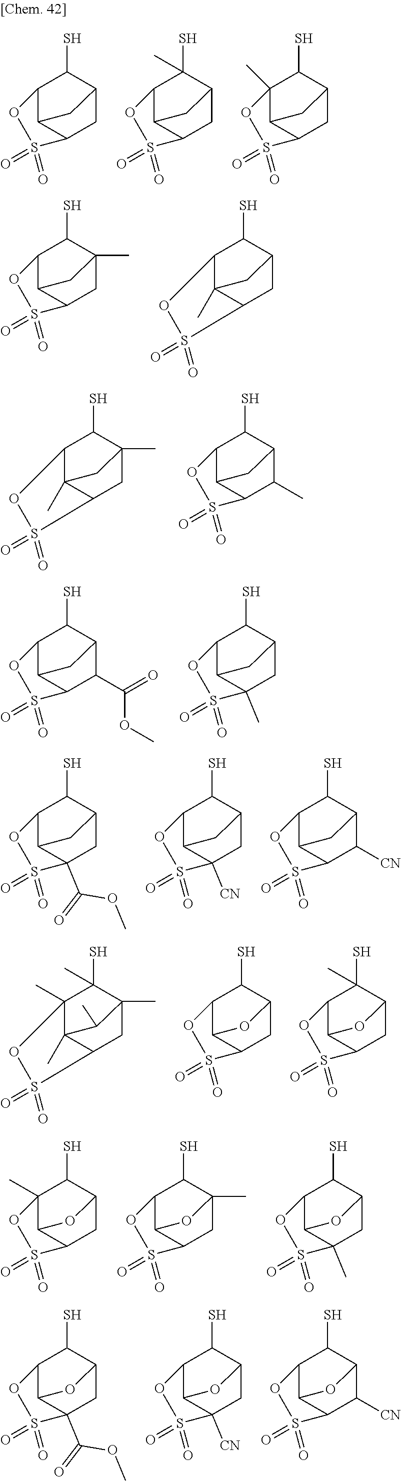

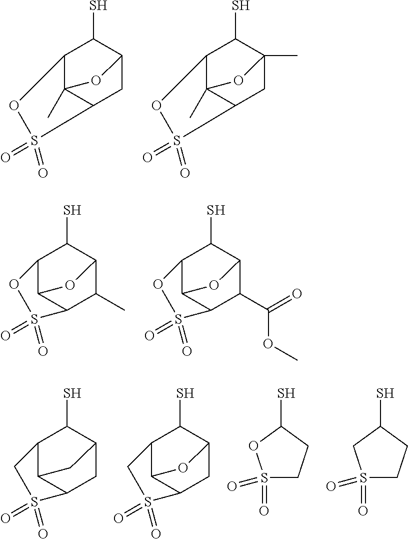

Furthermore, preferable examples of the compound having a mercapto group include compounds represented by the following formula (e4).

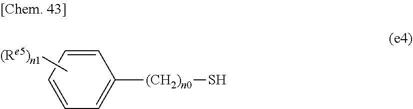

(In the formula (e4), R^{e5} is a group selected from the group consisting of a hydroxyl group, an alkyl group having 1 or more 4 or less carbon atoms, an alkoxy group having 1 or more 4 or less carbon atoms, an alkylthio group having 1 or more and 4 or less carbon atoms, a hydroxyalkyl group having 1 or more and 4 or less carbon atoms, a mercapto alkyl group having 1 or more and 4 or less carbon atoms, a halogenated alkyl group having 1 or more and 4 or less carbon atoms, and a halogen atom, n1 is an integer of 0 or more and 3 or less, n0 is an integer of 0 or more and 3 or less, when n1 is 2 or 3, R^{e5} may be the same as or different from each other.)

Specific examples of the case where R^{e5} is an alkyl group which may have a hydroxyl group having 1 or more 4 or less carbon atoms include a methyl group, an ethyl group, an n-propyl group, an isopropyl group, an n-butyl group, an isobutyl group, a sec-butyl group, and a tert-butyl group. Among these alkyl groups, a methyl group, a hydroxymethyl group, and an ethyl group are preferable.

Specific examples of the case where R^{e5} is an alkoxy group having 1 or more 4 or less carbon atoms include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable.

Specific examples of the case where R^{e5} is an alkylthio group having 1 or more 4 or less carbon atoms include a methylthio group, an ethylthio group, an n-propylthio group, an isopropylthio group, an n-butylthio group, an isobutylthio group, a sec-butylthio group, and a tert-butylthio group. Among these alkylthio groups, a methylthio group, and an ethylthio group are preferable, and a methylthio group is more preferable.

Specific examples of the case where R^{e5} is a hydroxyalkyl group having 1 or more 4 or less carbon atoms include a hydroxymethyl group, a 2-hydroxyethyl group, a 1-hydroxyethyl group, a 3-hydroxy-n-propyl group, and a 4-hydroxy-n-butyl group, and the like. Among these hydroxyalkyl groups, a hydroxymethyl group, a 2-hydroxyethyl group, and a 1-hydroxyethyl group are preferable, and a hydroxymethyl group is more preferable.

Specific examples of the case where R^{e5} is a mercapto alkyl group having 1 or more 4 or less carbon atoms include a mercapto methyl group, a 2-mercapto ethyl group, a 1-mercapto ethyl group, a 3-mercapto-n-propyl group, a 4-mercapto-n-butyl group, and the like. Among these mercapto alkyl groups, a mercapto methyl group, a 2-mercapto ethyl group, and 1-mercapto ethyl group are preferable, and a mercapto methyl group is more preferable.

When R^{e5} is a halogenated alkyl group having 1 or more 4 or less carbon atoms, examples of the halogen atom included in the halogenated alkyl group include fluorine, chlorine, bromine, iodine, and the like. Specific examples of the case where R^{e5} is a halogenated alkyl group having 1 or more 4 or less carbon atoms include a chloromethyl group, a bromomethyl group, an iodomethyl group, a fluoromethyl group, a dichloromethyl group, a dibromomethyl group, a difluoromethyl group, a trichloromethyl group, a tribromomethyl group, a trifluoromethyl group, a 2-chloroethyl group, a 2-bromoethyl group, a 2-fluoroethyl group, a 1,2-dichloroethyl group, a 2,2-difluoroethyl group, a 1-chloro-2-fluoroethyl group, 3-chloro-n-propyl group, a 3-bromo-n-propyl group, a 3-fluoro-n-propyl group, 4-chloro-n-butyl group, and the like. Among these halogenated alkyl groups, a chloromethyl group, a bromomethyl group, an iodomethyl group, a fluoromethyl group, a dichloromethyl group, a dibromomethyl group, a difluoromethyl group, a trichloromethyl group, a tribromomethyl group, and a trifluoromethyl group are preferable, and a chloromethyl group, a dichloromethyl group, a trichloromethyl group, and a trifluoromethyl group are more preferable.

Specific examples of the case where R^{e5} is a halogen atom include fluorine, chlorine, bromine, or iodine.

In the formula (e4), n1 is an integer of 0 or more 3 or less, and 1 is more preferable. When n1 is 2 or 3, a plurality of R^{e5}s may be the same as or different from each other.

In the compound represented by the formula (e4), a substituted position of R^{e5} on a benzene ring is not particularly limited. The substituted position of R^{e5} on a benzene ring is preferably a meta position or a para position with respect to the bond position of —(CH₂)ₙ₀—SH.

The compound represented by the formula (e4) is preferably a compound having at least one group selected from the group consisting of an alkyl group, a hydroxyalkyl group, and a mercapto alkyl group as R^{e5}, and more preferably a compound having one group selected from the group consisting of an alkyl group, a hydroxyalkyl group, and a mercapto alkyl group as R^{e5}. When the compound represented by the formula (e4) has one group selected from the group consisting of an alkyl group, a hydroxyalkyl group, and a mercapto alkyl group as R^{e5}, the substituted position on the benzene ring of the alkyl group, the hydroxyalkyl group, or the mercapto alkyl group is preferably a meta position or a para position with respect to the bond position of —(CH₂)ₙ₀—SH, and more preferably a para position.

In the formula (e4), n0 is an integer of 0 or more 3 or less. From the viewpoint that preparation or availability of a compound is easy, n0 is preferably 0 or 1, and more preferably 0.

Specific examples of the compound represented by the formula (e4) include p-mercaptophenol, p-thiocresol, m-thiocresol, 4-(methylthio)benzenethiol, 4-methoxybenzenethiol, 3-methoxybenzenethiol, 4-ethoxybenzenethiol, 4-isopropyloxy benzenethiol, 4-tert-butoxybenzenethiol, 3,4-dimethoxy benzenethiol, 3,4,5-trimethoxybenzenethiol, 4-ethylbenzenethiol, 4-isopropyl benzenethiol, 4-n-butylbenzenethiol, 4-tert-butylbenzenethiol, 3-ethylbenzenethiol, 3-isopropyl benzenethiol, 3-n-butylbenzenethiol, 3-tert-butylbenzenethiol, 3,5-dimethyl benzenethiol, 3,4-dimethyl benzenethiol, 3-tert-butyl-4-methylbenzenethiol, 3-tert-4-methylbenzenethiol, 3-tert-butyl-5-methylbenzenethiol, 4-tert-butyl-3-methylbenzenethiol, 4-mercaptobenzyl alcohol, 3-mercaptobenzyl alcohol, 4-(mercaptomethyl)phenol, 3-(mercaptomethyl)phenol, 1,4-di(mercaptomethyl)phenol, 1,3-di(mercaptomethyl)phenol, 4-fluorobenzenethiol, 3-fluorobenzenethiol, 4-chlorobenzenethiol, 3-chlorobenzenethiol, 4-bromobenzenethiol, 4-iodobenzenethiol, 3-bromobenzenethiol, 3,4-dichlorobenzenethiol, 3,5-dichlorobenzenethiol, 3,4-difluorobenzenethiol, 3,5-difluorobenzenethiol, 4-mercaptocatechol, 2,6-di-tert-butyl-4-mercaptophenol, 3,5-di-tert-butyl-4-methoxybenzenethiol, 4-bromo-3-methylbenzenethiol, 4-(trifluoromethyl)benzenethiol, 3-(trifluoromethyl)benzenethiol, 3,5-bis(trifluoromethyl)benzenethiol, 4-methylthiobenzenethiol, 4-ethylthiobenzenethiol, 4-n-butylthiobenzenethiol, and 4-tert-butylthiobenzenethiol, and the like.

Furthermore, examples of the sulfur-containing compound having a mercapto group include a compound including nitrogen-containing aromatic heterocycle substituted with a mercapto group, and a tautomer of a compound including nitrogen-containing aromatic heterocycle substituted with a mercapto group. Preferable specific examples of the nitrogen-containing aromatic heterocycle include imidazole, pyrazole, 1,2,3-triazol, 1,2,4-triazol, oxazole, thiazole, pyridine, pyrimidine, pyridazine, pyrazine, 1,2,3-triazine, 1,2,4-triazine, 1,3,5-triazine, indole, indazole, benzimidazole, benzoxazole, benzothiazole, 1H-benzotriazole, quinoline, isoquinoline, cinnoline, phthalazine, quinazoline, quinoxaline, and 1,8-naphthyridine.

Suitable specific examples of a nitrogen-containing heterocyclic compound suitable as a sulfur-containing compound, and a tautomer of the nitrogen-containing heterocyclic compound include the following compounds.

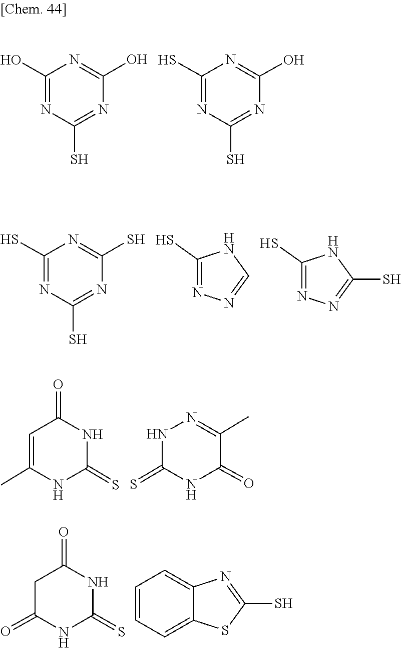

When the photosensitive composition contains the sulfur-containing compound (E), the amount thereof used is preferably 0.01 parts by mass or more and 5 parts by mass or less, and more preferably 0.02 parts by mass or more and 3 parts by mass or less, based on 100 parts by mass of the total mass of the resin (B) and the alkali-soluble resin (D).

### <Organic Solvent (S)>

The photosensitive composition includes an organic solvent (S). The organic solvent (S) includes a high boiling point organic solvent (S1) that satisfies the following conditions I) and II).
I) The boiling point at atmospheric pressure is 150° C. or higher; and
II) a value of δh, a term of energy by hydrogen bonding relating to a Hansen solubility parameter is 11 (MPa)^{0.5} or less.

The boiling point of the high-boiling-point organic solvent (S1) at atmospheric pressure is preferably 230° C. or less, more preferably 220° C. or less, and most preferably 215° C. or less.

The δh, a term of energy by hydrogen bonding relating to a Hansen solubility parameter can be determined with the software (Software name: Hansen Solubility Parameter in Practice (HSPiP)) developed by Charles Hansen et al. The δh, the term of energy by hydrogen bonding is preferably 10.0 (MPa)^{0.5} or less, and more preferably 9.5 (MPa)^{0.5} or less. The δh, the term of energy by hydrogen bonding is preferably 5.5 (MPa)^{0.5} or more.

Although evaporation rate of the high boiling point organic solvent (S1) is not particularly limited, for example, given that the evaporation rate of butyl acetate is 100, a relative evaporation rate is preferably 60 or less, and more preferably 40 or less. It should be noted that the relative evaporation rate is determined as a relative rate with respect to a weight reduction amount of n-butyl acetate per unit time at a temperature of 25° C. and a relative humidity of 55% RH, as specified by ASTM D 3539-87 standard test method.

Examples of the high boiling point organic solvent (S1) include anisole, methyl 3-ethoxypropionate, 3-methoxybutyl acetate, cyclohexanol acetate, dipropylene glycol dimethyl ether, 3-methoxy-3-methyl-1-butyl acetate (solfit acetate), propylene glycol diacetate, gamma butyrolactone, dipropylene glycol methyl ether acetate, and propylene glycol monobutyl ether.

The organic solvent (S) may contain an organic solvent other than the high boiling point organic solvent (S1) in addition to the high boiling point organic solvent (S1). However, the ratio of the mass of the high boiling point organic solvent (S1) to the mass of the organic solvent (S) is preferably 10% by mass or more, more preferably 50% by mass or more, more preferably 90% by mass or more, and particularly preferably 100% by mass.

In the photosensitive composition, the content of the organic solvent (S), that is, a sum of the mass of the high-boiling-point organic solvent (S1) and the mass of an organic solvent other than the high-boiling-point organic solvent (S1) where necessary, is not particularly limited as long as the object of the present invention is not impaired. When the photosensitive dry film (photosensitive layer) obtained by coating and drying (heating) the photosensitive composition has a thickness of 40 μm or more, the organic solvent (S) is used in a range in which the solid content concentration of the photosensitive composition is preferably 30% by mass or more, and more preferably 40% by mass or more. The upper limit of the solid content concentration of the photosensitive composition is preferably 60% by mass or less. In the present specification, the solid content is a component other than the organic solvent (S) and water. The content of the organic solvent (S) in the photosensitive dry film is preferably 10% by mass or more and 25% by mass or less, more preferably 15% by mass or more and 25% by mass or less from the viewpoint of flexibility of the photosensitive dry film.

### <Other Components>

The photosensitive composition may further contain a polyvinyl resin for improving plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and copolymers thereof, and the like. The polyvinyl resin is preferably polyvinyl methyl ether in view of lower glass transition temperatures.

The photosensitive composition may contain a Lewis acidic compound. When the photosensitive composition includes a Lewis acidic compound, a photosensitive composition with high sensitivity is easily obtained, so that a resist pattern whose cross-sectional shape is rectangular is more easily formed using a photosensitive dry film composed of a photosensitive composition. Furthermore, when a pattern is formed using the photosensitive dry film composed of the photosensitive composition, when time required for each process at the time of pattern formation or time required between the processes is long, a pattern having a desired shape and dimension may not be easily formed, or developing property may be deteriorated. However, when a Lewis acidic compound is blended into the photosensitive composition, such adverse effects on the pattern shape or the developing property can be mitigated or a process margin can be widened.

The Lewis acidic compound herein represents “a compound that acts as an electron-pair receptor having an empty orbital capable of receiving at least one electron pair.” The Lewis acidic compound is not particularly limited as long as it corresponds to the above definition, and is a compound which is recognized as the Lewis acidic compound by a person skilled in the art. As the Lewis acidic compound, a compound that does not correspond to a Bronsted acid (proton acid) is preferably used. Specific examples of the Lewis acidic compound include boron fluoride, ether complexes of boron fluoride (for example, BF₃·Et₂O, BF₃·Me₂O, BF₃·THF, etc., Et represents an ethyl group, Me represents a methyl group, and THF represents tetrahydrofuran), organic boron compounds (for example, tri-n-octyl borate, tri-n-butyl borate, triphenyl borate, triphenylboron, etc.), titanium chloride, aluminum chloride, aluminum bromide, gallium chloride, gallium bromide, indium chloride, thallium trifluoroacetate, tin chloride, zinc chloride, zinc bromide, zinc iodide, zinc trifluoromethanesulfonate, zinc acetate, zinc nitrate, zinc tetrafluoroborate, manganese chloride, manganese bromide, nickel chloride, nickel bromide, nickel cyanide, nickel acetylacetonate, cadmium chloride, cadmium bromide, stannous chloride, stannous bromide, stannous sulfate, stannous tartrate, and the like. Furthermore, other specific examples of the Lewis acidic compound include chloride, bromide, sulfate, nitrate, carboxylate, or trifluoromethanesulfonate, of the rare earth metal element, and cobalt chloride, ferrous chloride, yttrium chloride, and the like. Examples of the rare earth metal element herein include lanthanum, cerium, praseodymium, neodymium, samarium, europium, gadolinium, terbium, dysprosium, holmium, erbium, thulium, ytterbium, and lutetium.

From the viewpoint of easiness in availability and favorable effect by addition thereof, it is preferable that the Lewis acidic compound contains a Lewis acidic compound including elements belonging to Group 13 of the periodic table. Herein, examples of the elements belonging to Group 13 include boron, aluminum, gallium, indium, and thallium. Among the above elements belonging to Group 13, boron is preferable from the viewpoint that the Lewis acidic compound is easily available and addition effect is particularly excellent. In other words, it is preferable that the Lewis acidic compound contains a Lewis acidic compound including boron.

Examples of the Lewis acidic compound containing boron include boron fluoride, ether complexes of boron fluoride, boron halides such as boron chloride and boron bromide, and various organic boron compounds. As the Lewis acidic compound including boron, an organic boron compound is preferable because the content ratio of halogen atoms in the Lewis acidic compound is small and the photosensitive composition is easily applicable to an application requiring a low halogen content.

Preferable examples of the organic boron compound include a boron compound represented by the following formula (f1):

B(R^{f1})ₜ₁(OR^{f2})₍₃₋ₜ₁₎ (f1)

(In the formula (f1), R^{f1} and R^{f2} each independently represent a hydrocarbon group having 1 or more and 20 or less carbon atoms; the hydrocarbon group may have one or more substituents; t1 is an integer of 0 or more and 3 or less; when a plurality of R^{f1} exists, two of the plurality of R^{f1} may be bonded to each other to form a ring; and when a plurality of OR^{f2} is present, two of the plurality of OR^{f2} may be bonded to each other to form a ring). The photosensitive composition preferably includes one or more boron compounds represented by the above formula (f1) as the Lewis acidic compound mentioned above.

In the formula (f1), R^{f1} and R^{f2} are a hydrocarbon group, the number of carbon atoms of the hydrocarbon group is 1 or more and 20 or less. The hydrocarbon group having 1 or more and 20 or less carbon atoms may be an aliphatic hydrocarbon group, or an aromatic hydrocarbon group, a hydrocarbon group having a combination of an aliphatic group and an aromatic group. As the hydrocarbon group having 1 or more and 20 or less carbon atoms, a saturated aliphatic hydrocarbon group, or an aromatic hydrocarbon group is preferable. The number of carbon atoms of the hydrocarbon group as R^{f1} and R^{f2} is preferably 1 or more and 10 or less. When the hydrocarbon group is an aliphatic hydrocarbon group, the number of carbon atoms thereof is preferably 1 or more and 6 or less, and particularly preferably 1 or more and 4 or less. The hydrocarbon group as R^{f1} and R^{f2} may be a saturated hydrocarbon group, or an unsaturated hydrocarbon group, and a saturated hydrocarbon group is preferable. When the hydrocarbon group as R^{f1} and R^{f2} is an aliphatic hydrocarbon group, the aliphatic hydrocarbon group may be linear, branched or cyclic or combination thereof.

Suitable specific examples of aromatic hydrocarbon groups include a phenyl group, a naphthalene-1-yl group, a naphthalene-2-yl group, a 4-phenylphenyl, 3-phenylphenyl, and 2-phenylphenyl. Among them, a phenyl group is preferable.

The saturated aliphatic hydrocarbon group is preferably an alkyl group. Suitable examples of alkyl groups include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethyl hexyl group, an n-nonyl group, and an n-decyl group.

The hydrocarbon group as R^{f1} and R^{f2} may have one or more substituents. Examples of the substituent include a halogen atom, a hydroxyl group, an alkyl group, an aralkyl group, an alkoxy group, a cycloalkyloxy group, an aryloxy group, an aralkyloxy group, an alkylthio group, a cycloalkylthio group, an arylthio group, an aralkylthio group, an acyl group, an acyloxy group, an acylthio group, an alkoxycarbonyl group, a cycloalkyloxycarbonyl group, an aryloxycarbonyl group, an amino group, an N-monosubstituted amino group, an N,N-disubstituted amino group, a carbamoyl group (—CO—NH₂), an N-monosubstituted carbamoyl group, an N,N-disubstituted carbamoyl group, a nitro group and a cyano group. The number carbon atoms in the substituent is not particularly limited within a range where the objects of the present invention are not impaired, but the number is preferably 1 or more and 10 or less, and more preferably 1 or more and 6 or less.

Suitable specific examples of the organic boron compound represented by the above formula (f1) include the following compounds. Note here that in the following formulae, Pen represents a pentyl group, Hex represents a hexyl group, Hep represents a heptyl group, Oct represents an octyl group, Non represents a nonyl group, and Dec represents a decyl group.

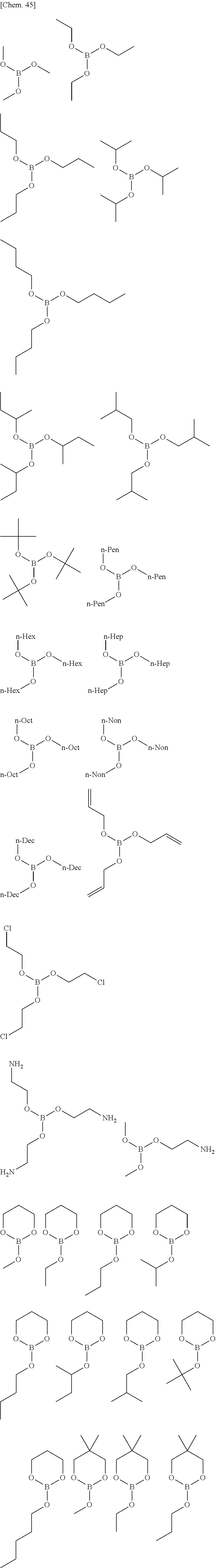

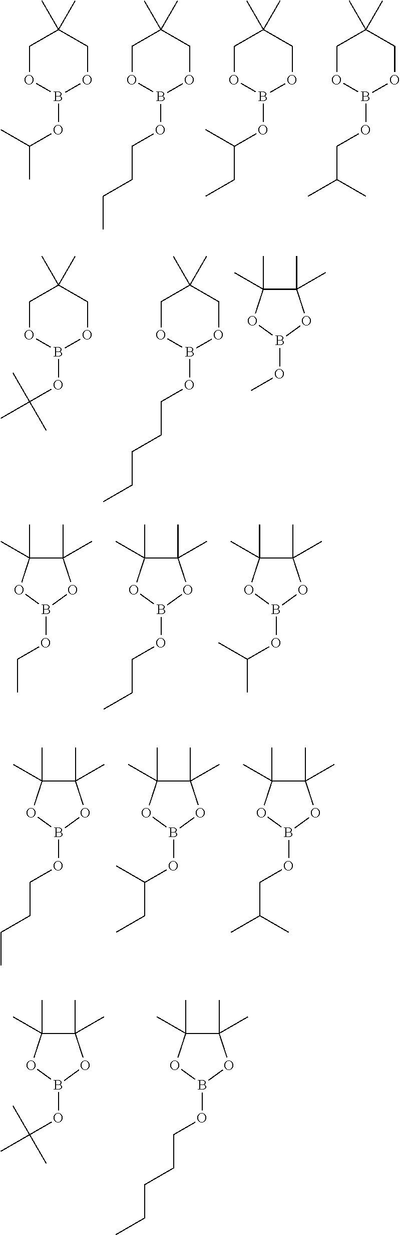

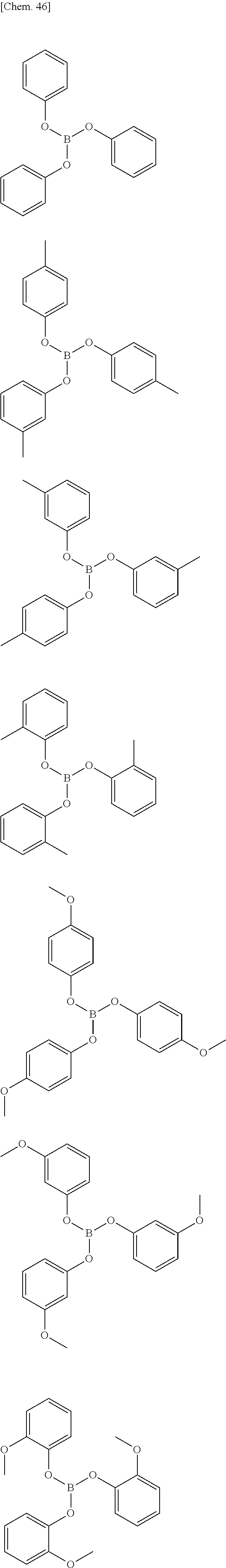

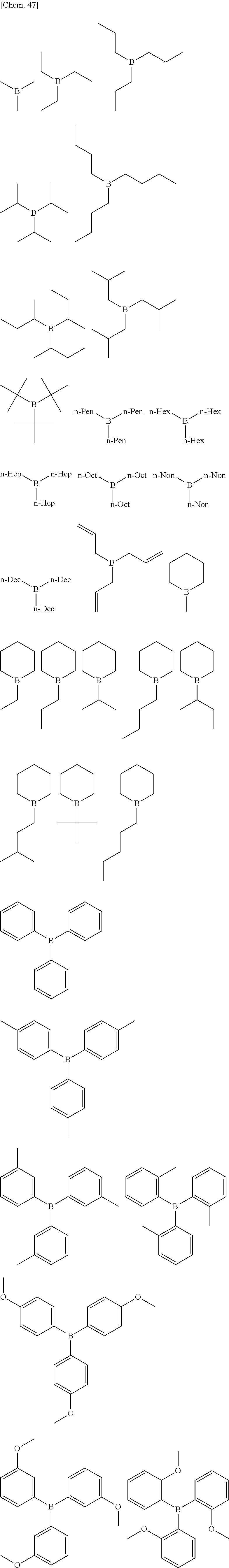

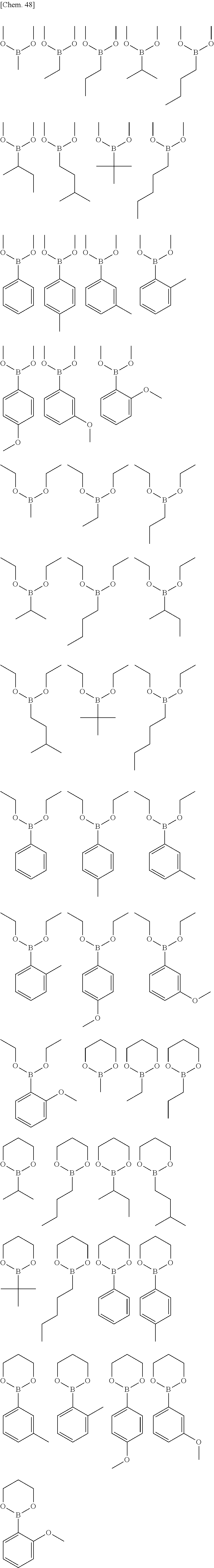

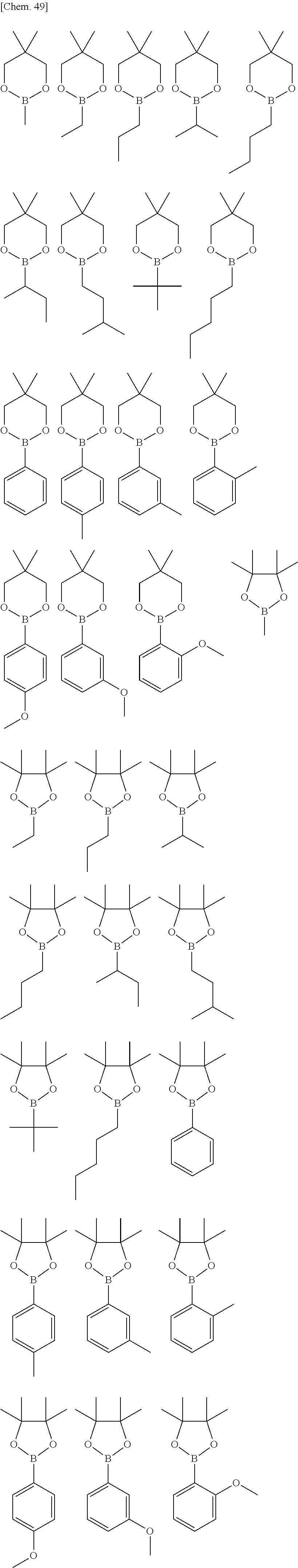

The Lewis acidic compound is used in the amount in a range of preferably 0.01 parts by mass or more and 5 parts by mass or less, more preferably 0.01 parts by mass or more and 3 parts by mass or less, further preferably 0.05 part by mass or more and 2 parts by mass or less, relative to 100 parts by mass of the total mass of the above resin (B) and the above alkali-soluble resin (D).

Further, when the photosensitive dry film composed of the photosensitive composition is used for forming pattern serving as a template for forming a plated article, the photosensitive composition may also contain an adhesive auxiliary agent in order to improve the adhesiveness between a template formed with the photosensitive dry film composed of the photosensitive composition and a metal substrate.

Also, the photosensitive composition may further contain a surfactant for improving coating characteristics, defoaming characteristics, leveling characteristics, and the like. As the surfactant, for example, a fluorine-based surfactant or a silicone-based surfactant is preferably used. Specific examples of the fluorine-based surfactant include commercially available fluorine-based surfactants such as BM-1000 and BM-1100 (both manufactured by B.M-Chemie Co., Ltd.), Megafac F142D, Megafac F172, Megafac F173 and Megafac F183 (all manufactured by Dainippon Ink And Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.) and the like, but not limited thereto. As the silicone-based surfactant, an unmodified silicone-based surfactant, a polyether modified silicone-based surfactant, a polyester modified silicone-based surfactant, an alkyl modified silicone-based surfactant, an aralkyl modified silicone-based surfactant, a reactive silicone-based surfactant, and the like, can be preferably used. As the silicone-based surfactant, commercially available silicone-based surfactant can be used. Specific examples of the commercially available silicone-based surfactant include Paintad M (manufactured by Dow Corning Toray Co., Ltd.), Topica K1000, Topica K2000, and Topica K5000 (all manufactured by Takachiho Industry Co., Ltd.), XL-121 (polyether modified silicone-based surfactant, manufactured by Clariant Co.), BYK-310 (polyester modified silicone-based surfactant, manufactured by BYK), and the like.

Additionally, in order to finely adjust the solubility in a developing solution, the photosensitive composition may further contain an acid or an acid anhydride.

Specific examples of the acid and acid anhydride include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic anhydride, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Moreover, the photosensitive composition may further contain a well-known sensitizer for improving the sensitivity.

The photosensitive composition described above is prepared by mixing and stirring the above components by a conventional method. Examples of a device that can be used for mixing and stirring the above components include a dissolver, a homogenizer, and a three-roll mill. After the above components are uniformly mixed, the obtained mixture may be further filtered using a mesh, a membrane filter, or the like.

The photosensitive dry film of the present invention formed using the photosensitive composition described above, i.e., a photosensitive composition including a high boiling point organic solvent (S1) satisfying the above-mentioned conditions I) and II) as the organic solvent (S) together with an acrylic resin containing a constituent unit (B3a) derived from a (meth)acrylate containing an acid-non-dissociable alicyclic hydrocarbon group-containing group as the resin (B) having an alkali solubility that increases under action of an acid includes the high boiling point organic solvent (S1) satisfying the above-mentioned conditions I) and II) as the organic solvent (S) together with the acrylic resin containing a constituent unit (B3a) derived from a (meth)acrylate containing an acid-non-dissociable alicyclic hydrocarbon group-containing group as the resin (B) having an alkali solubility that increases under action of an acid. The photosensitive dry film composed of such a photosensitive composition has an effect of suppressing white turbidity and separation due to the resin contained therein and being able to prevent bubbles generated while the solvent is removed by heating (PAB) from remaining, as shown in the Examples described below.

The reason why such effects are achieved is not known in detail, but is presumed as follows. When the photosensitive dry film is heated (PAB) to remove the solvent, first, the solvent on the surface of the photosensitive dry film evaporates, and thereby a layer harder than the inside of the photosensitive dry film is formed on the surface of the photosensitive dry film. Since the hard layer becomes a barrier, the bubbles generated while the solvent contained in the photosensitive dry film evaporates are difficult to leave the photosensitive dry film from the surface. Therefore, the bubbles remain in the photosensitive dry film. However, in the case of the photosensitive dry film of the present invention, the formation of the hard layer is suppressed or not formed, though the reason for this is unclear, perhaps because the photosensitive dry film of the present invention includes the high boiling point organic solvent (S1) that satisfies the conditions I) and II) as the organic solvent (S) together with the acrylic resin (B3) including a constituent unit (B3a) derived from a (meth)acrylate including an acid-non-dissociable alicyclic hydrocarbon group-containing group as the resin (B). Therefore, bubbles generated while the solvent evaporates by heating (PAB) the photosensitive dry film are likely to escape from the photosensitive dry film, and the bubbles are prevented from remaining. Further, in the photosensitive dry film containing the above-mentioned components, white turbidity and separation due to the resin contained are also suppressed.

The film thickness of the photosensitive dry film is preferably 40 μm or more and 200 μm or less, and more preferably 60 μm or more and 150 μm or less. The content ratio of the organic solvent (S) in the photosensitive dry film is preferably about 10% by mass or more and 25% by mass or less from the viewpoint of flexibility of the photosensitive dry film. In the photosensitive dry film, the content ratio of the high boiling point organic solvent (S1) to the organic solvent (S) is preferably 50% by mass or more, more preferably 90% by mass or more, and most preferably 100% by mass or more.

### <<Laminated Film and Producing Method of Laminated Film>>

The laminated film is a laminate in which a base film and the photosensitive dry film described above are laminated.

As the substrate film, a film having optical transparency is preferable. Specifically, a polyethylene terephthalate (PET) film, a polypropylene (PP) film, a polyethylene (PE) film, and the like. In view of excellent balance between the optical transparency and the breaking strength, a polyethylene terephthalate (PET) film is preferable.

Such a laminated film can be produced by a producing method of a laminated film, including coating a base film with the chemically amplified positive type photosensitive composition to form a coating film, and drying the coating film by heating to remove some of the organic solvent (S) to form a photosensitive dry film.

In the coating step, it is preferable to use an applicator, a bar coater, a wire bar coater, a roll coater, a curtain flow coater, or the like when the coating film is formed by coating the photosensitive composition on the base film. Although it is difficult to form a thick coating film by a spin coater or the like, it is easy to form a thick film by using these.

In the drying step, the coating film is heated to remove some of the organic solvent (S), thereby forming a photosensitive dry film (photosensitive layer). Although some of the organic solvent (S) is removed by the drying step, some of the organic solvent (S) remains without being removed. Therefore, the photosensitive dry film (photosensitive layer) has flexibility. The heating temperature of the coating film is not particularly limited, and is, for example, 50° C. or more and 100° C. or less, and preferably 50° C. or more and 90° C. or less.

The laminated film may further include a protective film on a surface opposite to the base film of the photosensitive dry film (photosensitive layer). Examples of the protective film include a polyethylene terephthalate (PET) film, a polypropylene (PP) film, and a polyethylene (PE) film.

<<Method of Producing Patterned Resist Film and Method of Producing Substrate with Template>>

By using the above-described laminated film, a patterned resist film can be formed on a substrate. Such a patterned resist film is preferably used as an insulating film, an etching mask, a template for forming a plated article, and the like. As a preferable method, the following method of producing a patterned resist film may be exemplified, the method including the steps of:
laminating the above-described laminated film on a substrate such that the photosensitive dry film is in contact with a surface of the substrate;
removing the base film from the laminated film;
removing the organic solvent (S) by heating (PAB) the photosensitive dry film at 100° C. or more and 180° C. or less; exposing the photosensitive dry film, after the solvent removing step, by irradiating the photosensitive dry film with an actinic ray or radiation in a position-selective manner; and
developing the photosensitive dry film after the exposing step. A method of producing a substrate with a template for forming a plated article is the same as the method of producing a patterned resist film, except for including using a substrate having a metal surface as the substrate and laminating the above-described laminated film on the metal surface of the substrate, such that the photosensitive dry film is in contact with the metal surface, and preparing a template for forming a plated article by developing in the developing step.

The substrate on which the laminated film is laminated is not particularly limited, and a conventionally known substrate can be used. For example, a substrate for electronic components and a substrate on which a predetermined wiring pattern is formed on the substrate for electronic components may be exemplified. As the substrate, a silicon substrate, a glass substrate, or the like can also be used. When producing a substrate with a template provided with a template for forming a plated article, a substrate having a metal surface is used as the substrate. As the metal species constituting the metal surface, copper, gold, and aluminum are preferable, and copper is more preferable.

In the laminating step, for example, a laminated film is placed on a substrate so that the photosensitive dry film is in contact with the surface of the substrate, and the photosensitive dry film and the substrate are pressed by a pressure roll or the like.

In the substrate film removing step, the substrate film is removed by peeling the substrate film off from the laminated film. Thus, the photosensitive dry film alone is formed on the substrate.

In the solvent removing step, the photosensitive dry film is heated (PAB) at 100° C. or more and 180° C. or less to remove the organic solvent (S). By removing the organic solvent (S), a resist pattern having a favorable shape can be formed by the exposing step and the developing step in later phases. In the solvent removing step, the temperature at which the photosensitive dry film is heated may be 100° C. or more and 180° C. or less, and for example, the lower limit is preferably 120° C. or more and 130° C. or more, and the upper limit is preferably 150° C. or less and 145° C. or less. In the solvent removing step, time for heating the photosensitive dry film is, for example, about 2 minutes or more and 120 minutes or less. In the photosensitive dry film after the organic solvent (S) is removed by heating in the solvent removing step, the content ratio of the organic solvent (S) is preferably less than 10% by mass, and more preferably 8% by mass or less.

Here, when the organic solvent contained in the photosensitive dry film is to be removed by heating the photosensitive dry film, bubbles generated while the organic solvent evaporates may remain in the photosensitive dry film. However, the above-described photosensitive dry film suppresses the bubbles from remaining.

In the exposing step, the photosensitive dry film formed on the substrate as described above is selectively irradiated (exposed) with an actinic ray or radiation, for example, an ultraviolet ray or a visible ray having a wavelength of 300 nm or more and 500 nm or less via a mask having a predetermined pattern.

As a radiation source, a low-pressure mercury lamp, a high-pressure mercury lamp, an ultrahigh-pressure mercury lamp, a metal halide lamp, an argon gas laser, or the like can be used. The radiation includes microwaves, infrared rays, visible light, ultraviolet rays, X-rays, y-rays, electron beams, proton beams, neutron beams, ion beams, and the like. The radiation dose varies depending on the composition of the photosensitive composition and the film thickness of the photosensitive layer, but is, for example, 100 mJ/cm² or more and 10000 mJ/cm² or less. The radiation includes a ray that activates the acid generating agent (A) to generate an acid.

After exposure, acid diffusion is accelerated by heating (PEB) the photosensitive dry film preferably using a known method to change the solubility of the photosensitive dry film in a developing solution such as an alkali developing solution, in the exposed portion of the photosensitive dry film.

Next, in the developing step, the exposed photosensitive dry film is developed according to a conventionally known method, and unnecessary portions are dissolved and removed to form a predetermined resist pattern (patterned resist film) or a template for forming a plated article. At this time, an alkaline aqueous solution is used as the developing solution.

As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene or 1,5-diazabicyclo[4.3.0]-5-nonane can be used. Also, an aqueous solution prepared by adding an adequate amount of a water-soluble organic solvent such as methanol or ethanol, or a surfactant to the above aqueous solution of the alkali can be used as the developing solution. Furthermore, depending on the composition of the photosensitive composition, developing by an organic solvent can be applied.

The developing time may vary depending on the composition of the photosensitive dry film, the film thickness of the photosensitive dry film, and the like. Usually, the developing time is 1 minute or more and 30 minutes or less. The method of the development may be any one of a liquid-filling method, a dipping method, a paddle method, a spray developing method, and the like.

After development, for example, it is washed with running water for 30 seconds or more and 90 seconds or less, and then dried with an air gun, an oven, and the like. In this manner, it is possible to form a resist pattern, which has been patterned in a predetermined pattern on a metal surface of a substrate having a metal surface. Also, in this manner, it is possible to manufacture a substrate with a resist pattern on a surface of a substrate.

### <<Method of Manufacturing Plated Article>>

A conductor such as a metal may be embedded, by plating, into a nonresist portion (a portion removed with a developing solution) in the template formed by the above method on the substrate to form a plated article, for example, like a contacting terminal such as a bump and a metal post, or Cu redistribution. Note here that there is no particular limitation on the method of plate processing, and various conventionally known methods can be used. As a plating liquid, in particular, a solder plating liquid, a copper plating liquid, a gold plating liquid, and a nickel plating liquid are suitably used. The remaining template is removed with a stripping liquid and the like in accordance with a conventional method.

### EXAMPLES

Hereinafter, the present invention will be described in more detail with reference to the Examples, but the present invention is not limited to these Examples.

### Examples 1 to 20, and Comparative Examples 1 to 18

In the Examples and the Comparative Examples, PAG1 represented by the following formula was used as the acid generating agent (A).

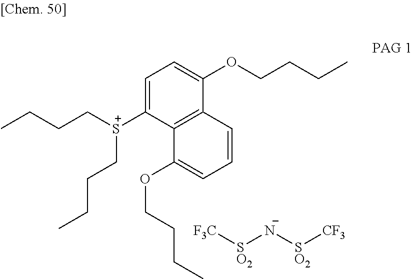 [SMILES: CCCCOc1ccc([S+](CCCC)CCCC)c2c(OCCCC)cccc12 ; O=S(=O)([N-]S(=O)(=O)C(F)(F)F)C(F)(F)F]

In the Examples and the Comparative Examples, the following B1 and B2 were used as resins (resin (B)) having an alkali solubility that increases under action of an acid. The number at the lower right of the parentheses in each constituent unit in the following structural formula represents the content (% by mass) of the constituent unit in each resin. The weight average molecular weight Mw of B1 is 80500 and the dispersity (Mw/Mn) is 5.82. B2 has a mass average molecular weight Mw of 80800 and a dispersity (Mw/Mn) of 5.08.

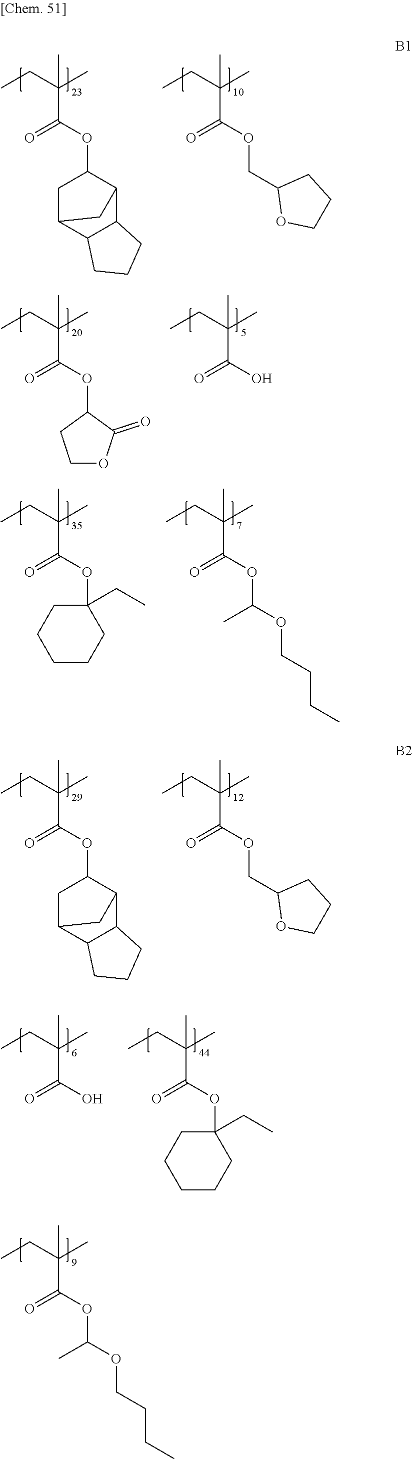

In the Examples and the Comparative Examples, a compound C1 represented by the following formula was used as an acid diffusion controlling agent (C).

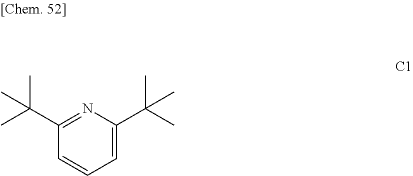

In the Examples and the Comparative Examples, a sulfur-containing compound E1 represented by the following formula was used as the sulfur-containing compound (E).

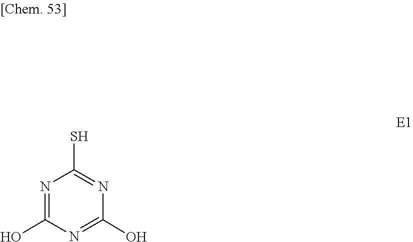

100 parts by mass of each of resins (B) described in Table 1 and Table 2, 1.5 parts by mass of the acid generating agent (A), 0.1 parts by mass of the acid diffusion controlling agent (C), 0.02 parts by mass of the sulfur-containing compound (E), and 0.05 parts by mass of the surfactant (BYK310, manufactured by BYK-Chemie) were dissolved in each of organic solvents (S) described in Table 1 and Table 2, so that the solid content concentration was 40 to 55% by mass to obtain photosensitive compositions of Examples 1 to 20 and Comparative Examples 1 to 18. The solid content concentration was adjusted in the range of 40 to 55% by mass in the Examples and Comparative Examples so that the content of the organic solvent in the photosensitive dry film prepared in the following [Preparation of Laminated Films Including Photosensitive Dry Film] using the photosensitive composition was 18% by mass. Table 1 and Table 2 describe boiling points of organic solvents used and δh, an energy term by hydrogen bonding relating to a Hansen solubility parameter.

### [Preparation of Laminated Films Including Photosensitive Dry Film]

Each of the photosensitive compositions of the Examples and the Comparative Examples was applied to the entire surface of a rectangular PET film having a length of 300 mm×a width of 500 mm as a base film by an applicator, and the coated film was dried by heating at 80° C. for 20 minutes in an oven to obtain a laminated film including a photosensitive layer (photosensitive dry film) having a thickness of 120 μm on the PET film. In all of the Examples and the Comparative Examples, the photosensitive layer (photosensitive dry film) in the obtained laminated films contained 18% by mass of the organic solvent contained in the photosensitive composition.

### [Appearance Evaluation of Dry Films]

The photosensitive dry films of the obtained laminated films were visually observed, and a photosensitive dry film in which neither resin separation nor white turbidity was observed and which was transparent was evaluated as good (indicated by circle symbol (∘)), a photosensitive dry film in which white turbidity was observed was evaluated as poor (indicated by cross symbol (×)), and a photosensitive dry film in which resin separation was observed was evaluated as bad (indicated by double cross symbol (××). The results are shown in Tables 1 and 2.

[Evaluation of Foam Present in the Photosensitive Dry Film after Heating (PAB)]

The obtained laminated film was attached to the surface of a copper-sputtered silicon wafer substrate (8 inch) using a dry film laminator (VA-700, manufactured by Taisei Laminator Co., Ltd.) under the conditions of speed of 1 m/min, a pressure of 0.5 MPa (G), and a heating temperature of 70° C. so that the photosensitive dry film (photosensitive layer) was in contact with the copper-sputtered surface of the substrate, and the photosensitive dry film having a film thickness of 120 μm was laminated on the substrate. The PET film was then peeled off and the organic solvent was removed from the photosensitive dry film by heating (PAB) using a hot plate at 140° C. for 10 minutes. In the photosensitive dry film after heating (PAB) at 140° C. for 10 minutes, less than 10% by mass of the organic solvent remained. The photosensitive dry film on the substrate was observed with a microscope, after heating (PAB) at 140° C. for 10 minutes, and a photosensitive dry film in which the number of bubbles present was 10 or less was evaluated as good (indicated by circle symbol (∘)), a photosensitive dry film in which the number of bubbles present was 11 or more and 50 or less was evaluated as poor (indicated by cross symbol (×)), and a photosensitive dry film in which the number of bubbles present was 51 or more was evaluated as bad (indicated by double cross symbol (××)). The results are shown in the column “Bubbles after Heating” in Tables 1 and 2.

### [Formation of Patterned Resist Film]

With regard to the photosensitive dry films of the Examples after heating (PAB) at 140° C. for 10 minutes in the [Evaluation of Foam Present in the Photosensitive Dry Film after Heating (PAB)] above, each film was selectively exposed to light at an exposure amount of 2000 mJ/cm² using a projection exposure apparatus Prisma GHI (manufactured by Ultratech Inc., NA=0.16) through a predetermined mask. The substrate was then placed on a hot plate and subjected to post exposure heating (PEB) at 100° C. for 3 minutes. Then, an aqueous 2.38% tetramethylammonium hydroxide (TMAH) solution (developing solution, NMD-3, manufactured by Tokyo Ohka Kogyo Co., Ltd.) was added dropwise on the photosensitive dry film, the film was allowed to stand at 23° C. for 60 seconds (puddle development), and this was repeated ten times to develop the film. Thereafter, the resist film was washed with running water for 60 seconds and spin-dried to obtain a resist pattern (patterned resist film) having a contact hole pattern having a diameter of 40 μm. It should be noted that there were no differences between the shapes of the resist patterns obtained in Examples 1 to 20.

TABLE 1

| | | Organic solvent (S) | | | | |
|---|---|---|---|---|---|---|
| | | Organic solvent (S1) | | | Evaluation | |
| | | | Boiling | | | Bubbles |
| | Resin | | point | | | after |
| | (B) | Type | (° C.) | δh | Appearance | heating |
| Example 1 | B1 | Anisole | 154 | 6.1 | ∘ | ∘ |
| Example 2 | B2 | | | | ∘ | ∘ |
| Example 3 | B1 | Methyl | 170 | 8.8 | ∘ | ∘ |
| Example 4 | B2 | 3-ethoxypropionate | | | ∘ | ∘ |
| Example 5 | B1 | 3-methoxybutyl | 171 | 8.1 | ∘ | ∘ |
| Example 6 | B2 | acetate | | | ∘ | ∘ |
| Example 7 | B1 | Cyclohexanol acetate | 173 | 6.0 | ∘ | ∘ |
| Example 8 | B2 | | | | ∘ | ∘ |
| Example 9 | B1 | Dipropylene glycol | 175 | 7.1 | ∘ | ∘ |
| Example 10 | B2 | dimethyl ether | | | ∘ | ∘ |
| Example 11 | B1 | 3-methoxy-3-methyl- | 188 | 7.7 | ∘ | ∘ |
| Example 12 | B2 | 1-butyl acetate | | | ∘ | ∘ |
| Example 13 | B1 | Propylene glycol | 190 | 8.4 | ∘ | ∘ |
| Example 14 | B2 | diacetate | | | ∘ | ∘ |
| Example 15 | B1 | Gamma butyrolactone | 204 | 7.4 | ∘ | ∘ |
| Example 16 | B2 | | | | ∘ | ∘ |
| Example 17 | B1 | Dipropylene glycol | 213 | 8 | ∘ | ∘ |
| Example 18 | B2 | methyl ether acetate | | | ∘ | ∘ |
| Example 19 | B1 | Propylene glycol | 170 | 9.2 | ∘ | ∘ |
| Example 20 | B2 | monobutyl ether | | | ∘ | ∘ |

TABLE 2

| | | Organic solvent (S) | | | | |
|---|---|---|---|---|---|---|
| | | Organic solvent which | | | | |
| | | does not fall under S1 | | | Evaluation | |
| | | | Boiling | | | Bubbles |
| | Resin | | point | | | after |
| | (B) | Type | (° C.) | δh | Appearance | heating |
| Comparative | B1 | Methyl ethyl ketone | 80 | 5.1 | ∘ | x |
| Example 1 | | | | | | |
| Comparative | B2 | | | | ∘ | x |
| Example 2 | | | | | | |
| Comparative | B1 | Methyl isobutyl | 116 | 4.1 | ∘ | x |
| Example 3 | | ketone | | | | |
| Comparative | B2 | | | | ∘ | x |
| Example 4 | | | | | | |
| Comparative | B1 | Propylene glycol | 121 | 11.6 | x | x |
| Example 5 | | monomethyl ether | | | | |
| Comparative | B2 | | | | x | x |
| Example 6 | | | | | | |
| Comparative | B1 | Ethylene glycol | 145 | 11.6 | x | x |
| Example 7 | | monomethyl ether | | | | |
| Comparative | B2 | acetate | | | x | x |
| Example 8 | | | | | | |
| Comparative | B1 | Propylene glycol | 146 | 9.8 | ∘ | x |
| Example 9 | | monomethyl ether | | | | |
| Comparative | B2 | acetate | | | ∘ | x |
| Example 10 | | | | | | |
| Comparative | B1 | 2-heptanone | 149 | 4.1 | ∘ | xx |
| Example 11 | | | | | | |
| Comparative | B2 | | | | ∘ | xx |
| Example 12 | | | | | | |
| Comparative | B1 | 3-methoxy-3-metnyl- | 174 | 12.9 | xx | ∘ |
| Example 13 | | 1-butanol | | | | |
| Comparative | B2 | | | | xx | ∘ |
| Example 14 | | | | | | |
| Comparative | B1 | Ethyl lactate | 154 | 12.5 | xx | ∘ |
| Example 15 | | | | | | |
| Comparative | B2 | | | | xx | ∘ |
| Example 16 | | | | | | |
| Comparative | B1 | Propylene glycol | 188 | 21.3 | xx | ∘ |
| Example 17 | | | | | | |
| Comparative | B2 | | | | xx | ∘ |
| Example 18 | | | | | | |

According to Examples 1 to 20, it can be seen that in the photosensitive dry films including an acid generating agent (A) to generate an acid by irradiation, a resin (B) having an alkali solubility that increases under action of an acid, and an organic solvent (S), the resin (B) including an acrylic resin (B3) which contains a constituent unit (B3a) derived from a (meth)acrylate including an acid-non-dissociable alicyclic hydrocarbon group-containing group, the organic solvent (S) including a high boiling point organic solvent (S1) which has I) a boiling point at atmospheric pressure of 150° C. or more and II) a value of δh, an energy term by hydrogen bonding relating to a Hansen solubility parameter, of 11 (MPa)^{0.5} or less, white turbidity or separation due to the resin does not occur, and remaining of foam after heating (PAB) can be suppressed. Further, according to Examples 1 to 20, it is understood that a resist pattern having a good shape can be formed by using the obtained dry films.

On the other hand, according to Comparative Examples 1 to 18, it is understood that in the dry films that contain neither the acrylic resin (B3) as the resin (B) nor the high-boiling-point organic solvent (S1) as the organic solvent (S), white turbidity or separation due to the resin occurs, and many bubbles exist after heating (PAB) the dry films.

1. A photosensitive dry film comprising a chemically amplified positive type photosensitive composition, comprising:
an acid generating agent (A) that generates an acid by irradiation with an actinic ray or radiation;
a resin (B) having an alkali solubility that increases under action of an acid; and
an organic solvent (S),
the resin (B) comprising an acrylic resin (B3),
the acrylic resin (B3) comprising a constituent unit (B3a) derived from a (meth)acrylate comprising an acid-non-dissociable alicyclic hydrocarbon group-comprising group,
the organic solvent (S) comprising a high boiling point organic solvent (S1) that satisfies the following conditions I) and II):
I) a boiling point at atmospheric pressure of 150° C. or more, and
II) a value of δh, a term of energy by hydrogen bonding relating to a Hansen solubility parameter, of 11 (MPa)^{0.5} or less.

2. The photosensitive dry film according to claim 1, wherein a ratio of a mass of the high boiling point organic solvent (S1) to a mass of the organic solvent (S) is 10% by mass or more.

3. The photosensitive dry film according to claim 1, wherein a ratio of a mass of the constituent unit (B3a) to a mass of the acrylic resin (B3) is 15% by mass or more and 50% by mass or less.

4. The photosensitive dry film according to claim 1, wherein the high boiling point organic solvent (S1) is at least one selected from the group consisting of anisole, methyl 3-ethoxypropionate, 3-methoxybutyl acetate, cyclohexanol acetate, dipropylene glycol dimethyl ether, 3-methoxy-3-methyl-1-butyl acetate, propylene glycol diacetate, gamma butyrolactone, dipropylene glycol methyl ether acetate, and propylene glycol monobutyl ether.

5. The photosensitive dry film according to claim 1, wherein the film has a thickness of 40 μm or more and 200 μm or less.

6. A laminated film comprising a base film and the photosensitive dry film according to claim 1, wherein the photosensitive dry film is laminated on the base film.

7. A method of producing the laminated film according to claim 6, the method comprising:
coating a base film with the chemically amplified positive type photosensitive composition to form a coating film; and
drying the coating film by heating to remove some of the organic solvent (S) to form the photosensitive dry film.

8. The method of producing a laminated film according to claim 7, wherein the coating film is heated at a temperature in the range of 50° C. or more and 100° C. or less.

9. A method of producing a patterned resist film, comprising:
laminating the laminated film according to claim 6 on a substrate so that the photosensitive dry film is in contact with a surface of the substrate;
removing the base film from the laminated film;
removing the organic solvent (S) by heating the photosensitive dry film at 100° C. or more and 180° C. or less;
exposing the photosensitive dry film by irradiating the photosensitive dry film with an actinic ray or radiation in a position-selective manner after removing the solvent; and
developing the photosensitive dry film after exposing the photosensitive dry film.
